(19) United States
(12) Patent Application Publication
(10) Pub. No.: US 2025/0008818 A1
(43) Pub. Date: Jan. 2, 2025

(54) DISPLAY APPARATUS AND METHOD FOR MANUFACTURING THE DISPLAY APPARATUS

(71) Applicant: Semiconductor Energy Laboratory Co., Ltd., Atsugi-shi, Kanagawa-ken (JP)

(72) Inventors: Yukinori SHIMA, Tatebayashi (JP); Kenichi OKAZAKI, Atsugi (JP); Masataka NAKADA, Tochigi (JP); Yasutaka NAKAZAWA, Tochigi (JP); Naoto GOTO, Tochigi (JP); Saki EGUCHI, Tochigi (JP); Sachiko KATANIWA, Isehara (JP)

(21) Appl. No.: 18/711,284

(22) PCT Filed: Nov. 21, 2022
(86) PCT No.: PCT/IB2022/061194

§ 371 Date: May 17, 2024

(30) Foreign Application Priority Data
Nov. 30, 2021 (JP) 2021-193948
Dec. 29, 2021 (JP) 2021-215363
Sep. 16, 2022 (JP) 2022-147625

(51) Int. Cl. H10K 59/80; H10K 39/00; H10K 59/12; H10K 59/95

(52) U.S. Cl. CPC H10K 59/873; H10K 39/621; H10K 59/1201; H10K 59/95

(57) ABSTRACT

A display apparatus with extremely high resolution is provided. A display apparatus with high display quality is provided. The display apparatus includes a first light-emitting element and a second light-emitting element over a first insulating layer, a second insulating layer, and a third insulating layer. The first light-emitting element includes a first pixel electrode and a first organic layer. The second light-emitting element includes a second pixel electrode and a second organic layer. The first insulating layer includes a groove-like region provided along a side of the first pixel electrode in a plan view. The groove-like region includes a first region overlapping with the first pixel electrode and a second region overlapping with the second pixel electrode. The first region and the second region each have a width greater than or equal to 20 nm and less than or equal to 500 nm. The second insulating layer includes a region in contact with a top surface of the first organic layer, a region in contact with a side surface of the first organic layer, and a region located below the first pixel electrode. The third insulating layer includes a region in contact with a top surface of the second organic layer, a region in contact with a side surface of the second organic layer, and a region located below the second pixel electrode.

### TECHNICAL FIELD

One embodiment of the present invention relates to a display apparatus. One embodiment of the present invention relates to a method for manufacturing the display apparatus.

Note that one embodiment of the present invention is not limited to the above technical field. Examples of a technical field of one embodiment of the present invention disclosed in this specification and the like include a semiconductor device, a display apparatus, a light-emitting apparatus, a power storage device, a memory device, an electronic device, a lighting device, an input device, an input/output device, a driving method thereof, and a manufacturing method thereof. Note that in this specification and the like, a semiconductor device generally means a device that can function by utilizing semiconductor characteristics.

### BACKGROUND ART

In recent years, higher-resolution display panels have been required. As a device that requires a high-resolution display panel, for example, devices for virtual reality (VR), augmented reality (AR), substitutional reality (SR), or mixed reality (MR) have been actively developed in recent years.

Examples of display apparatuses that can be used for a display panel include, typically, a liquid crystal display apparatus, a light-emitting apparatus including a light-emitting element such as an organic EL (Electro Luminescence) element or a light-emitting diode (LED), and electronic paper performing display by an electrophoretic method or the like.

For example, the basic structure of an organic EL element is a structure where a layer containing a light-emitting organic compound is provided between a pair of electrodes. By voltage application to this element, light emission can be obtained from the light-emitting organic compound. A display apparatus containing such an organic EL element does not need a backlight that is necessary for a liquid crystal display apparatus and the like; thus, a thin, lightweight, high-contrast, and low-power-consumption display apparatus can be achieved. Patent Document 1, for example, discloses an example of a display apparatus using an organic EL element.

### REFERENCE

### Patent Document

[Patent Document 1] Japanese Published Patent Application No. 2002-324673

### SUMMARY OF THE INVENTION

### Problems to be Solved by the Invention

For example, in the above-described device for VR, AR, SR, or MR that is wearable, a lens for focus adjustment needs to be provided between eyes and the display panel. Since part of a screen is enlarged by the lens, the low definition of the display panel might cause a problem of weak sense of reality and immersion.

The display panel is also required to have high color reproducibility. In particular, when using the display panel with high color reproducibility, the above-described device for VR, AR, SR, or MR can perform display with colors that are close to those of the actual objects, leading to higher senses of reality and immersion.

An object of one embodiment of the present invention is to provide a display apparatus with extremely high resolution. An object of one embodiment of the present invention is to provide a display apparatus which can achieve high color reproducibility. An object of one embodiment of the present invention is to provide a high-luminance display apparatus. An object of one embodiment of the present invention is to provide a highly reliable display apparatus. An object of one embodiment of the present invention is to provide a display apparatus manufactured at low cost. An object of one embodiment of the present invention is to provide a method for manufacturing the above-described display apparatus.

Note that the description of these objects does not preclude the existence of other objects. One embodiment of the present invention does not have to achieve all of these objects. Note that objects other than these can be derived from the description of the specification, the drawings, the claims, and the like.

### Means for Solving the Problems

One embodiment of the present invention is a display apparatus including a first insulating layer, a light-emitting element and a light-receiving element over the first insulating layer, a second insulating layer, a third insulating layer, and a resin layer over the first insulating layer. The light-emitting element includes a first pixel electrode, a first organic layer, and a common electrode. The light-receiving element includes a second pixel electrode, a second organic layer, and the common electrode. The first organic layer includes a light-emitting layer. The second organic layer includes a photoelectric conversion layer. The first insulating layer includes a depressed portion. The depressed portion includes a region overlapping with the first pixel electrode, a region overlapping with the second pixel electrode, and a region overlapping with neither the first pixel electrode nor the second pixel electrode. The second insulating layer includes a region in contact with a top surface of the first organic layer, a region in contact with a side surface of the first organic layer, and a region located below the first pixel electrode. The third insulating layer includes a region in contact with a top surface of the second organic layer, a region in contact with a side surface of the second organic layer, and a region located below the second pixel electrode. The resin layer includes a region located in the depressed portion. The common electrode is provided to cover a top surface of the resin layer.

In the above structure, it is preferable that the second insulating layer include a region in contact with the first insulating layer below the first pixel electrode, and the third insulating layer include a region in contact with the first insulating layer below the second pixel electrode.

In the above structure, the shortest distance between an end portion of the first pixel electrode and an end portion of the second pixel electrode is preferably larger than twice the thickness of the first organic layer.

In the above structure, the depressed portion preferably has a downward-convex arc shape in a cross-sectional view.

In the above structure, each of the second insulating layer and the third insulating layer preferably contains aluminum and oxygen.

One embodiment of the present invention is a display apparatus including a first insulating layer, a second insulating layer and a third insulating layer over the first insulating layer, a light-emitting element over the second insulating layer, a light-receiving element over the third insulating layer, a fourth insulating layer, a fifth insulating layer, and a resin layer over the first insulating layer. The first insulating layer is an organic insulating layer. The second insulating layer and the third insulating layer are inorganic insulating layers. The light-emitting element includes a first pixel electrode, a first organic layer, and a common electrode. The light-receiving element includes a second pixel electrode, a second organic layer, and the common electrode. The first organic layer includes a light-emitting layer. The second organic layer includes a photoelectric conversion layer. The first insulating layer includes a depressed portion. The depressed portion includes a region overlapping with the first pixel electrode, a region overlapping with the second pixel electrode, and a region overlapping with neither the first pixel electrode nor the second pixel electrode. The fourth insulating layer includes a region in contact with a top surface of the first organic layer, a region in contact with a side surface of the first organic layer, and a region in contact with the second insulating layer below the first pixel electrode. The fifth insulating layer includes a region in contact with a top surface of the second organic layer, a region in contact with a side surface of the second organic layer, and a region in contact with the third insulating layer below the second pixel electrode. The resin layer includes a region located in the depressed portion. The common electrode is provided to cover a top surface of the resin layer.

One embodiment of the present invention is a method for manufacturing a display apparatus, in which a first pixel electrode and a second pixel electrode are formed over a first insulating layer; part of the first insulating layer is etched to form a depressed portion including a region overlapping with the first pixel electrode, a region overlapping with the second pixel electrode, and a region overlapping with neither the first pixel electrode nor the second pixel electrode; a first organic film is formed over the first pixel electrode, the second pixel electrode, and the first insulating layer to form a first organic layer over the first pixel electrode and form a second organic layer over the second pixel electrode; a second insulating layer is formed over the first organic layer; the second organic layer is removed; a second organic film is formed over the first organic layer, the second pixel electrode, and the first insulating layer to form a third organic layer over the second pixel electrode and form a fourth organic layer over the first organic layer; a third insulating layer is formed over the third organic layer; the fourth organic layer is removed; a resin layer is formed over the first insulating layer, the second insulating layer, and the third insulating layer; part of the resin layer, part of the second insulating layer, and part of the third insulating layer are removed to form a first opening portion reaching the first organic layer in the resin layer and the second insulating layer and form a second opening portion reaching the third organic layer in the resin layer and the third insulating layer; and a common electrode is formed so as to overlap with the first organic layer through the first opening portion and overlap with the third organic layer through the second opening portion.

In the above structure, it is preferable that the first organic film contain a light-emitting compound emitting light having intensity in a red-wavelength range, a green-wavelength range, or a blue-wavelength range, and the second organic film contain a light-emitting compound emitting light having intensity in a wavelength range that is any of the red-wavelength range, the green-wavelength range, and the blue-wavelength range and is different from the wavelength range of the color of the first organic film.

In the above structure, it is preferable that the first organic film contain a light-emitting compound, and the second organic film contain an organic semiconductor.

One embodiment of the present invention is a display apparatus including a first insulating layer, a first light-emitting element and a second light-emitting element over the first insulating layer; a second insulating layer, a third insulating layer, and a resin layer over the first insulating layer. The first light-emitting element includes a first pixel electrode, a first organic layer, and a common electrode. The second light-emitting element includes a second pixel electrode, a second organic layer, and the common electrode. Each of the first organic layer and the second organic layer includes a light-emitting layer. The first insulating layer includes a groove-like region provided along a side of the first pixel electrode in a plan view. The groove-like region includes a first region overlapping with the first pixel electrode and a second region overlapping with the second pixel electrode. The first region has a width greater than or equal to 20 nm and less than or equal to 500 nm. The second region has a width greater than or equal to 20 nm and less than or equal to 500 nm. The second insulating layer includes a region in contact with a top surface of the first organic layer, a region in contact with a side surface of the first organic layer, and a region located below the first pixel electrode. The third insulating layer includes a region in contact with a top surface of the second organic layer, a region in contact with a side surface of the second organic layer, and a region located below the second pixel electrode. The resin layer includes a region located in the groove-like region. The common electrode comprises a region covering a top surface of the resin layer.

In the above structure, the groove-like region preferably has a depth greater than or equal to 50 nm and less than or equal to 3000 nm.

In the above structure, it is preferable that the second insulating layer include a region in contact with the first insulating layer below the first pixel electrode, and the third insulating layer include a region in contact with the first insulating layer below the second pixel electrode.

In the above structure, the shortest distance between an end portion of the first pixel electrode and an end portion of the second pixel electrode is preferably larger than twice the thickness of the first organic layer.

In the above structure, the depressed portion preferably has a downward-convex arc shape in a cross-sectional view.

In the above structure, each of the second insulating layer and the third insulating layer preferably contains aluminum and oxygen.

One embodiment of the present invention is a display apparatus including a first insulating layer, a second insulating layer and a third insulating layer over the first insulating layer, a first light-emitting element over the second insulating layer, a second light-emitting element over the third insulating layer, a fourth insulating layer, a fifth insulating layer, and a resin layer over the first insulating layer. The first insulating layer is an organic insulating layer. The second insulating layer and the third insulating layer are inorganic insulating layers. The first light-emitting element includes a first pixel electrode, a first organic layer, and a common electrode. The second light-emitting element includes a second pixel electrode, a second organic layer, and the common electrode. Each of the first organic layer and the second organic layer includes a light-emitting layer. The first insulating layer includes a groove-like region provided along a side of the first pixel electrode in a plan view. The groove-like region includes a first region overlapping with the first pixel electrode and a second region overlapping with the second pixel electrode. The first region has a width greater than or equal to 20 nm and less than or equal to 500 nm. The second region has a width greater than or equal to 20 nm and less than or equal to 500 nm. The fourth insulating layer includes a region in contact with a top surface of the first organic layer, a region in contact with a side surface of the first organic layer, and a region in contact with the second insulating layer below the first pixel electrode. The fifth insulating layer includes a region in contact with a top surface of the second organic layer, a region in contact with a side surface of the second organic layer, and a region in contact with the third insulating layer below the second pixel electrode. The resin layer includes a region located in the groove-like region. The common electrode includes a region covering a top surface of the resin layer.

In the above structure, the groove-like region preferably has a depth greater than or equal to 50 nm and less than or equal to 3000 nm.

### Effect of the Invention

According to one embodiment of the present invention, a display apparatus with extremely high resolution can be provided. Alternatively, a display apparatus which can achieve high color reproducibility can be provided. Alternatively, a high-luminance display apparatus can be provided. Alternatively, a highly reliable display apparatus can be provided. Alternatively, a display apparatus manufactured at low cost can be provided. Alternatively, a method for manufacturing the above-described display apparatus can be provided.

Note that the description of these effects does not preclude the existence of other effects. One embodiment of the present invention does not need to have all these effects. Note that effects other than these can be derived from the description of the specification, the drawings, the claims, and the like.

### BRIEF DESCRIPTION OF THE DRAWINGS

FIG. 1 is a diagram illustrating a structure example of a display apparatus.

FIG. 2A and FIG. 2B are diagrams illustrating a structure example of a display apparatus.

FIG. 3 is a diagram illustrating a structure example of a display apparatus.

FIG. 4A to FIG. 4E are diagrams illustrating an example of a method for manufacturing a display apparatus.

FIG. 5A to FIG. 5D are diagrams illustrating an example of a method for manufacturing a display apparatus.

FIG. 6A to FIG. 6C are diagrams illustrating structure examples of a display apparatus.

FIG. 7A to FIG. 7C are diagrams illustrating structure examples of a display apparatus.

FIG. 8A to FIG. 8G are diagrams showing pixel examples.

FIG. 9A to FIG. 9I are diagrams showing pixel examples.

FIG. 10A and FIG. 10B are diagrams illustrating a structure example of a display apparatus.

FIG. 11 is a diagram illustrating a structure example of a display apparatus.

FIG. 12 is a diagram illustrating a structure example of a display apparatus.

FIG. 13 is a diagram illustrating a structure example of a display apparatus.

FIG. 14 is a diagram illustrating a structure example of a display apparatus.

FIG. 15 is a diagram illustrating a structure example of a display apparatus.

FIG. 16 is a diagram illustrating a structure example of a display apparatus.

FIG. 17 is a diagram illustrating a structure example of a display apparatus.

FIG. 18 is a diagram illustrating a structure example of a display apparatus.

FIG. 19A to FIG. 19C are diagrams illustrating structure examples of a display apparatus.

FIG. 20A is a circuit diagram illustrating a structure example of a display apparatus. FIG. 20B to FIG. 20D are circuit diagrams illustrating examples of a pixel circuit.

FIG. 21A to FIG. 21F are diagrams illustrating structure examples of a light-emitting element.

FIG. 22A to FIG. 22C are diagrams illustrating structure examples of a light-emitting element.

FIG. 23A to FIG. 23C are cross-sectional views illustrating an example of a display apparatus.

FIG. 23D is a diagram illustrating an example of an image.

FIG. 24A to FIG. 24E are cross-sectional views illustrating structure examples of a light-receiving element.

FIG. 25A to FIG. 25D are diagrams illustrating examples of electronic devices.

FIG. 26A to FIG. 26F are diagrams illustrating examples of electronic devices.

FIG. 27A to FIG. 27G are diagrams illustrating examples of electronic devices.

FIG. 28 is a graph showing measurement results of peel force.

FIG. 29 is a photograph of a display panel.

FIG. 30 is a cross-sectional view illustrating an example of a display apparatus.

FIG. 31A and FIG. 31B show results of cross-sectional observation.

FIG. 32A and FIG. 32B show results of cross-sectional observation.

FIG. 33A and FIG. 33B show results of cross-sectional observation.

FIG. 34A and FIG. 34B show results of a peel test.

FIG. 35 shows results of a peel test.

### MODE FOR CARRYING OUT THE INVENTION

Embodiments will be described below with reference to the drawings. Note that the embodiments can be implemented with many different modes, and it will be readily understood by those skilled in the art that modes and details thereof can be changed in various ways without departing from the spirit and scope thereof. Therefore, the present invention should not be construed as being limited to the description of embodiments below.

Note that in structures of the invention described below, the same portions or portions having similar functions are denoted by the same reference numerals in different drawings, and the description thereof is not repeated. Furthermore, the same hatch pattern is used for the portions having similar functions, and the portions are not especially denoted by reference numerals in some cases.

Note that in each drawing described in this specification, the size, the layer thickness, or the region of each component is exaggerated for clarity in some cases. Therefore, they are not limited to the illustrated scale.

Note that ordinal numbers such as “first” and “second” in this specification and the like are used in order to avoid confusion among components and do not limit the number of components.

In this specification and the like, a hole or an electron is sometimes referred to as a “carrier”. Specifically, a hole-injection layer or an electron-injection layer may be referred to as a “carrier-injection layer”, a hole-transport layer or an electron-transport layer may be referred to as a “carrier-transport layer”, and a hole-blocking layer or an electron-blocking layer may be referred to as a “carrier-blocking layer”. Note that in some cases, the above-described carrier-injection layer, carrier-transport layer, and carrier-blocking layer cannot be distinguished from one another on the basis of the cross-sectional shape, properties, or the like. Furthermore, one layer may have two or three functions of the carrier-injection layer, the carrier-transport layer, and the carrier-blocking layer in some cases.

In this specification and the like, a light-emitting element (also referred to as a light-emitting device) includes an EL layer between a pair of electrodes, for example. The EL layer includes at least a light-emitting layer. Here, examples of a layer included in the EL layer (also referred to as a functional layer) include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer).

In this specification and the like, a light-receiving element (also referred to as a light-receiving device) includes a layer including a photoelectric conversion layer between a pair of electrodes, for example.

Here, the display apparatus of one embodiment of the present invention includes a layer shared by a light-receiving element and a light-emitting element (the layer can be also regarded as a continuous layer shared by a light-receiving element and a light-emitting element) in some cases. The function of such a layer in the light-emitting element is different from its function in the light-receiving element in some cases. In this specification and the like, the name of a component is sometimes based on its function in the light-emitting element.

One embodiment of the present invention is a display apparatus that includes a display portion capable of full-color display. The display portion includes a first subpixel and a second subpixel that emit light of different colors and a third subpixel that detects light. The first subpixel includes a first light-emitting element that emits blue light and the second subpixel includes a second light-emitting element that emits light of a color different from the color of light emitted by the first light-emitting element. The third subpixel includes a light-receiving element that detects light. At least one type of material is different between the first light-emitting element and the second light-emitting element; for example, the light-emitting elements contain different light-emitting materials. That is, light-emitting elements separately formed for respective emission colors are used in the display apparatus of one embodiment of the present invention. The light-receiving element contains a photoelectric conversion material.

One embodiment of the present invention is capable of image capturing by a plurality of light-receiving elements and thus functions as an image capturing device. In this case, the light-emitting elements can be used as a light source for image capturing. Moreover, one embodiment of the present invention is capable of displaying an image with the plurality of light-emitting elements and thus functions as a display apparatus. Accordingly, one embodiment of the present invention can be regarded as a display apparatus that has an image capturing function or an image capturing device that has a display function.

For example, in the display apparatus of one embodiment of the present invention, light-emitting elements are arranged in a matrix in a display portion, and light-receiving elements are also arranged in a matrix in the display portion. Hence, the display portion has a function of displaying an image and a function of a light-receiving portion. An image can be captured with the plurality of light-receiving elements provided in the display portion, so that the display apparatus can function as an image sensor or the like. That is, the display portion can capture an image or detect an approach or touch of an object, for example. Furthermore, since the light-emitting elements provided in the display portion can be used as a light source at the time of receiving light, a light source does not need to be provided separately from the display apparatus; thus, a highly functional display apparatus can be provided without increasing the number of electronic components.

In one embodiment of the present invention, when an object reflects light emitted by the light-emitting element included in the display portion, the light-receiving element can detect the reflected light; thus, image capturing, touch (including non-contact touch) detecting, or the like can be performed even in a dark environment.

Furthermore, when a finger, a palm, or the like touches the display portion of the display apparatus of one embodiment of the present invention, an image of the fingerprint or the palm print can be captured. Thus, an electronic device including the display apparatus of one embodiment of the present invention can perform personal authentication by using the captured image of the fingerprint, the palm print, or the like. Accordingly, an image capturing device for the fingerprint authentication, the palm print authentication, or the like does not need to be additionally provided, and the number of components of the electronic device can be reduced. Since the light-receiving elements are arranged in a matrix in the display portion, an image of the fingerprint, the palm print, or the like can be captured in any position in the display portion, which can provide a highly convenient electronic device.

A structure in which light-emitting layers in light-emitting elements of different emission wavelengths (for example, blue (B), green (G), and red (R)) are separately formed or separately patterned is sometimes referred to as an SBS (Side By Side) structure. The SBS structure can optimize materials and structures of light-emitting elements and thus can increase the freedom of choices of the materials and the structures, so that the luminance and the reliability can be easily improved.

In the case of manufacturing a display apparatus including a plurality of light-emitting elements emitting light of different colors, the light-emitting layers emitting light of different colors each need to be formed into an island shape. A photoelectric conversion layer is formed into an island shape also in the light-receiving element. Note that in this specification and the like, the term “island shape” refers to a state where two or more layers formed using the same material in the same step are physically separated from each other. For example, the term “island-shaped light-emitting layers” means a state where the light-emitting layer and its adjacent light-emitting layer are physically separated from each other.

The display apparatus of one embodiment of the present invention includes a touch sensor that acquires the positional data of an object being in contact with or in proximity to a display surface. As the touch sensor, any of various types such as a resistive type, a capacitive type, an infrared type, an electromagnetic induction type, and a surface acoustic wave type can be employed. As the touch sensor, a capacitive touch sensor is particularly preferable.

Examples of the capacitive touch sensor include a surface capacitive touch sensor and a projected capacitive touch sensor. Examples of the projected capacitive type include a self-capacitive type and a mutual capacitive type. The use of a mutual capacitive type is preferable because multiple points can be sensed simultaneously.

The mutual capacitive touch sensor can include a plurality of electrodes to which pulse potentials are supplied and a plurality of electrodes to which a sensor circuit is connected. The touch sensor can sense the approach of a finger or the like using a change in capacitance between the electrodes. The electrodes included in the touch sensor are preferably placed closer to a display surface side than the light-emitting element (or the light-receiving element) is.

At least part of an electrode of the touch sensor overlaps with a region interposed between two adjacent light-emitting elements (or two adjacent light-receiving elements) or a region interposed between two adjacent EL layers (or two adjacent PS layers). Furthermore, at least part of the electrode of the touch sensor preferably includes a region overlapping with the organic resin film provided between two adjacent EL layers (or two adjacent PS layers). With such a structure, the touch sensor can be provided in an upper portion of the display apparatus without reducing the light-emitting area of the light-emitting element (or the light-receiving element). Thus, a display apparatus having both a high aperture ratio and a high resolution can be provided.

Here, a metal or an alloy material is preferably used for the conductive layer functioning as the electrode of the touch sensor. When the electrode of the touch sensor is placed as described above, a metal or an alloy material that does not have a light-transmitting property can be used as the electrode of the touch sensor without reducing the aperture ratio of the display apparatus. When a metal or an alloy material with low resistance is used for the electrode of the touch sensor, touch sensing with high sensitivity can be achieved.

Note that a light-transmitting electrode that transmits light emitted from the light-emitting element can be used as the electrode of the touch sensor. Here, the light-transmitting electrode can be provided to overlap with the light-emitting element (or the light-receiving element).

The light-emitting element (or the light-receiving element) can be provided between a pair of substrates. As the substrate, a rigid substrate such as a glass substrate or a flexible film may be used. In this case, the electrode of the touch sensor can be formed over the substrate located on the display surface side. Alternatively, the structure in which the electrode of the touch sensor is formed over another substrate and bonded to the display surface side may be employed.

The electrode of the touch sensor is preferably placed between the pair of substrates. Here, a protective layer that covers the light-emitting element (or the light-receiving element) can be provided, and the electrode of the touch sensor can be provided over the protective layer. Thus, the number of components can be reduced, whereby the manufacturing process can be simplified. Furthermore, since the thickness of the display apparatus can be made small, the structure is particularly suitable in the case where a display apparatus is used as a flexible display using a flexible film for the substrate.

Note that in this specification and the like, a tapered shape refers to a shape such that at least part of a side surface of a component is inclined to a substrate surface. For example, a tapered shape preferably includes a region where the angle formed by the inclined side surface and the substrate surface (such an angle is also referred to as a taper angle) is less than 90°. Note that the side surface of the structure and the substrate surface are not necessarily completely flat and may be substantially flat with a slight curvature or substantially flat with slight unevenness.

In this specification and the like, an inverse tapered shape refers to the case where an angle formed by at least part of the side surface of a component and the bottom surface of the component is greater than 90°. Alternatively, the inverse tapered shape refers to a shape in which a side portion or an upper portion extends beyond a bottom portion in the direction parallel to a substrate.

In this specification, in the case where the maximum value and the minimum value are specified, a structure in which the maximum value and the minimum value are freely combined is also disclosed.

### Embodiment 1

In this embodiment, a display apparatus of one embodiment of the present invention and a method for manufacturing the display apparatus are described.

The display apparatus of one embodiment of the present invention includes light-emitting elements emitting light of different colors. The light-emitting element includes a lower electrode, an upper electrode, and a layer containing a light-emitting compound (also referred to as a light-emitting layer) therebetween. As the light-emitting element, an electroluminescent element such as an organic EL element or an inorganic EL element is preferably used. Alternatively, a light-emitting diode (LED) may be used.

In addition, the display apparatus of one embodiment of the present invention includes a light-receiving element. The light-receiving element can detect one or both of visible light and infrared light. The light-receiving element includes, for example, a lower electrode, an upper electrode, and a photoelectric conversion layer therebetween.

As the light-emitting element, an OLED (Organic Light Emitting Diode) or a QLED (Quantum-dot Light Emitting Diode) is preferably used, for example. Examples of a light-emitting substance contained in the light-emitting element include a substance that emits fluorescent light (a fluorescent material), a substance that emits phosphorescent light (a phosphorescent material), a substance that exhibits thermally activated delayed fluorescence (a thermally activated delayed fluorescence (TADF) material), and an inorganic compound (e.g., a quantum dot material). Alternatively, an LED such as a micro-LED (Light Emitting Diode) can be used as the light-emitting element.

The emission color of the light-emitting element can be red, green, blue, cyan, magenta, yellow, white, or the like. When the light-emitting element has a microcavity structure, the color purity can be increased.

Embodiment 3 can be referred to for the structure and the materials of the light-emitting element.

The light-emitting layer may contain one or more kinds of compounds (a host material and an assist material) in addition to a light-emitting substance (a guest material). As the host material and the assist material, one or more kinds of substances whose energy gap is larger than the energy gap of the light-emitting substance (the guest material) can be selected and used. As the host material and the assist material, compounds that form an exciplex are preferably used in combination. In order to form an exciplex efficiently, it is particularly preferable to combine a compound that easily accepts holes (a hole-transport material) and a compound that easily accepts electrons (an electron-transport material).

Either a low molecular compound or a high molecular compound can be used for the light-emitting element, and an inorganic compound (e.g., a quantum dot material) may be contained.

In the display apparatus of one embodiment of the present invention, the light-emitting elements of different colors can be separately formed with extremely high accuracy. Thus, a display apparatus with higher resolution than a conventional display apparatus can be achieved. For example, the display apparatus preferably has extremely high resolution in which pixels including one or more light-emitting elements are arranged with a resolution greater than or equal to 2000 ppi, preferably greater than or equal to 3000 ppi, further preferably greater than or equal to 5000 ppi, still further preferably greater than or equal to 6000 ppi, and less than or equal to 20000 ppi or less than or equal to 30000 ppi.

More specific structure examples of a display apparatus and manufacturing method examples thereof will be described below with reference to drawings.

### Structure Example 1

### Structure Example 1-1

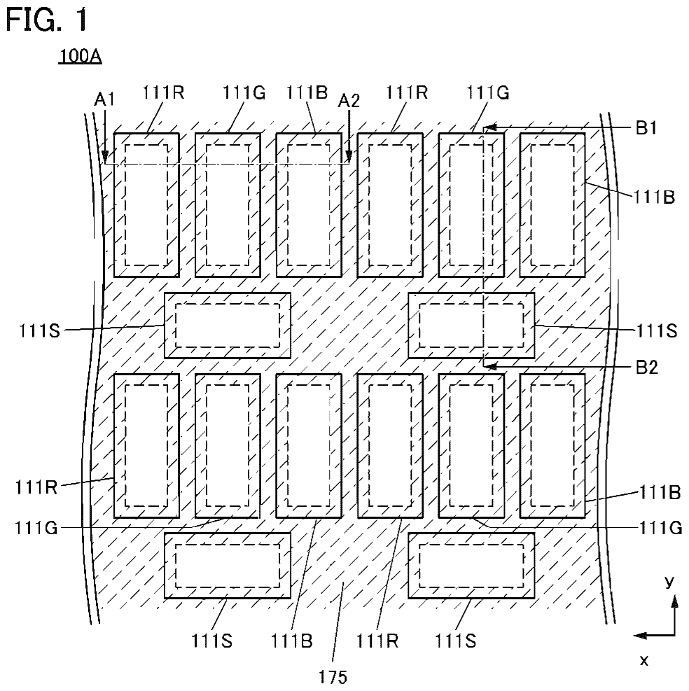

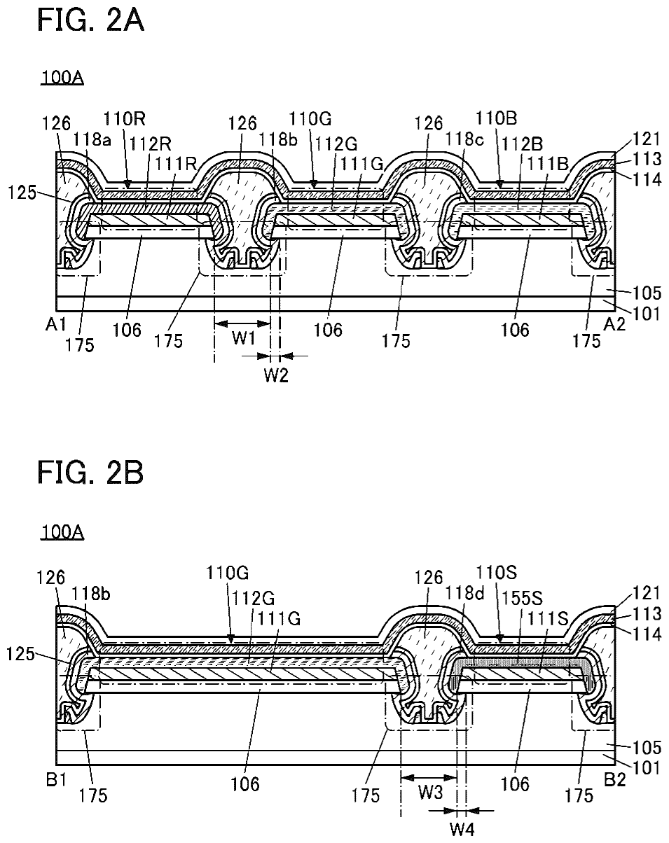

FIG. 1, FIG. 2A and FIG. 2B are diagrams illustrating a display apparatus of one embodiment of the present invention. FIG. 1 is a schematic top view of a display apparatus 100A, and FIG. 2A and FIG. 2B are each a schematic cross-sectional view of the display apparatus 100A. Here, FIG. 2A is a cross-sectional view of a portion indicated by a dashed-dotted line A1-A2 in FIG. 1, and FIG. 2B is a cross-sectional view of a portion indicated by a dashed-dotted line B1-B2 in FIG. 1. Note that for clarity of the drawing, some components are omitted in the top view of FIG. 1.

The display apparatus 100A includes a substrate 101 provided with a semiconductor circuit, an insulating layer 105, a light-emitting element 110R, a light-emitting element 110G, and a light-emitting element 110B. The display apparatus 100A preferably includes a light-receiving element 110S. In FIG. 2A and FIG. 2B, the light-emitting element 110R, the light-emitting element 110G, the light-emitting element 110B, and the light-receiving element 110S are provided over the insulating layer 105.

In FIG. 2A and FIG. 2B, the display apparatus 100A includes an insulating layer 106 between the insulating layer 105 and the light-emitting element 110R, between the insulating layer 105 and the light-emitting element 110G, between the insulating layer 105 and the light-emitting element 110B, and between the insulating layer 105 and the light-receiving element 110S.

The insulating layer 105 is preferably an organic insulating film (an organic insulating layer), and the insulating layer 106 is preferably an inorganic insulating film (an inorganic insulating layer). Alternatively, the insulating layer 105 may be an inorganic insulating film and the insulating layer 106 may be an organic insulating film.

In the display apparatus 100A illustrated in FIG. 2A, an organic layer 112 preferably includes a region in contact with the top surface of a pixel electrode 111, a region in contact with the side surface of the pixel electrode 111, and a region in contact with the insulating layer 105. In addition, the organic layer 112 preferably includes a region in contact with the side surface of the insulating layer 106. Furthermore, the organic layer 112 preferably includes a region in contact with the bottom surface of the insulating layer 106. With the structure illustrated in FIG. 2A, the organic layer 112 can be sealed with the insulating layer 106 and an insulating layer 118. Sealing the organic layer 112 with the insulating layer 106 and the insulating layer 118 can inhibit the insulating layer 118 from being separated from the organic layer 112, for example. Moreover, diffusion of impurities such as water into the organic layer 112 can be inhibited.

In the display apparatus 100A illustrated in FIG. 2B, a PS layer 155S preferably includes a region in contact with the top surface of the pixel electrode 111, a region in contact with the side surface of the pixel electrode 111, and a region in contact with the insulating layer 105. The PS layer 155S preferably includes a region in contact with the side surface of the insulating layer 106. Furthermore, the PS layer 155S preferably includes a region in contact with the bottom surface of the insulating layer 106. With the structure illustrated in FIG. 2B, the PS layer 155S can be sealed with the insulating layer 106 and an insulating layer 118d. Sealing the PS layer 155S with the insulating layer 106 and the insulating layer 118 can inhibit the insulating layer 118 from being separated from the organic layer 112, for example. Moreover, diffusion of impurities such as water into the organic layer 112 can be inhibited.

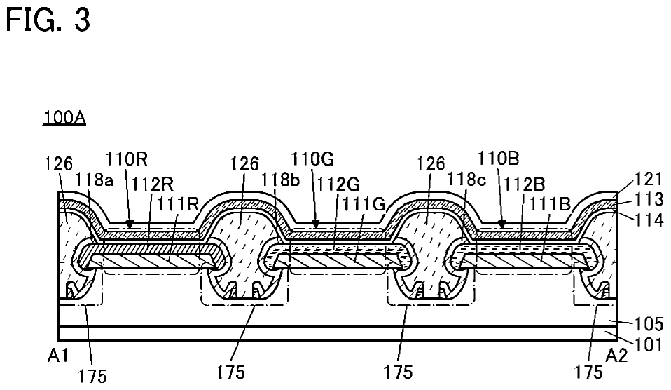

Alternatively, a structure where the display apparatus 100A does not include the insulating layer 106 may be employed. FIG. 3 is different from FIG. 2A in that the display apparatus 100A does not include the insulating layer 106.

In the display apparatus 100A illustrated in FIG. 3, the organic layer 112 preferably includes a region in contact with the top surface of the pixel electrode 111, a region in contact with the side surface of the pixel electrode 111, and a region in contact with the insulating layer 105. The organic layer 112 preferably includes a region in contact with the bottom surface of the pixel electrode 111.

As the structure of the insulating layer 105, a single-layer structure or a stacked-layer structure of two or more layers can be selected as appropriate. For example, the insulating layer 105 may have a stacked-layer structure of an inorganic insulating film and an organic insulating film.

The light-emitting element 110R is a light-emitting element emitting red light, the light-emitting element 110G is a light-emitting element emitting green light, and the light-emitting element 110B is a light-emitting element emitting blue light. In other words, the light-emitting element 110R and the light-emitting element 110G emit light of different colors. The light-emitting element 110G and the light-emitting element 110B emit light of different colors. The light-emitting element 110B and the light-emitting element 110R emit light of different colors. Such a structure in which emission colors (here, red (R), green (G), and blue (B)) are separately patterned for each of the light-emitting elements is referred to as an SBS (Side By Side) structure in some cases.

In this specification and the like, a structure in which at least light-emitting layers are separately formed for light-emitting elements with different emission wavelengths is referred to as a side-by-side (SBS) structure in some cases. The SBS structure can optimize materials and structures of light-emitting elements and thus can increase the freedom of choices of the materials and the structures, so that the luminance and the reliability can be easily improved.

The light-emitting element 110R includes a pixel electrode 111R, an organic layer 112R, a common layer 114, and a common electrode 113. The light-emitting element 110G includes a pixel electrode 111G, an organic layer 112G, the common layer 114, and the common electrode 113. The light-emitting element 110B includes a pixel electrode 111B, an organic layer 112B, the common layer 114, and the common electrode 113. The common layer 114 and the common electrode 113 are provided to be shared by the light-emitting element 110R, the light-emitting element 110G, and the light-emitting element 110B.

The organic layer 112R contains at least a light-emitting organic compound that emits light with intensity in the red wavelength range. The organic layer 112G contains at least a light-emitting organic compound that emits light with intensity in the green wavelength range. The organic layer 112B contains at least a light-emitting organic compound that emits light with intensity in the blue wavelength range. Each of the organic layer 112R, the organic layer 112G, and the organic layer 112B includes at least a layer containing a light-emitting organic compound (a light-emitting layer).

Note that hereafter, in the description common to the light-emitting element 110R, the light-emitting element 110G, and the light-emitting element 110B, the alphabets are omitted from the reference numerals and the term “light-emitting element 110” is used in some cases. Similarly, the organic layer 112R, the organic layer 112G, and the organic layer 112B are also described using the term “organic layer 112” in some cases. Similarly, the pixel electrode 111R, the pixel electrode 111G, the pixel electrode 111B, and a pixel electrode 111S are also described using the term “pixel electrode 111” in some cases.

In the light-emitting element 110, an EL layer sometimes refers to a structure in which the organic layer 112 and the common layer 114 are combined, for example.

The pixel electrode 111R, the pixel electrode 111G, and the pixel electrode 111B are provided in the respective light-emitting elements. In addition, the common layer 114 and the common electrode 113 are each provided as a continuous layer shared by the light-emitting elements. A conductive film having a property of transmitting visible light is used for either the pixel electrodes or the common electrode 113, and a conductive film having a reflective property is used for the other. When the pixel electrodes have light-transmitting properties and the common electrode 113 has a reflective property, a bottom-emission display apparatus can be obtained. In contrast, when the pixel electrodes have reflective properties and the common electrode 113 has a light-transmitting property, a top-emission display apparatus can be obtained. Note that when both the pixel electrodes and the common electrode 113 have light-transmitting properties, a dual-emission display apparatus can be also obtained.

A protective layer 121 is provided over the common electrode 113 to cover the light-emitting element 110R, the light-emitting element 110G, and the light-emitting element 110B. The protective layer 121 has a function of inhibiting diffusion of impurities such as water into each light-emitting element from the above.

The light-receiving element 110S can detect one or both of visible light and infrared light. In the case of detecting visible light, for example, one or more of blue light, violet light, bluish violet light, green light, yellowish green light, yellow light, orange light, red light, and the like can be detected. The infrared light is preferably detected because an object can be detected even in a dark environment.

As the light-receiving element 110S, a pn photodiode or a pin photodiode can be used, for example. The light-receiving element 110S functions as a photoelectric conversion element (also referred to as a photoelectric conversion device) that detects light entering the light-receiving element 110S and generates charge. The amount of generated charge in the photoelectric conversion element is determined depending on the amount of incident light.

It is particularly preferable to use an organic photodiode including a layer containing an organic compound as the light-receiving element 110S. An organic photodiode, which is easily made thin, lightweight, and large in area and has a high degree of freedom for shape and design, can be used in a variety of devices.

Here, the display apparatus of one embodiment of the present invention includes a layer shared by the light-receiving element and the light-emitting element (the layer can be also regarded as a continuous layer shared by the light-receiving element and the light-emitting element) in some cases. The function of such a layer in the light-emitting element is different from its function in the light-receiving element in some cases. In this specification, the name of a component is sometimes based on its function in the light-emitting element. For example, a hole-injection layer functions as a hole-injection layer in the light-emitting element and functions as a hole-transport layer in the light-receiving element. Similarly, an electron-injection layer functions as an electron-injection layer in the light-emitting element and functions as an electron-transport layer in the light-receiving element. A layer shared by the light-receiving element and the light-emitting element may have the same functions in the light-emitting element and the light-receiving element. A hole-transport layer functions as a hole-transport layer in both of the light-emitting element and the light-receiving element, and an electron-transport layer functions as an electron-transport layer in both of the light-emitting element and the light-receiving element.

In one embodiment of the present invention, organic EL elements are used as the light-emitting elements, and organic photodiodes are used as the light-receiving elements. The organic EL elements and the organic photodiodes can be formed over the same substrate. Thus, the organic photodiodes can be incorporated in a display apparatus including the organic EL elements.

When the light-receiving element is driven by application of reverse bias between the pixel electrode and the common electrode, light entering the light-receiving element can be detected and charge can be generated and extracted as current.

The light-receiving element 110S includes the pixel electrode 111S, the PS layer 155S, and the common electrode 113. In the structures illustrated in FIG. 2B and the like, the light-receiving element 110S includes the common layer 114 between the PS layer 155S and the common electrode 113.

The PS layer 155S includes at least a photoelectric conversion layer (also referred to as an active layer). Examples of layers included in the PS layer 155S (also referred as functional layers) include a photoelectric conversion layer, carrier-injection layers (a hole-injection layer and an electron-injection layer), carrier-transport layers (a hole-transport layer and an electron-transport layer), and carrier-blocking layers (a hole-blocking layer and an electron-blocking layer).

The photoelectric conversion layer includes a semiconductor. Examples of the semiconductor include an inorganic semiconductor such as silicon and an organic semiconductor including an organic compound. As the semiconductor included in the photoelectric conversion layer, an organic semiconductor can be used, for example. The use of an organic semiconductor is preferable because the light-emitting layer and the photoconversion layer can be formed by the same method (e.g., a vacuum evaporation method) and thus a manufacturing apparatus can be shared. As the photoelectric conversion layer, a pn photodiode or a pin photodiode can be used, for example.

For the pixel electrode 111S, any of the materials and structures described as for the pixel electrode 111R, the pixel electrode 111G, the pixel electrode 111B, and the like can be used.

The combination of colors of light emitted by the light-emitting elements 110 is not limited to the above examples, and cyan, magenta, yellow, or the like may also be used. Although the example of three colors of red (R), green (G), and blue (B) is shown in the above, the number of colors of light emitted by the light-emitting elements 110 included in the display apparatus 100A may be two or four or more.

The pixel electrode 111 functions as a lower electrode and the common electrode 113 functions as an upper electrode. The common electrode 113 has a transmissive property and a reflective property with respect to visible light. The organic layer 112 contains a light-emitting compound.

As the light-emitting element 110, it is possible to use an electroluminescent element having a function of emitting light in accordance with current flowing into the organic layer 112 when a potential difference is applied between the pixel electrode 111 and the common electrode 113. In particular, an organic EL element using a light-emitting organic compound is preferably used for the organic layer 112. In addition, the light-emitting element 110 is preferably an element emitting monochromatic light the emission spectrum of which has one peak in the visible light region. Note that the light-emitting element 110 may be an element emitting white light the emission spectrum of which has two or more peaks in the visible light region.

A potential for controlling the amount of light emitted from the light-emitting element 110 is independently applied to the pixel electrode 111 provided in each of the light-emitting elements 110.

The organic layer 112 and the common layer 114 can each independently include one or more of an electron-injection layer, an electron-transport layer, a hole-injection layer, and a hole-transport layer. For example, it is possible to employ a structure in which the organic layer 112 has a stacked-layer structure of a hole-injection layer, a hole-transport layer, a light-emitting layer, and an electron-transport layer from the pixel electrode 111 side and the common layer 114 includes an electron-injection layer.

The common electrode 113 is formed to have a transmissive property and a reflective property with respect to visible light. For example, a metal film or an alloy film that is thin enough to transmit visible light can be used. Alternatively, a light-transmitting conductive film (e.g., a metal oxide film) may be stacked over such a film.

In the cross-sectional view of FIG. 2A, the end portion of the organic layer 112 is located outward from the end portion of the pixel electrode 111. The end portion of the organic layer 112 covers the end portion of the pixel electrode 111. The end portion of the organic layer 112 is located outward from the end portion of the pixel electrode 111, whereby a short circuit between the pixel electrode 111 and the common electrode 113 can be inhibited.

In the cross-sectional view of FIG. 2B, the end portion of the PS layer 155S is located outward from the end portion of the pixel electrode 111. The end portion of the PS layer 155S covers the end portion of the pixel electrode 111. The end portion of the PS layer 155S is located outward from the end portion of the pixel electrode 111, whereby a short circuit between the pixel electrode 111 and the common electrode 113 can be inhibited.

The insulating layer 105 includes a depressed portion 175. The depressed portion 175 is provided in the insulating layer 105 in a region located between two pixel electrodes 111 that are adjacent to each other in the A1-A2 direction illustrated in FIG. 1. The depressed portion 175 is also provided in the insulating layer 105 in a region located between two pixel electrodes 111 that are adjacent to each other in the B1-B2 direction. The depressed portion 175 can be expressed as a group of depressed portions. Alternatively, the depressed portion 175 can be expressed as a group of grooves, and one groove is provided between adjacent pixel electrodes 111, for example.

The depressed portion 175 includes a groove-like region. The depressed portion 175 includes a groove-like region provided along a side of the pixel electrode 111 in a top view, for example. The depressed portion 175 in the groove-like region includes a region overlapping with the pixel electrode 111, which is inward from the side of the pixel electrode 111 in the top view. When the depressed portion 175 includes a region overlapping with the pixel electrode inside the pixel electrode, for example, the organic layer 112 can be disconnected in the region that is inward from the side below the pixel electrode 111 at the time of forming the organic layer 112.

As illustrated in FIG. 1 and FIG. 2A, the depressed portion 175 is provided in a region of the insulating layer 105 located between the light-emitting element 110R and the light-emitting element 110G, the depressed portion 175 is provided in a region of the insulating layer 105 located between the light-emitting element 110G and the light-emitting element 110B, and the depressed portion 175 is provided in a region of the insulating layer 105 located between the light-emitting element 110B and the light-emitting element 110R. Furthermore, as illustrated in FIG. 1 and FIG. 2B, the depressed portion 175 is provided in a region of the insulating layer 105 located between the light-emitting element 110G and the light-receiving element 110S.

As illustrated in FIG. 1, in the top view of the display apparatus 100A, the direction in which the light-emitting element 110R, the light-emitting element 110G, and the light-emitting element 110B are arranged in this order is the x direction, and the direction perpendicular to the x direction is the y direction. The depressed portion 175 can be expressed as a group of linear-shaped grooves extending in the x direction and linear-shaped grooves extending in the y direction.

Part of the depressed portion 175 is preferably located below the pixel electrode 111. In other words, the depressed portion 175 preferably includes a region located below the pixel electrode 111.

For example, in the depressed portion 175 located between a first pixel electrode and a second pixel electrode, the depressed portion 175 preferably includes a first region overlapping with the first pixel electrode, a second region overlapping with the second pixel electrode, and a third region overlapping with neither the first pixel electrode nor the second pixel electrode. The third region is located between the first region and the second region. The first region can be regarded as being located below the first pixel electrode. The second region can be regarded as being located below the second pixel electrode. Note that a light-emitting element including the first pixel electrode and a light-emitting element including the second pixel electrode emit light of different colors. Alternatively, the first pixel electrode is included in a light-emitting element, and the second pixel electrode is included in a light-receiving element.

The depressed portion 175 has a downward-convex shape in a cross-sectional view of the display apparatus 100A. The depressed portion 175 has a downward-convex arc shape, for example. Alternatively, the depressed portion 175 may include, for example, a region with a downward-convex arc shape and a region with a flat shape. For example, the sidewall of the depressed portion 175 may have a downward-convex arc shape, and the bottom surface thereof may have a flat shape.

There is no particular limitation on the shape of the depressed portion 175 as long as part of the depressed portion 175 is located below the pixel electrode 111. For example, in the cross-sectional view of the display apparatus, the depressed portion 175 may have a downward-convex arc shape or may have a shape with a flat bottom surface and a downward-convex arc side wall.

The shape of the depressed portion 175 is not limited to those described above. For example, the depressed portion 175 does not necessarily include a region located below the pixel electrode 111 in some cases. For example, the depressed portion 175 may have a cross-like shape, a T-like shape, or an inverse T-like shape in the cross-sectional view of the display apparatus.

Note that the downward-convex arc shape can also be referred to as a concave curved shape. Furthermore, the downward-convex arc shape includes a downward-convex semicircular shape.

When the depressed portion 175 is provided, the organic layer 112 included in the light-emitting element 110 can be cut between the light-emitting element 110 and the adjacent light-emitting element 110 or between the light-emitting element 110 and the adjacent light-receiving element 110S. Furthermore, when the depressed portion 175 is provided, the PS layer 155S included in the light-receiving element 110S can be cut between the light-receiving element 110S and the adjacent light-emitting element 110 or between the light-receiving element 110S and the adjacent light-receiving element 110S.

When a film to be the organic layer 112 is formed over the pixel electrode and in the depressed portion 175, for example, the film to be the organic layer 112 is cut in a region of the depressed portion 175 overlapping with the pixel electrode 111. Thus, the film to be the organic layer 112 can be processed into an island shape without using a shadow mask such as a metal mask or using etching, for example.

When a film to be the PS layer 155S is formed over the pixel electrode and in the depressed portion 175, for example, the film to be the PS layer 155S is cut in a region of the depressed portion 175 overlapping with the pixel electrode 111. Thus, the film to be the organic layer 112 can be processed into an island shape without using etching or a shadow mask such as a metal mask, for example.

Note that after the film to be the organic layer 112 and the film to be the PS layer 155S are each cut in the depressed portion 175, part of the film to be the organic layer 112 that remains in the depressed portion 175 and part of the film to be the PS layer 155S that remains in the depressed portion 175 are preferably removed by etching or the like.

In the display apparatus 100A, the organic layer 112 is divided between adjacent light-emitting elements, between a light-emitting element and a light-receiving element that are adjacent to each other, or between adjacent light-receiving elements. Accordingly, current (leakage current) flowing between the adjacent light-emitting elements through the organic layer 112 can be prevented. Thus, light emission caused by the leakage current can be inhibited, so that display with high contrast can be obtained. Furthermore, even in the case where the resolution is increased, the range of choices for materials can be widened since the organic layer 112 can be formed using a material with high conductivity, which facilitates an improvement in efficiency, a reduction in power consumption, and an improvement in reliability.

Each of the organic layer 112 and the PS layer 155S may be patterned into an island shape by film formation with use of a shadow mask such as a metal mask; however, it is particularly preferable to employ a processing method using no metal mask. Accordingly, an extremely fine pattern can be formed; thus, resolution and an aperture ratio can be improved as compared to the formation method using a metal mask. A typical example of such a processing method is a photolithography method. Alternatively, a formation method such as a nanoimprinting method or a sandblasting method can be used.

In this specification and the like, a device manufactured using a metal mask or an FMM (a fine metal mask or a high-resolution metal mask) is sometimes referred to as a device having an MM (metal mask) structure. In this specification and the like, a device formed without using a metal mask or an FMM may be referred to as a device having an MML (metal maskless) structure.

The display apparatus 100A includes an insulating layer 118a over the organic layer 112R, an insulating layer 118b over the organic layer 112G, an insulating layer 118c over the organic layer 112B, the insulating layer 118d over the PS layer 155S, an insulating layer 125, and a resin layer 126.

In the following description common to the insulating layer 118a, the insulating layer 118b, the insulating layer 118c, and the insulating layer 118d, the alphabets added to the reference numerals are omitted and the term “insulating layer 118” is used in the description in some cases.

The insulating layer 118 is provided to cover at least part of the top surface of the organic layer 112 or the PS layer 155S. The insulating layer 118 is provided to overlap with at least part of the depressed portion 175. As illustrated in FIG. 2A, the insulating layer 118a over the organic layer 112R is provided to overlap with at least part of the depressed portion 175, the insulating layer 118b over the organic layer 112G is provided to overlap with at least part of the depressed portion 175, and the insulating layer 118c over the organic layer 112B is provided to overlap with at least part of the depressed portion 175. As illustrated in FIG. 2B, the insulating layer 118d over the PS layer 155S is provided to overlap with at least part of the depressed portion 175.

The insulating layer 118 includes a region in contact with at least part of the top surface of the organic layer 112 (the PS layer 155S) and a region in contact with the side surface of the organic layer 112 (the PS layer 155S). The insulating layer 118 includes a region in contact with the insulating layer 105 below the light-emitting element 110 (the light-receiving element 110S), specifically, the pixel electrode 111. The insulating layer 118 includes a region in contact with the bottom surface of the insulating layer 106. Here, with high adhesion between the insulating layer 106 and the insulating layer 118, the insulating layer 118 can be inhibited from being separated from the organic layer 112 (the PS layer 155S) and the organic layer 112 (the PS layer 155S) can be inhibited from being separated from the pixel electrode 111. Furthermore, with high adhesion between the insulating layer 105 and the insulating layer 118, the insulating layer 118 can be inhibited from being separated from the organic layer 112 (the PS layer 155S) and the organic layer 112 (the PS layer 155S) can be inhibited from being separated from the pixel electrode 111. Inhibiting film separation can improve a yield in the manufacturing process of the display apparatus. In addition, the display quality of the display apparatus can be increased. The adhesion between the insulating layer 105 and the insulating layer 118 is preferably higher than the adhesion between the insulating layer 118 and the organic layer 112. The adhesion between the insulating layer 105 and the insulating layer 118 is preferably higher than the adhesion between the insulating layer 118 and the PS layer 155S.

In the case of using an organic insulating film as the insulating layer 105, an acrylic resin, a polyimide resin, an epoxy resin, an imide resin, a polyamide resin, a polyimide-amide resin, a silicone resin, a siloxane resin, a benzocyclobutene-based resin, a phenol resin, a precursor of any of these resins, or the like can be used. For the insulating layer 105, an organic material such as polyvinyl alcohol (PVA), polyvinylbutyral, polyvinylpyrrolidone, polyethylene glycol, polyglycerin, pullulan, water-soluble cellulose, or an alcohol-soluble polyamide resin may be used. Here, in the formation of the insulating layer 105, baking (heating treatment) is preferably performed after a resin is applied. The baking is preferably performed in a reduction atmosphere and can be performed in a nitrogen atmosphere, for example.

In the case of using an acrylic resin for the insulating layer 105, the baking temperature is preferably higher than or equal to 125° C., further preferably higher than or equal to 150° C., still further preferably higher than or equal to 200° C., for example. By performing the baking at such a temperature, the adhesion between the insulating layer 105 and the insulating layer 118 is increased in some cases.

Note that a baking temperature in the formation of the resin layer 126 described later is lower than the baking temperature in the formation of the insulating layer 105 in some cases. The baking temperature in the formation of the resin layer 126 is preferably lower than or equal to 200° C., further preferably lower than or equal to 150° C., still further preferably lower than or equal to 125° C., for example.

As illustrated in FIG. 2A, the insulating layer 118a includes a region in contact with at least part of the top surface of the organic layer 112R, a region in contact with the side surface of the organic layer 112R, and a region in contact with the insulating layer 105 below the pixel electrode 111R. The insulating layer 118a includes a region in contact with the bottom surface of the insulating layer 106. The insulating layer 118b includes a region in contact with at least part of the top surface of the organic layer 112G, a region in contact with the side surface of the organic layer 112G, and a region in contact with the insulating layer 105 below the pixel electrode 111G. The insulating layer 118b includes a region in contact with the bottom surface of the insulating layer 106. The insulating layer 118c includes a region in contact with at least part of the top surface of the organic layer 112B, a region in contact with the side surface of the organic layer 112B, and a region in contact with the insulating layer 105 below the pixel electrode 111B. The insulating layer 118c includes a region in contact with the bottom surface of the insulating layer 106.

As illustrated in FIG. 2B, the insulating layer 118d includes a region in contact with at least part of the top surface of the PS layer 155S, a region in contact with the side surface of the PS layer 155S, and a region in contact with the insulating layer 105 below the pixel electrode 111S.

The insulating layer 118 includes an opening portion reaching the organic layer 112 (the PS layer 155S). In the opening portion, the organic layer 112 (the PS layer 155S) is in contact with the common layer 114. The common electrode 113 includes a region overlapping with the organic layer 112 (the PS layer 155S) through the opening portion.

The insulating layer 118 includes a region located between the resin layer 126 and the organic layer 112 (the PS layer 155S) and functions as a protective film for preventing contact between the resin layer 126 and the organic layer 112 (the PS layer 155S). When the organic layer 112 (the PS layer 155S) and the resin layer 126 are in contact with each other, the organic layer 112 (the PS layer 155S) might be dissolved by an organic solvent or the like used at the time of forming the resin layer 126. Therefore, the insulating layer 118 is provided between the organic layer 112 (the PS layer 155S) and the resin layer 126 as described in this embodiment to protect the side surface of the organic layer 112 (the PS layer 155S).

The insulating layer 118 can be an insulating layer containing an inorganic material. As the insulating layer 118, an inorganic insulating film such as an oxide insulating film, a nitride insulating film, an oxynitride insulating film, or a nitride oxide insulating film can be used, for example. The insulating layer 118 may have a single-layer structure or a stacked-layer structure. Examples of the oxide insulating film include a silicon oxide film, an aluminum oxide film, a magnesium oxide film, an indium gallium zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. In particular, a metal oxide film such as an aluminum oxide film or a hafnium oxide film, or an inorganic insulating film such as a silicon oxide film, which is formed by an ALD method, is used for the insulating layer 118, whereby the insulating layer 118 can have few pinholes and an excellent function of protecting the organic layer 112.

Note that in this specification and the like, oxynitride refers to a material that contains more oxygen than nitrogen in its composition, and nitride oxide refers to a material that contains more nitrogen than oxygen in its composition. For example, in the case where silicon oxynitride is described, it refers to a material that contains more oxygen than nitrogen in its composition. In the case where silicon nitride oxide is described, it refers to a material that contains more nitrogen than oxygen in its composition.

The insulating layer 118 may function as a protective layer that prevents diffusion of impurities such as water into the organic layer 112 and the PS layer 155S. As the insulating layer 118, it is preferable to use an inorganic insulating film with low moisture permeability, such as a silicon oxide film, a silicon nitride film, or an aluminum oxide film. When aluminum oxide is used for the insulating layer 118, the insulating layer 118 contains aluminum and oxygen.

The insulating layer 118 can be formed by a sputtering method, a CVD method, a PLD method, an ALD method, or the like. The insulating layer 118 is preferably formed by an ALD method achieving good coverage.

The thickness of the insulating layer 118 is preferably greater than or equal to 3 nm, greater than or equal to 5 nm, or greater than or equal to 10 nm and less than or equal to 200 nm, less than or equal to 150 nm, less than or equal to 100 nm, or less than or equal to 50 nm, for example.

Between two adjacent light-emitting elements of different colors, side surfaces of the organic layers 112 are provided to face each other with the resin layer 126 therebetween. The resin layer 126 is positioned between the two adjacent light-emitting elements of different colors and is provided to fill end portions of the organic layers 112 and a region between the two organic layers 112.

In a light-emitting element and a light-receiving element that are adjacent to each other, a side surface of the organic layer 112 included in the light-emitting element and a side surface of the PS layer 155S included in the light-receiving element face each other with the resin layer 126 therebetween. The resin layer 126 is located between the light-emitting element and the light-receiving element that are adjacent to each other to fill a region between an end portion of the organic layer 112 and an end portion of the PS layer 155S and a region between the organic layer 112 and the PS layer 155S.

In the case where the display apparatus of one embodiment of the present invention has a structure in which light-receiving elements are adjacent to each other, side surfaces of the PS layers 155S in the adjacent light-receiving elements are provided to face each other with the resin layer 126 therebetween. The resin layer 126 is located between the two adjacent light-receiving elements and is provided to fill end portions of the PS layers 155S and a region between the two PS layers 155S.

The resin layer 126 has a top surface with a smooth convex shape. The common layer 114 and the common electrode 113 are provided to cover the top surface of the resin layer 126.

For example, between adjacent light-emitting elements and between a light-emitting element and a light-receiving element that are adjacent to each other, the resin layer 126 includes a region in contact with the insulating layer 105. For example, the resin layer 126 includes a region in contact with the insulating layer 105 in a portion located between the organic layer 112R and the organic layer 112G. The resin layer 126 includes a region in contact with the insulating layer 105 in a portion located between the organic layer 112G and the organic layer 112B. The resin layer 126 includes a region in contact with the insulating layer 105 in a portion located between the organic layer 112B and the organic layer 112R. The resin layer 126 includes a region in contact with the insulating layer 105 in a portion located between the PS layer 155S and the organic layer 112.

The resin layer 126 functions as a planarization film that fills a step located between adjacent light-emitting elements, a step located between a light-emitting element and a light-receiving element that are adjacent to each other, and the like. Providing the resin layer 126 can inhibit a phenomenon in which the common electrode 113 is divided by a step at an end portion of the organic layer 112 and a step at an end portion of the PS layer 155S (such a phenomenon is also referred to as disconnection) and can prevent insulation of the common electrode 113 over the organic layer 112. The resin layer 126 can be also referred to as LFP (Local Filling Planarization).

An insulating layer containing an organic material can be suitably used as the resin layer 126. For the resin layer 126, an acrylic resin, a polyimide resin, an epoxy resin, an imide resin, a polyamide resin, a polyimide-amide resin, a silicone resin, a siloxane resin, a benzocyclobutene-based resin, a phenol resin, a precursor of these resins, or the like can be used, for example. For the resin layer 126, an organic material such as polyvinyl alcohol (PVA), polyvinylbutyral, polyvinylpyrrolidone, polyethylene glycol, polyglycerin, pullulan, water-soluble cellulose, or an alcohol-soluble polyamide resin may be used.

Alternatively, a photosensitive resin can be used for the resin layer 126. A photoresist may be used for the photosensitive resin. As the photosensitive resin, a positive photosensitive material or a negative photosensitive material can be used.

The resin layer 126 may contain a material absorbing visible light. For example, the resin layer 126 itself may be made of a material absorbing visible light, or the resin layer 126 may contain a pigment absorbing visible light. For example, for the resin layer 126, it is possible to use a resin that can be used as a color filter transmitting red, blue, or green light and absorbing other light, a resin that contains carbon black as a pigment and functions as a black matrix, or the like.

The insulating layer 125 is provided between the resin layer 126 and the insulating layer 118a, between the resin layer 126 and the insulating layer 118b, and between the resin layer 126 and the insulating layer 118c. An opening portion reaching the organic layer 112 (the PS layer 155S) is provided in the insulating layer 125. Note that the insulating layer 125 is not necessarily provided in the display apparatus 100A.

The protective layer 121 is provided to cover the common electrode 113.

The protective layer 121 can have, for example, a single-layer structure or a stacked-layer structure including at least an inorganic insulating film. Examples of the inorganic insulating film include an oxide film or a nitride film, such as a silicon oxide film, a silicon oxynitride film, a silicon nitride oxide film, a silicon nitride film, an aluminum oxide film, an aluminum oxynitride film, and a hafnium oxide film. Alternatively, a semiconductor material or a conductive material such as indium gallium oxide, indium zinc oxide, indium tin oxide, or indium gallium zinc oxide may be used for the protective layer 121.

As the protective layer 121, a stacked film of an inorganic insulating film and an organic insulating film can be used. For example, a structure in which an organic insulating film is sandwiched between a pair of inorganic insulating films is preferable. Furthermore, the organic insulating film preferably functions as a planarization film. This enables a top surface of the organic insulating film to be flat, which results in improved coverage with the inorganic insulating film thereover and a higher barrier property. Moreover, the top surface of the protective layer 121 is flat, which is preferable because the influence of an uneven shape due to a lower structure can be reduced in the case where a component (e.g., a color filter, an electrode of a touch sensor, a lens array, or the like) is provided above the protective layer 121.

Although not illustrated in FIG. 2B, it is preferable that the common electrode 113 extend to a region outside the end portion of the depressed portion 175.

With such a structure, the EL layers can be separately provided in the light-emitting elements 110 emitting different colors, whereby color display with high color reproducibility can be performed with low power consumption.

A circuit substrate including a transistor, a wiring, and the like can be used as the substrate 101. Note that in the case where either a passive matrix method or a segment method can be employed, an insulating substrate such as a glass substrate can be used as the substrate 101. The substrate 101 is a substrate provided with a circuit for driving the light-emitting elements (also referred to as a pixel circuit) or a semiconductor circuit functioning as a driver circuit for driving the pixel circuit. More specific structure examples of the substrate 101 will be described later.

The substrate 101 and the pixel electrode 111 of the light-emitting element 110 are electrically connected to each other through a conductive layer.

A width W1 illustrated in FIG. 2A is a width of the depressed portion 175 in a region not overlapping with the pixel electrode 111 in the A1-A2 direction. Note that in the display apparatus 100A illustrated in FIG. 2A, the width W1 can be referred to as the shortest distance between the end portions of the pixel electrodes 111 facing each other. A width W2 illustrated in FIG. 2A is a width of the depressed portion 175 in a region overlapping with the pixel electrode 111 in the A1-A2 direction.

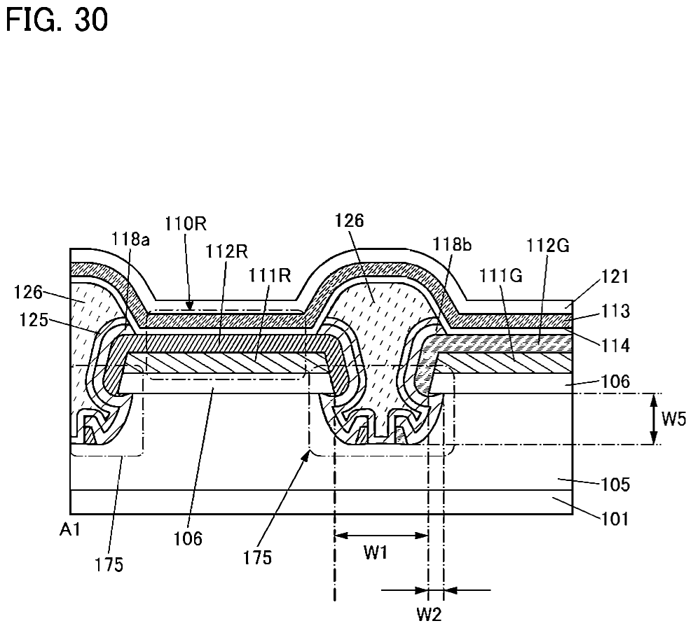

FIG. 30 is an enlarged view of a region including the width W1 and the width W2 in FIG. 2A. A depth W5 of the depressed portion 175 is illustrated in FIG. 30. The depth W5 is a difference between the height of the bottom portion of the depressed portion 175 and the height of the top surface of the insulating layer 105, for example. Note that the width W1, the width W2, and the height of the bottom portion of the depressed portion 175 and the height of the top surface of the insulating layer 105 can each be measured in a cross-sectional observation image of the display apparatus 100A, for example. The cross-sectional observation image can be obtained with a TEM (Transmission Electron Microscope), a STEM (Scanning Transmission Electron Microscope), or the like, for example. For measurement in the cross-sectional observation image, a cross section is exposed by processing, and a height in an observation area can be used. The height of the bottom portion of the depressed portion 175 may be calculated by averaging heights in the observation area, for example. Alternatively, the height of the bottom portion of the depressed portion 175 may be obtained by measuring the deepest point of the depressed portion 175 in the observed region. The height of the top surface of the insulating layer 105 may be calculated by averaging heights in the observation area, for example. Alternatively, the height of the top surface of the insulating layer 105 may be obtained by measuring the highest point of the top surface of the insulating layer 105 in the observed region.

In the case where a plurality of depressed portions 175 are observed in the observation area, the average value, the maximum value, the minimum value, the median value, or the like of the plurality of depressed portions 175 may be used as each of the width W1, the width W2, the depth W5, and the like of the depressed portion.

The width W1 is preferably greater than twice the thickness of the organic layer 112 (the PS layer 155S). For example, in the case where the thickness of the organic layer 112 (the PS layer 155S) is 100 nm, the width W1 is greater than or equal to 200 nm and less than or equal to 1200 nm, preferably greater than or equal to 200 nm and less than or equal to 1000 nm, further preferably greater than or equal to 200 nm and less than or equal to 900 nm. Thus, disconnection occurs in the organic layer 112 (the PS layer 155S) owing to the depressed portion 175, whereby the organic layer 112 (the PS layer 155S) can be formed over the pixel electrode 111. At that time, as illustrated in FIG. 2A, the organic layer 112 (the PS layer 155S) is provided to cover the side surface and the top surface of the pixel electrode 111. Note that in this specification and the like, “a layer covers a component” refers to a state where the layer covers part of the end surface of the component or a state where the layer completely covers the end surface of the component. Here, the layer refers to an insulating layer, an insulating film, a conductive layer, or the like. The component refers to a conductive layer, an organic layer, a stacked body, a light-emitting element, or the like.

Note that the width W1 is preferably adjusted as appropriate in accordance with processing accuracy at the time of forming the depressed portion 175, deposition conditions of the organic layer 112 (the PS layer 155S), or the like. In the case where the organic layer 112 (the PS layer 155S) is deposited by a vacuum evaporation method, for example, even when the width W1 is less than twice the thickness of the organic layer 112 (the PS layer 155S), disconnection sometimes occurs in the organic layer 112 (the PS layer 155S). For example, in the case where the thickness of the organic layer 112 (the PS layer 155S) is 100 nm, the width W1 may be greater than or equal to 100 nm and less than or equal to 1200 nm, less than or equal to 1000 nm, or less than or equal to 900 nm.

The width W2 is set as such a width that disconnection occurs in the organic layer 112 (the PS layer 155S). The width W2 is preferably greater than or equal to 2 nm, greater than or equal to 5 nm, greater than or equal to 10 nm, greater than or equal to 20 nm, greater than or equal to 30 nm, greater than or equal to 40 nm, or greater than or equal to 50 nm. Increasing the width W2 can cause disconnection in the organic layer 112. In addition, increasing the width W2 can increase adhesion owing to an anchoring effect of the organic layer 112. In the case where the width W2 is too large, the aperture ratio of the display apparatus may be reduced. Therefore, the width W2 is preferably less than or equal to 500 nm, less than or equal to 300 nm, less than or equal to 200 nm, less than or equal to 150 nm, or less than or equal to 100 nm.

The width W2 is preferably greater than or equal to 20 nm and less than or equal to 500 nm, further preferably greater than or equal to 30 nm and less than or equal to 300 nm, still further preferably greater than or equal to 40 nm and less than or equal to 200 nm, yet still further preferably greater than or equal to 50 nm and less than or equal to 150 nm, and for example, preferably approximately 90 nm. When the width W2 is within a suitable range, disconnection can be caused in the organic layer 112 while the aperture ratio is kept high even in a high-resolution display, part of the insulating layer 118 can be in contact with the bottom surface of the insulating layer 106 and the side surface of the insulating layer 105, and the insulating layer 118 can be suitably inhibited from being separated from the organic layer 112 (the PS layer 155S). Furthermore, adhesion can be increased owing to the anchoring effect of the organic layer 112.

Note that the width W1, the width W2, and the depth W5 can be measured using a cross-sectional image of the display apparatus observed with an electron microscope or the like, for example. The cross section subjected to observation is preferably substantially perpendicular to a side of the pixel electrode 111 in a top view. In that case, the cross section is processed to be substantially perpendicular to the side in a region where the side is substantially linear, and then the cross section is observed.

In a region where the depressed portion 175 is provided in a groove-like shape, the width W1 and the width W2 are measured in the width direction of the groove.

The depth W5 is, for example, greater than or equal to 20 nm, greater than or equal to 50 nm and less than or equal to 3000 nm, greater than or equal to 100 nm and less than or equal to 2000 nm, or greater than or equal to 200 nm and less than or equal to 1000 nm.

In the display apparatus of one embodiment of the present invention, the width W2 is set as the above width, whereby disconnection can be favorably caused in the organic layer 112. Furthermore, when the width W2 is set as the above width, the organic layer 112 can be favorably disconnected even in the case where one or more of the insulating layer 106 and the pixel electrode 111 have a tapered shape.

In the display apparatus of one embodiment of the present invention, when part of the insulating layer 118 is in contact with the bottom surface of the insulating layer 106 and the side surface of the insulating layer 105, the organic layer 112 can be sealed with the pixel electrode 111, the insulating layer 118, the insulating layer 106, and the insulating layer 105. Note that the sealing is performed in a peripheral region of the pixel electrode 111. Thus, the sealing can be performed more favorably when the perimeter of the pixel electrode is sufficiently large with respect to the area of the pixel electrode 111 in a plan view. Thus, in the higher-resolution display apparatus with the pixel electrode 111 having a smaller area, the sealing can be performed more favorably. For example, the sealing can be performed more favorably in some cases when the resolution is greater than or equal to 400 ppi, preferably greater than or equal to 600 ppi.

Accordingly, it is possible to achieve an extremely high-resolution display apparatus in which pixels including one or more light-emitting elements are arranged with a resolution greater than or equal to 2000 ppi, preferably greater than or equal to 3000 ppi, further preferably greater than or equal to 5000 ppi, still further preferably greater than or equal to 6000 ppi, and less than or equal to 20000 ppi or less than or equal to 30000 ppi.

In addition, a microcavity structure can be given when the thickness of the EL layer in the light-emitting element 110 is adjusted in accordance with a peak wavelength of an emission spectrum, so that a high luminance display apparatus can be achieved. Moreover, the light-emitting elements 110 can be arranged extremely densely. For example, a display apparatus having resolution exceeding 2000 ppi can be achieved.

To achieve a microcavity structure, the thickness of the EL layer included in the light-emitting element 110 is adjusted in accordance with a peak wavelength of the emission spectrum in some cases. For example, the organic layer 112R included in the light-emitting element 110R emitting light with the longest wavelength has the largest thickness, and the organic layer 112B included in the light-emitting element 110B emitting light with the shortest wavelength has the smallest thickness. Without limitation to this, the thickness of each organic layer can be adjusted in consideration of the wavelength of light emitted by the light-emitting element, the optical characteristics of the layer included in the light-emitting element, the electrical characteristics of the light-emitting element, and the like.

In the above description, the width W1 is preferably larger than twice the thickness of the organic layer 112 (the PS layer 155S) having the smallest thickness, further preferably larger than twice the thickness of the organic layer 112 (the PS layer 155S) having the largest thickness. Thus, disconnection occurs in the organic layer 112 (the PS layer 155S) owing to the depressed portion 175, whereby the organic layer 112 (the PS layer 155S) can be formed over the pixel electrode 111. Furthermore, a microcavity structure can be obtained.

A width W3 illustrated in FIG. 2B is a width of the depressed portion 175 in a region not overlapping with the pixel electrode 111 in the B1-B2 direction. Note that in the display apparatus 100A illustrated in FIG. 2B, the width W3 can also be referred to as the shortest distance between the end portions of the pixel electrodes 111 facing each other. A width W4 illustrated in FIG. 2B is a width of the depressed portion 175 in a region overlapping with the pixel electrode 111 in the B1-B2 direction.

For the width W3, the description of the width W1 can be referred to. For the width W4, the description of the width W2 can be referred to.

### [Components]

### [Light-Emitting Element]

As a light-emitting element that can be used as the light-emitting element 110, a self-luminous element can be used, and an element whose luminance is controlled by current or voltage is included in the category. For example, an LED, an organic EL element, an inorganic EL element, or the like can be used. In particular, an organic EL element is preferably used.

The light-emitting element has a top-emission structure, a bottom-emission structure, a dual-emission structure, or the like. A conductive film that transmits visible light is used as an electrode through which light is extracted. A conductive film that reflects visible light is used as an electrode through which no light is extracted.

In one embodiment of the present invention, a top-emission light-emitting element in which light is emitted to the opposite side of the formation surface or a dual-emission light-emitting element can be particularly suitably used.

The organic layer 112 includes at least a light-emitting layer. In addition to the light-emitting layer, the organic layer 112 may further include a layer containing any of a substance having a high hole-injection property, a substance having a high hole-transport property, a hole-blocking material, a substance having a high electron-transport property, a substance having a high electron-injection property, an electron-blocking material, a substance having a bipolar property (a substance having a high electron-transport property and a high hole-transport property), and the like.

Either a low molecular compound or a high molecular compound can be used for the organic layer 112, and an inorganic compound may also be contained. The layers that constitute the organic layer 112 can each be formed by a method such as an evaporation method (including a vacuum evaporation method), a transfer method, a printing method, an inkjet method, or a coating method.

When a voltage higher than the threshold voltage of the light-emitting element 110 is applied between a cathode and an anode, holes are injected to the organic layer 112 from the anode side and electrons are injected to the organic layer 112 from the cathode side. The injected electrons and holes are recombined in the organic layer 112 and a light-emitting substance contained in the organic layer 112 emits light.

In the case where a light-emitting element emitting white light is used as the light-emitting element 110, the organic layer 112 preferably contains two or more kinds of light-emitting substances. For example, a white light emission can be obtained by selecting light-emitting substances such that two or more light-emitting substances emit light of complementary colors. For example, it is preferable to contain two or more of light-emitting substances emitting light of R (red), G (green), B (blue), Y (yellow), O (orange), and the like or light-emitting substances emitting light containing two or more of spectral components of R, G, and B. A light-emitting element whose emission spectrum has two or more peaks in the wavelength range of a visible light region (e.g., 350 nm to 750 nm) is preferably employed. An emission spectrum of a material emitting light having a peak in a yellow wavelength range preferably includes spectral components also in green and red wavelength ranges.

The organic layer 112 preferably has a structure in which a light-emitting layer containing a light-emitting material emitting light of one color and a light-emitting layer containing a light-emitting material emitting light of another color are stacked. For example, the plurality of light-emitting layers in the organic layer 112 may be stacked in contact with each other or may be stacked with a region not including any light-emitting material therebetween. For example, between a fluorescent light-emitting layer and a phosphorescent light-emitting layer, a region that contains the same material as the fluorescent light-emitting layer or the phosphorescent light-emitting layer (for example, a host material or an assist material) and no light-emitting material may be provided. This facilitates the fabrication of the light-emitting element and reduces the drive voltage.

The light-emitting element 110 may be a single element including one EL layer or a tandem element in which a plurality of EL layers are stacked with a charge generation layer therebetween.

A device with a single structure includes one light-emitting unit between a pair of electrodes, and the light-emitting unit preferably includes one or more light-emitting layers. When white light emission is obtained using two light-emitting layers, the two light-emitting layers are selected such that emission colors of the two light-emitting layers are complementary colors. For example, when an emission color of a first light-emitting layer and an emission color of a second light-emitting layer are complementary colors, the light-emitting element can be configured to emit white light as a whole. To obtain white light emission by using three or more light-emitting layers, the light-emitting element is configured to emit white light as a whole by combining emission colors of the three or more light-emitting layers.

A device having a tandem structure includes two or more light-emitting units between a pair of electrodes, and each light-emitting unit preferably includes one or more light-emitting layers. To obtain white light emission, the structure is made such that light from light-emitting layers of the plurality of light-emitting units can be combined to be white light. Note that a structure for obtaining white light emission is similar to a structure in the case of a single structure. In the device having a tandem structure, an intermediate layer such as a charge-generation layer is suitably provided between the plurality of light-emitting units.

The conductive film that can be used for the pixel electrode 111 or the like and transmits visible light can be formed using, for example, indium oxide, indium tin oxide, indium zinc oxide, zinc oxide, or zinc oxide to which gallium is added. Alternatively, a metal material such as gold, silver, platinum, magnesium, nickel, tungsten, chromium, molybdenum, iron, cobalt, copper, palladium, or titanium; an alloy containing any of these metal materials; a nitride of any of these metal materials (e.g., titanium nitride), or the like formed thin enough to have a light-transmitting property can be used. Furthermore, a stacked film of the above materials can be used as a conductive layer. For example, a stacked-layer film of indium tin oxide and an alloy of silver and magnesium is preferably used, in which case conductivity can be increased. Further alternatively, graphene or the like may be used.

For a portion of the pixel electrode 111 that is positioned on the organic layer 112 side, the above conductive film that reflects visible light is preferably used. For the conductive film, for example, a metal material such as aluminum, gold, platinum, silver, nickel, tungsten, chromium, molybdenum, iron, cobalt, copper, or palladium or an alloy containing any of these metal materials can be used. Silver is preferable because of its high reflectance of visible light. Aluminum is preferable because an aluminum electrode is easily etched and thus is easily processed, and aluminum has high reflectance with respect to visible light and near-infrared light. Lanthanum, neodymium, germanium, or the like may be added to the above-described metal material or alloy. An alloy (an aluminum alloy) containing aluminum and titanium, nickel, or neodymium may be used. An alloy containing silver and copper, palladium, or magnesium may be used. An alloy containing silver and copper is preferable because of its high heat resistance.

The pixel electrode 111 may have a structure in which a conductive metal oxide film is stacked over a conductive film that reflects visible light. With such a structure, oxidization, corrosion, or the like of the conductive film reflecting visible light can be inhibited. When a metal film or a metal oxide film is stacked in contact with an aluminum film or an aluminum alloy film, for example, oxidization can be inhibited. Examples of a material for the metal film or the metal oxide film include titanium and titanium oxide. Alternatively, the above conductive film that transmits visible light and a film containing a metal material may be stacked. For example, a stacked-layer film of silver and indium tin oxide or a stacked-layer film of an alloy of silver and magnesium and indium tin oxide can be used.

When aluminum is used for the pixel electrode 111, the thickness of aluminum is preferably larger than or equal to 40 nm, further preferably larger than or equal to 70 nm, in which case the reflectance with respect to visible light or the like can be sufficiently increased. When silver is used for the pixel electrode 111, the thickness of silver is preferably larger than or equal to 70 nm, further preferably larger than or equal to 100 nm, in which case the reflectance with respect to visible light or the like can be sufficiently increased.

As the conductive film having a light-transmitting property and a reflective property that can be used for the common electrode 113, the above conductive film reflecting visible light formed to be thin enough to transmit visible light can be used. In addition, with a stacked-layer structure of the conductive film and the conductive film transmitting visible light, the conductivity, the mechanical strength, or the like can be increased.

The conductive film having a light-transmitting property and a reflective property preferably has a reflectance with respect to visible light (e.g., the reflectance with respect to light having a predetermined wavelength within the range of 400 nm to 700 nm) of higher than or equal to 20% and lower than or equal to 80%, preferably higher than or equal to 40% and lower than or equal to 70%. The conductive film having a reflective property preferably has a reflectance with respect to visible light of higher than or equal to 40% and lower than or equal to 100%, further preferably higher than or equal to 70% and lower than or equal to 100%. The conductive film having a light-transmitting property preferably has a reflectance with respect to visible light of higher than or equal to 0% and lower than or equal to 40%, further preferably higher than or equal to 0% and lower than or equal to 30%.

For the pixel electrode 111 functioning as a lower electrode, for example, a metal material such as gold, silver, platinum, magnesium, nickel, tungsten, chromium, molybdenum, iron, cobalt, copper, palladium, or titanium; an alloy containing any of these metal materials; or a nitride of any of these metal materials (e.g., titanium nitride) can be used.

The electrodes included in the light-emitting elements may each be formed by an evaporation method, a sputtering method, or the like. Alternatively, a discharging method such as an ink-jet method, a printing method such as a screen printing method, or a plating method may be used for the formation.

Note that the aforementioned light-emitting layer and layers containing a substance with a high hole-injection property, a substance with a high hole-transport property, a substance with a high electron-transport property, a substance with a high electron-injection property, a substance with a bipolar property, and the like may include an inorganic compound such as a quantum dot or a high molecular compound (e.g., an oligomer, a dendrimer, and a polymer). For example, when used for a light-emitting layer, the quantum dots can function as a light-emitting material.

As the quantum dot material, a colloidal quantum dot material, an alloyed quantum dot material, a core-shell quantum dot material, a core quantum dot material, or the like can be used. A material containing elements belonging to Group 12 and Group 16, elements belonging to Group 13 and Group 15, or elements belonging to Group 14 and Group 16 may be used. Alternatively, a quantum dot material containing an element such as cadmium, selenium, zinc, sulfur, phosphorus, indium, tellurium, lead, gallium, arsenic, or aluminum may be used.

In each of the light-emitting elements, the optical distance between the surface of the reflective layer reflecting visible light and the common electrode 113 having a light-transmitting property and a reflective property with respect to visible light is preferably adjusted to be m×λ/2 (m is an integer greater than or equal to 1) or in the vicinity thereof, where λ is the wavelength of light whose intensity is desired to be increased.

To be exact, the above-described optical distance depends on a product of the physical distance between the reflective surface of the reflective layer and the reflective surface of the common electrode 113 having a light-transmitting property and a reflective property and the refractive index of a layer provided therebetween, and thus is difficult to adjust precisely. Thus, it is preferable to adjust the optical distance on the assumption that the surface of the reflective layer and the surface of the common electrode 113 having a light-transmitting property and a reflective property are each the reflective surface.

### Manufacturing Method Example

An example of a method for manufacturing the display apparatus of one embodiment of the present invention will be described with reference to drawings.

Note that thin films included in the display apparatus (insulating films, semiconductor films, conductive films, and the like) can be formed by a sputtering method, a chemical vapor deposition (CVD) method, a vacuum evaporation method, a pulsed laser deposition (PLD) method, an atomic layer deposition (ALD) method, or the like. Examples of the CVD method include a plasma-enhanced chemical vapor deposition (PECVD: Plasma Enhanced CVD) method and a thermal CVD method. As an example of the thermal CVD method, a metal organic chemical vapor deposition (MOCVD: Metal Organic CVD) method can be given.

Alternatively, thin films included in the display apparatus (e.g., insulating films, semiconductor films, and conductive films) can be formed by a wet film formation method such as spin coating, dipping, spray coating, ink-jetting, dispensing, screen printing, offset printing, a doctor knife method, slit coating, roll coating, curtain coating, or knife coating.

Thin films included in the display apparatus can be processed by a photolithography method or the like. Besides, a nanoimprinting method, a sandblasting method, a lift-off method, or the like may be used for the processing of the thin films. Alternatively, island-shaped thin films may be directly formed by a film formation method using a shielding mask such as a metal mask.

There are the following two typical examples of photolithography methods. In one of the methods, a resist mask is formed over a thin film that is to be processed, the thin film is processed by etching or the like, and then the resist mask is removed. In the other method, a photosensitive thin film is formed and then processed into a desired shape by light exposure and development.

As the light used for light exposure in the photolithography method, for example, an i-line (with a wavelength of 365 nm), a g-line (with a wavelength of 436 nm), an h-line (with a wavelength of 405 nm), or combined light of any of them can be used. Alternatively, ultraviolet rays, KrF laser light, ArF laser light, or the like can be used. Light exposure may be performed by liquid immersion light exposure technique. As the light used for the light exposure, extreme ultraviolet (EUV) light or X-rays may be used. Furthermore, instead of the light used for light exposure, an electron beam can be used. It is preferable to use extreme ultraviolet light, X-rays, or an electron beam because they can perform extremely fine processing. Note that a photomask is not needed when light exposure is performed by scanning with a beam such as an electron beam.

For processing of the thin film, a dry etching method, a wet etching method, a sandblasting method, or the like can be used. Note that the resist mask can be removed by dry etching treatment such as ashing, wet etching treatment, wet etching treatment after dry etching treatment, or dry etching treatment after wet etching treatment.

For planarization treatment of the thin film, typically, a polishing method such as a chemical mechanical polishing (CMP) method can be suitably used. Alternatively, dry etching treatment or plasma treatment may be used. Note that polishing treatment, dry etching treatment, or plasma treatment may be performed a plurality of times, or these treatments may be performed in combination. In the case where the treatments are performed in combination, the order of steps is not particularly limited and may be set as appropriate depending on the roughness of the surface to be processed.

In order to accurately process the thin film to have a desired thickness, for example, the CMP method is employed. In that case, first, polishing is performed at a constant processing rate until part of the top surface of the thin film is exposed. After that, polishing is performed under a condition with a lower processing rate until the thin film has a desired thickness, so that highly accurate processing can be performed.

Examples of a method for detecting the end of the polishing include an optical method in which the surface to be processed is irradiated with light and a change in the reflected light is detected; a physical method in which a change in the polishing resistance received by the processing apparatus from the surface to be processed is detected; and a method in which a magnetic line is applied to the surface to be processed and a change in the magnetic line due to the generated eddy current is used.

After the top surface of the thin film is exposed, polishing treatment is performed under a condition with a low processing rate while the thickness of the thin film is monitored by an optical method using a laser interferometer or the like, whereby the thickness of the thin film can be controlled with high accuracy. Note that the polishing treatment may be performed a plurality of times until the thin film has a desired thickness, as necessary.

### {Preparation for Substrate 101}

As the substrate 101, a substrate having at least heat resistance high enough to withstand the following heat treatment can be used. In the case where an insulating substrate is used as the substrate 101, a glass substrate, a quartz substrate, a sapphire substrate, a ceramic substrate, or the like can be given. Alternatively, a single crystal semiconductor substrate or a polycrystalline semiconductor substrate using silicon or silicon carbide as a material, a compound semiconductor substrate of silicon germanium or the like, or a semiconductor substrate such as an SOI substrate can be used.

As the substrate 101, it is particularly preferable to use the semiconductor substrate or the insulating substrate over which a semiconductor circuit including a semiconductor element such as a transistor is formed. The semiconductor circuit preferably forms a pixel circuit, a gate line driver circuit (a gate driver), a source line driver circuit (a source driver), or the like. In addition to the above, an arithmetic circuit, a memory circuit, or the like may be formed.

In this embodiment, a substrate including at least a pixel circuit is used as the substrate 101.

### [Formation of Insulating Layer 105, Plug 131, and Pixel Electrode 111]

An insulating film to be the insulating layer 105 is formed over the substrate 101.

### {Formation of Depressed Portion 175}

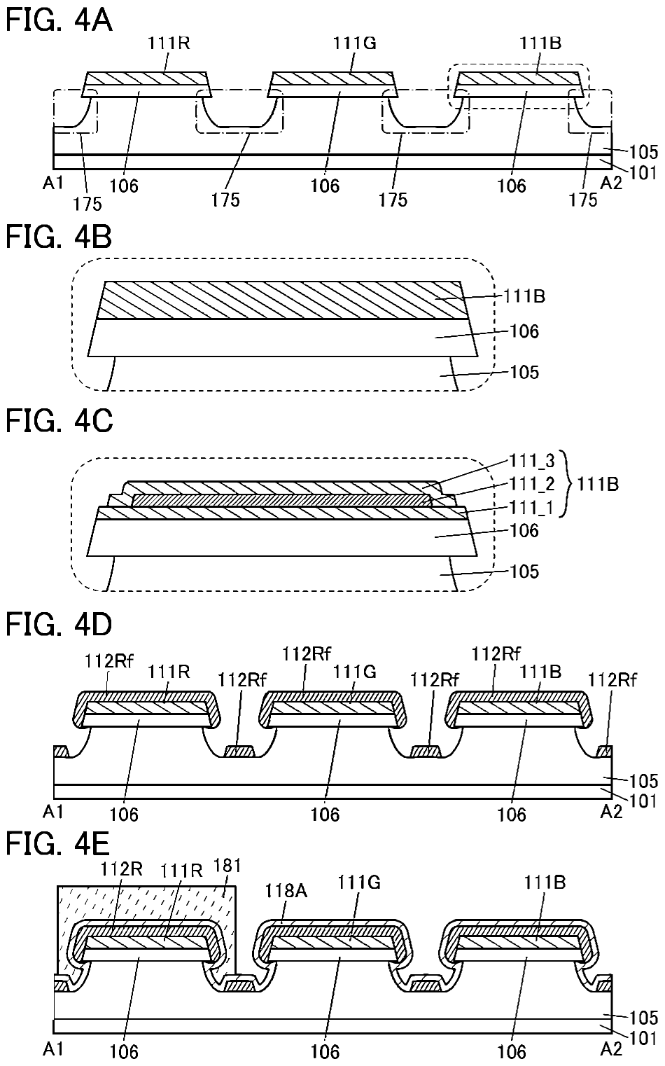

Next, the depressed portion 175 is formed in the insulating layer 105 (FIG. 4A). To form the depressed portion 175, an isotropic etching method can be used. For example, isotropic plasma etching treatment or wet etching treatment can be used. In particular, in the case where an insulating layer containing an organic material is used as the insulating layer 105, isotropic dry etching treatment, plasma treatment, or the like is preferably used. As the plasma treatment, for example, RF plasma treatment using oxygen as a gas can be performed. In the case where an insulating layer containing an inorganic material is used as the insulating layer 105, wet etching treatment is preferably used. Thus, the depressed portion 175 part of which is located below the pixel electrode 111 can be formed.

As illustrated in FIG. 4A, in the case where the insulating layer 106 is provided over the insulating layer 105 and the pixel electrode 111 is formed over the insulating layer 106, it is preferable that an organic insulating film be used as the insulating layer 105 and an inorganic insulating film be used as the insulating layer 106, for example. With such a structure, the depressed portion 175 part of which is located below the insulating layer 106 can be formed in the insulating layer 105 by using isotropic dry etching treatment and using etching conditions where the etching rate of the organic insulating film is higher than that of the inorganic insulating film.

FIG. 4B illustrates an enlarged view of a region surrounded by a dashed line in FIG. 4A. FIG. 4C illustrates an example of the pixel electrode 111 having a shape different from that in FIG. 4B.

The pixel electrode 111 may be a single layer or a stacked-layer film. FIG. 4C illustrates an example of a structure of the case where a stacked-layer film is used as the pixel electrode. The pixel electrode 111 illustrated in FIG. 4C has a stacked-layer structure of a conductive layer 111_1, a conductive layer 111_2 over the conductive layer 111_1, and a conductive layer 111_3 over the conductive layer 111_2. The end portion of the conductive layer 111_2 is located inward from the end portions of the conductive layer 111_1 and the conductive layer 111_3. The side surface of the conductive layer 111_2 is covered with the conductive layer 111_3. Thus, a structure in which the conductive layer 111_2 and the organic layer 112 or the conductive layer 111_2 and the PS layer 155S are not in contact with each other can be obtained.

With the structure illustrated in FIG. 4C, oxidation or the like of the conductive layer 111_2 in a later process can be inhibited. Furthermore, even when selectivity with the conductive layer 111_2 is low in etching of the conductive layer 111_3, the conductive layer 111_2 can be inhibited from receding, and excellent display quality can be achieved in the display apparatus.

Here, for example, a transparent conductive layer can be used as the conductive layer 111_3, and a reflective conductive layer can be used as the conductive layer 111_2.

{Formation of Organic Layer 112R and Insulating Layer 118a}

A film containing a first light-emitting compound is formed over the pixel electrode 111R, the pixel electrode 111G, the pixel electrode 111B, and the insulating layer 105 (FIG. 4D).

The film containing the first light-emitting compound can be formed by an evaporation method, specifically a vacuum evaporation method, for example. Alternatively, the film may be formed by a method such as a transfer method, a printing method, an inkjet method, or a coating method.

At that time, disconnection occurs in the film containing the first light-emitting compound in the depressed portion 175. In FIG. 4D, disconnection occurs in the film in projecting portions of the insulating layer 106. As a result, an organic layer 112Rf is formed over the pixel electrode 111R, the pixel electrode 111G, the pixel electrode 111B, and the insulating layer 105.

Next, an insulating film 118A is formed over the organic layer 112Rf and the insulating layer 105. The insulating film 118A can be formed by a sputtering method, a CVD method, an MBE method, a PLD method, an ALD method, or the like as appropriate.

The insulating film 118A is formed to cover the side surface of the organic layer 112R, the side surface of the pixel electrode 111R, and the side surface of the insulating layer 106. The insulating film 118A is formed to cover the bottom surface of the insulating layer 106 in the depressed portion 175. The insulating film 118A is formed to cover the insulating layer 105 below the pixel electrode in the depressed portion 175.

For the insulating film 118A, a metal material such as gold, silver, platinum, magnesium, nickel, tungsten, chromium, molybdenum, iron, cobalt, copper, palladium, titanium, aluminum, yttrium, zirconium, or tantalum or an alloy material containing the metal material can be used. It is particularly preferable to use a low-melting-point material such as aluminum or silver. The use of a metal material capable of blocking ultraviolet light for the insulating film 118A is preferable, in which case the EL layer can be inhibited from being irradiated with ultraviolet light and deteriorating.

For the insulating film 118A, a metal oxide such as In—Ga—Zn oxide can be used. As the insulating film 118A, an In—Ga—Zn oxide film can be formed by a sputtering method, for example. Furthermore, indium oxide, In—Zn oxide, In—Sn oxide, indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), or the like can be used. Alternatively, indium tin oxide containing silicon can also be used, for example.

In addition, in place of gallium described above, an element M (M is one or more selected from of aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) may be used. In particular, M is preferably one or more kinds selected from gallium, aluminum, and yttrium.

As the insulating film 118A, a variety of inorganic insulating films that can be used as the protective layer 121 can be used. As the insulating film 118A, a variety of inorganic insulating films that can be used as the insulating layer 125 can be used. In particular, an oxide insulating film is preferable because its adhesion to the EL layer is higher than that of a nitride insulating film. For example, an inorganic insulating material such as aluminum oxide, hafnium oxide, or silicon oxide can be used for the insulating film 118A. As the insulating film 118A, for example, an aluminum oxide film can be formed by an ALD method. The use of an ALD method is preferable, in which case damage to a base (in particular, the EL layer or the like) can be reduced.

In this embodiment, aluminum oxide is deposited as the insulating film 118A by an ALD method. The insulating film 118A needs to be formed with good coverage on the bottom surface and the side surface of the depressed portion 175 provided in the insulating layer 105. By an ALD method, an atomic layer can be deposited one by one on the bottom surface and the side surface of the depressed portion 175, whereby the insulating film 118A can be deposited on the depressed portion 175 with good coverage. Furthermore, deposition damage can be reduced.

For example, in the case where aluminum oxide is deposited by an ALD method, two kinds of gases, H₂O as an oxidizer and a source gas that is obtained by vaporizing liquid containing a solvent and an aluminum precursor compound (trimethylaluminum (TMA, Al(CH₃)₃) or the like) are used. Examples of another material include tris(dimethylamide)aluminum, triisobutylaluminum, and aluminum tris(2,2,6,6-tetramethyl-3,5-heptanedionate).

Note that the insulating film 118A may be formed by a sputtering method, a CVD method, or a PECVD method that provides a higher deposition rate than an ALD method. In that case, a highly reliable display apparatus can be manufactured with high productivity.

The insulating film 118A may have a stacked-layer structure of two or more layers.

For example, a two-layer structure in which an inorganic insulating film (e.g., an aluminum oxide film) is formed as the lower layer by an ALD method and an inorganic film (e.g., an In—Ga—Zn oxide film, an aluminum film, or a tungsten film) is formed as the upper layer by a sputtering method can be employed.

Next, a resist mask 181 is formed over the insulating film 118A (FIG. 4E). At that time, the resist mask 181 is formed in a portion overlapping with the organic layer 112R and part of the depressed portion 175.

Although an end portion of the resist mask 181 has a shape perpendicular to the surface of the substrate 101 in FIG. 4E, the shape of the end portion of the resist mask 181 is not limited thereto. The end portion of the resist mask 181 may have a tapered shape or an inverse tapered shape.

Then, the insulating film 118A in a portion not covered with the resist mask 181 is removed, so that the insulating layer 118a can be formed. A dry etching method or a wet etching method can be used for the removal of the part of the insulating film 118A.

After that, the resist mask 181 is removed.

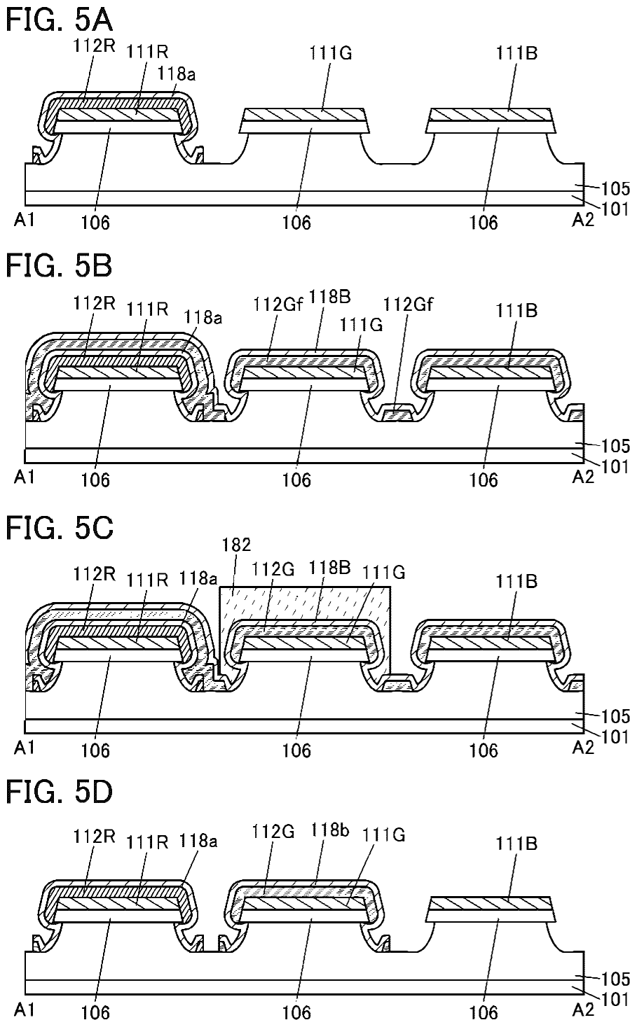

Next, part of the organic layer 112Rf is removed by etching treatment using the insulating layer 118a as a hard mask, so that the organic layer 112R is formed (FIG. 5A). Thus, a stacked-layer structure of the organic layer 112R and the insulating layer 118a remains over the pixel electrode 111R.

In FIG. 5A, the organic layer 112Rf in a portion that does not overlap with the resist mask 181 is removed. Since the organic layer 112Rf in the portion is separated from the organic layer 112R, the organic layer 112Rf in the portion may remain. The organic layer 112Rf that is in contact with the insulating layer 105 and formed over the depressed portion 175 may remain.

In the above manner, the organic layer 112R and the pixel electrode 111R can be sealed with the insulating layer 106 and the insulating layer 118a.

{Formation of Organic Layer 112G and Insulating Layer 118b}

A film containing a second light-emitting compound is formed over the pixel electrode 111G, the pixel electrode 111B, the insulating layer 105, and the insulating layer 118a.

The film containing the second light-emitting compound can be formed by an evaporation method, specifically a vacuum evaporation method, for example. Alternatively, the film may be formed by a method such as a transfer method, a printing method, an inkjet method, or a coating method.

At that time, disconnection occurs in the film containing the second light-emitting compound in the depressed portion 175. As a result, an organic layer 112Gf is formed over the pixel electrode 111G, the pixel electrode 111B, the insulating layer 105, and the insulating layer 118a.

Next, an insulating film 118B is formed over the organic layer 112Gf and the insulating layer 105 (FIG. 5B). The insulating film 118B can be formed by a sputtering method, a CVD method, an MBE method, a PLD method, an ALD method, or the like as appropriate. For the insulating film 118B, the description of the insulating film 118A can be referred to.

Then, a resist mask 182 is formed over the insulating film 118B (FIG. 5C).

After that, the insulating film 118B in a portion not covered with the resist mask 182 is removed, so that the insulating layer 118b can be formed. A dry etching method or a wet etching method can be used for the removal of the part of the insulating film 118B.

After that, the resist mask 182 is removed.

Next, part of the organic layer 112Gf is removed by etching treatment using the insulating layer 118b as a hard mask, so that the organic layer 112G is formed (FIG. 5D). Thus, a stacked-layer structure of the organic layer 112G and the insulating layer 118b remains over the pixel electrode 111G.

In the above manner, the organic layer 112G and the pixel electrode 111G can be sealed with the insulating layer 106 and the insulating layer 118b.

{Formation of Organic Layer 112B, Insulating Layer 118c, PS Layer 155S, and Insulating Layer 118d}

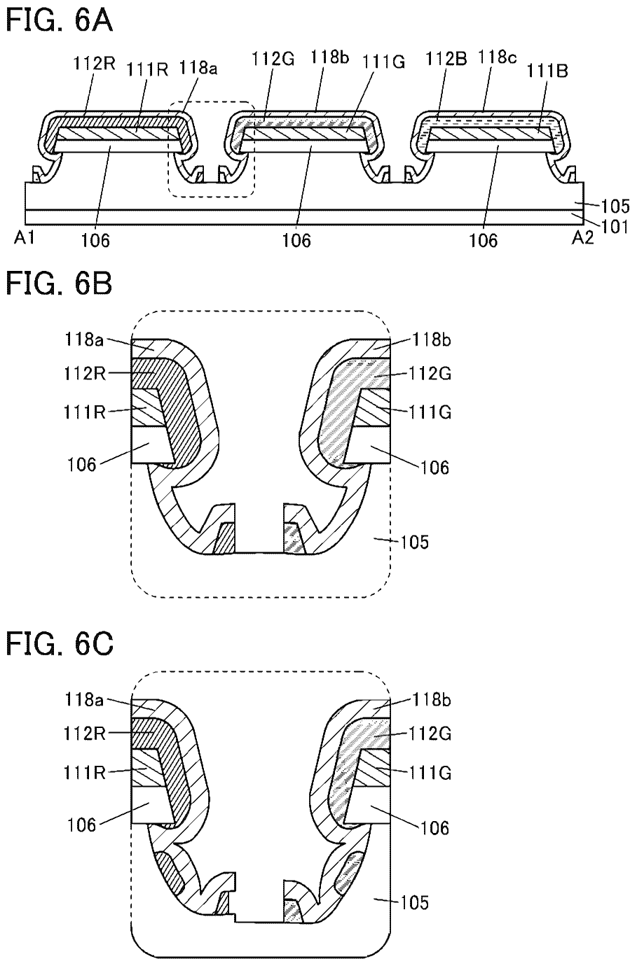

With reference to the formation processes of the organic layer 112R and the organic layer 112G, a stacked-layer structure of the organic layer 112B and the insulating layer 118c is formed over the pixel electrode 111B (FIG. 6A). Furthermore, although not illustrated, a stacked-layer structure of the PS layer 155S and the insulating layer 118d is formed over the pixel electrode 111S.

The organic layer 112B and the pixel electrode 111B can be sealed with the insulating layer 106 and the insulating layer 118c. The PS layer 155S and the pixel electrode 111S can be sealed with the insulating layer 106 and the insulating layer 118d.

FIG. 6B illustrates an enlarged view of a region surrounded by a dashed line in FIG. 6A. FIG. 6C illustrates an example of a structure different from that in FIG. 6B.

As illustrated in FIG. 6C, in the organic layer 112, the thickness of a region in contact with the side surface of the pixel electrode 111 and the thickness of a region in contact with the side surface of the depressed portion 175 are smaller than the thickness of a region in contact with the top surface of the pixel electrode 111 in some cases. Similarly, in the PS layer 155S, the thickness of a region in contact with the side surface of the pixel electrode 111 and the thickness of a region in contact with the side surface of the depressed portion 175 are smaller than the thickness of a region in contact with the top surface of the pixel electrode 111 in some cases. In a process of forming the organic layer 112G or the like, a step is sometimes formed in the insulating layer 105. Specifically, for example, a step is formed in the vicinity of the end portion of the insulating layer 118a as illustrated in FIG. 6C.

### {Formation of Insulating Layer 125, Resin Layer 126, Common Layer 114, and Common Electrode 113}

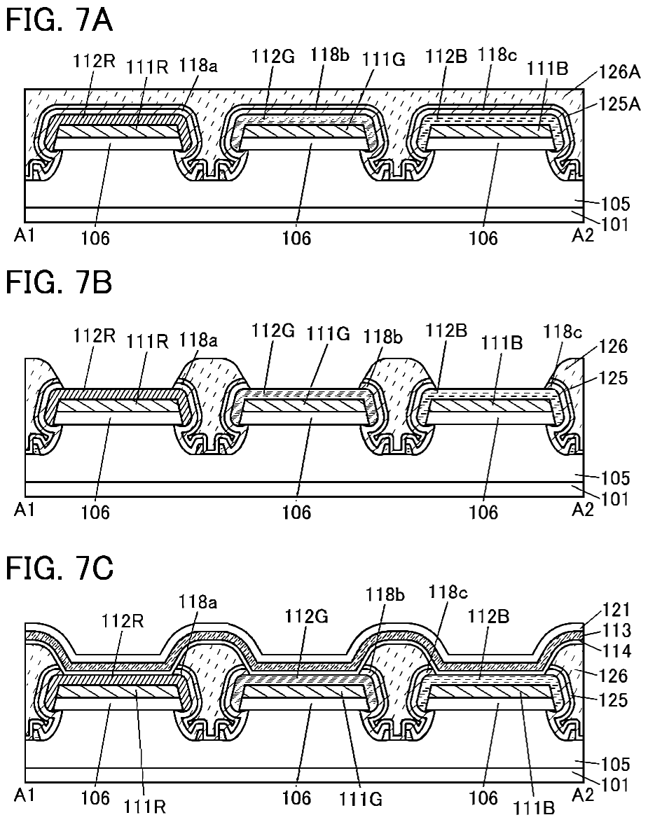

Next, an insulating film 125A is formed over the insulating layer 105, the insulating layer 118a, the insulating layer 118b, and the insulating layer 118c, and a resin film 126A is formed over the insulating film 125A (FIG. 7A). The insulating film 125A is a film to be the insulating layer 125, and the resin film 126A is a film to be the resin layer 126. Note that in the case where a two-layer stacked-layer structure is used for the insulating layer 118, the upper layer may be removed before the formation of the insulating film 125A and the resin film 126A.

A film that can be used for the insulating film 118A or the like can be used for the insulating film 125A. The insulating film 125A is not necessarily provided.

The resin film 126A is formed at a temperature lower than the upper temperature limits of the organic layer 112R, the organic layer 112G, the organic layer 112B, and the PS layer 155S. A substrate temperature at the time of forming the insulating film is preferably higher than or equal to 60° C., higher than or equal to 80° C., higher than or equal to 100° C., or higher than or equal to 120° C. and lower than or equal to 200° C., lower than or equal to 180° C., lower than or equal to 160° C., lower than or equal to 150° C., or lower than or equal to 140° C.

The resin film 126A is preferably formed by the aforementioned wet film formation method. The insulating film is preferably formed by spin coating using a photosensitive material, for example, and preferably formed using specifically a photosensitive resin composition containing an acrylic resin.

The resin film 126A is preferably formed using a resin composition containing a polymer, an acid-generating agent, and a solvent, for example. The polymer is formed using one or more kinds of monomers and has a structure where one or more kinds of structural units (also referred to as building blocks) are repeated regularly or irregularly. As the acid-generating agent, one or both of a compound that generates an acid by light irradiation and a compound that generates an acid by heating can be used. The resin composition may also include one or more of a photosensitizing agent, a sensitizer, a catalyst, an adhesive aid, a surface-active agent, and an antioxidant.

Heat treatment (also referred to as pre-baking) is preferably performed after the formation of the resin film 126A. The heat treatment is performed at a temperature lower than the upper temperature limits of the organic layer 112R, the organic layer 112G, and the organic layer 112B. The substrate temperature in the heat treatment is preferably higher than or equal to 50° C. and lower than or equal to 200° C., further preferably higher than or equal to 60° C. and lower than or equal to 150° C., still further preferably higher than or equal to 70° C. and lower than or equal to 120° C. Accordingly, a solvent contained in the resin film 126A can be removed.

Then, light exposure is performed to expose part of the resin film 126A to visible rays or ultraviolet rays. Here, when a positive photosensitive resin composition containing an acrylic resin is used for the insulating film, a region where the resin layer 126 is not formed in a later process is irradiated with visible rays or ultraviolet rays. The resin layer 126 is formed in a region interposed between any two of the pixel electrode 111R, the pixel electrode 111G, and the pixel electrode 111B. Thus, the pixel electrode 111 is irradiated with visible rays or ultraviolet rays. Note that when a negative photosensitive material is used for the resin film, the region where the resin layer 126 is to be formed is irradiated with visible rays or ultraviolet rays.

The width of the resin layer 126 formed later can be controlled in accordance with the exposed region of the resin film 126A. In this embodiment, processing is performed such that the resin layer 126 includes a region overlapping with the top surface of the pixel electrode 111.

Light used for light exposure preferably includes the i-line (wavelength: 365 nm). The light used for light exposure may include at least one of the g-line (wavelength: 436 nm) and the h-line (wavelength: 405 nm).

Next, development is performed to remove the region of the resin film 126A that is exposed to light, whereby the resin layer 126 is formed. The resin layer 126 is formed in a region interposed between any two of the pixel electrode 111R, the pixel electrode 111G, and the pixel electrode 111B. Here, in the case where an acrylic resin is used for the insulating film, an alkaline solution is preferably used as a developer, and for example, an aqueous solution of tetramethyl ammonium hydroxide (TMAH) can be used.

Then, a residue (scum) due to the development may be removed. For example, the residue can be removed by ashing using oxygen plasma.

Etching may be performed so that the height of the surface of the resin layer 126 is adjusted. The resin layer 126 may be processed by ashing using oxygen plasma, for example. In the case where a non-photosensitive material is used for a resin film to be the resin layer 126, the height of the surface of the insulating film can be adjusted by the ashing, for example.

Next, etching treatment is performed using the resin layer 126 as a mask to remove part of the insulating film 125A, part of the insulating layer 118a, part of the insulating layer 118b, and part of the insulating layer 118c. Thus, an opening portion is formed in the insulating film 125A and the insulating layer 118a, so that the top surface of the organic layer 112R is exposed. An opening portion is formed in the insulating film 125A and the insulating layer 118b, so that the top surface of the organic layer 112G is exposed. An opening portion is formed in the insulating film 125A and the insulating layer 118c, so that the top surface of the organic layer 112B is exposed (FIG. 7B). Although not illustrated, an opening portion is formed in the insulating film 125A and the insulating layer 118d, so that the top surface of the PS layer 155S is exposed. In other words, an opening portion reaching the organic layer 112R is provided in the resin layer 126, the insulating layer 125, and the insulating layer 118a. An opening portion reaching the organic layer 112G is provided in the resin layer 126, the insulating layer 125, and the insulating layer 118b. An opening portion reaching the organic layer 112B is provided in the resin layer 126, the insulating layer 125, and the insulating layer 118c. An opening portion reaching the PS layer 155S is provided in the resin layer 126, the insulating layer 125, and the insulating layer 118d.

The etching treatment is performed by wet etching. Using a wet etching method can reduce damage to the organic layer 112R, the organic layer 112G, and the organic layer 112B as compared with the case of using a dry etching method. A chemical solution used for the wet etching treatment may be alkaline or acid. For example, wet etching using an alkaline solution such as TMAH can be performed. Alternatively, an acid solution such as diluted hydrofluoric acid, oxalic acid, phosphoric acid, acetic acid, nitric acid, or a mixed solution thereof may be used for the wet etching. In the case of wet etching method using an acid solution, a mixed acid chemical solution containing water, phosphoric acid, diluted hydrofluoric acid, and nitric acid may be used.

After the organic layer 112R, the organic layer 112G, the organic layer 112B, and the PS layer 155S are partly exposed, heat treatment may be further performed. The heat treatment can remove water contained in the organic layer 112 and the PS layer 155S, water adsorbed on the surface of the organic layer 112 and the surface of the PS layer 155S, and the like. For example, heat treatment in an inert gas atmosphere or a reduced pressure atmosphere can be performed. The heat treatment can be performed at a substrate temperature higher than or equal to 50° C. and lower than or equal to 200° C., preferably higher than or equal to 60° C. and lower than or equal to 150° C., further preferably higher than or equal to 70° C. and lower than or equal to 120° C. A reduced-pressure atmosphere is preferable because dehydration at a lower temperature is possible. Note that the temperature range of the heat treatment is preferably set as appropriate also in consideration of the upper temperature limits of the organic layer 112 and the PS layer 155S. In consideration of the upper temperature limits of the organic layer 112 and the PS layer 155S, a temperature higher than or equal to 70° C. and lower than or equal to 120° C. is particularly preferable in the above temperature ranges.

Next, the common layer 114 is formed over the organic layer 112R, the organic layer 112G, the organic layer 112B, the PS layer 155S, and the resin layer 126. The common layer 114 can be formed by an evaporation method (including a vacuum evaporation method), a transfer method, a printing method, an inkjet method, a coating method, or the like.

Next, the common electrode 113 is formed over the common layer 114. The common electrode 113 can be formed by a sputtering method, a vacuum evaporation method, or the like. Alternatively, the common electrode 113 may be formed by stacking a film formed by an evaporation method and a film formed by a sputtering method.

The common electrode 113 is formed to overlap with the organic layer 112R through the opening portion formed in the resin layer 126 and the insulating layer 118a. The common electrode 113 is formed to overlap with the organic layer 112G through the opening portion formed in the resin layer 126 and the insulating layer 118b. The common electrode 113 is formed to overlap with the organic layer 112B through the opening portion formed in the resin layer 126 and the insulating layer 118c. The common electrode 113 is formed to overlap with the PS layer 155S through the opening portion formed in the resin layer 126 and the insulating layer 118d.

Thus, the light-emitting element 110R, the light-emitting element 110G, the light-emitting element 110B, and the light-receiving element 110S can be formed.

Next, the protective layer 121 is formed over the common electrode 113 (FIG. 7C). The protective layer 121 can be formed by a vacuum evaporation method, a sputtering method, a CVD method, an ALD method, or the like.

In the above manner, the display apparatus 100A with the structure illustrated in FIG. 2A and the like can be manufactured.

According to the above manufacturing method example, the organic layer 112 and the PS layer 155S are not exposed to a chemical solution or the like used in removing the resist mask because of being sealed with the insulating layer 106 and the insulating layer 118 or the insulating layer 105 and the insulating layer 118. Thus, the light-emitting element 110 can be formed without using a metal mask for forming the organic layer 112 and the PS layer 155S.

According to the above manufacturing method example, a wet etching method can be used for all the etching treatment performed in a process after the formation of the pixel electrode 111, which makes it possible to reduce the manufacturing cost of the display apparatus 100A.

According to the above manufacturing method example, the difference in the optical distance between the pixel electrode 111 and the common electrode 113 can be precisely controlled by the thicknesses of the organic layer 112; thus, chromaticity deviation in the light-emitting elements is unlikely to occur, so that a display apparatus having excellent color reproducibility and extremely high display quality can be manufactured easily.

The resin layer 126 having a tapered end portion and being provided between the adjacent island-shaped organic layers 112, between the organic layer 112 and the PS layer 155S adjacent to each other, and the like can inhibit occurrence of disconnection and inhibit formation of a locally thinned portion in the common electrode 113 at the time of forming the common electrode 113. This can inhibit the common layer 114 and the common electrode 113 from having connection defects due to the disconnected portion and an increased electric resistance due to the locally thinned portion. Thus, the display apparatus of one embodiment of the present invention can achieve a high resolution, high display quality, and high light-receiving sensitivity.

Note that in the display apparatus of one embodiment of the present invention or a method for manufacturing the display apparatus, there is no particular limitation on the screen ratio (aspect ratio) of a display portion in the display apparatus. For example, the display apparatus is compatible with a variety of screen ratios such as 1:1 (a square), 3:4, 16:9, and 16:10.

### [Pixel Layout]

Pixel layouts different from the layout in FIG. 1 will be mainly described below. There is no particular limitation on the arrangement of subpixels, and a variety of methods can be employed. Examples of the arrangement of subpixels include stripe arrangement, S-stripe arrangement, matrix arrangement, delta arrangement, Bayer arrangement, or PenTile arrangement.

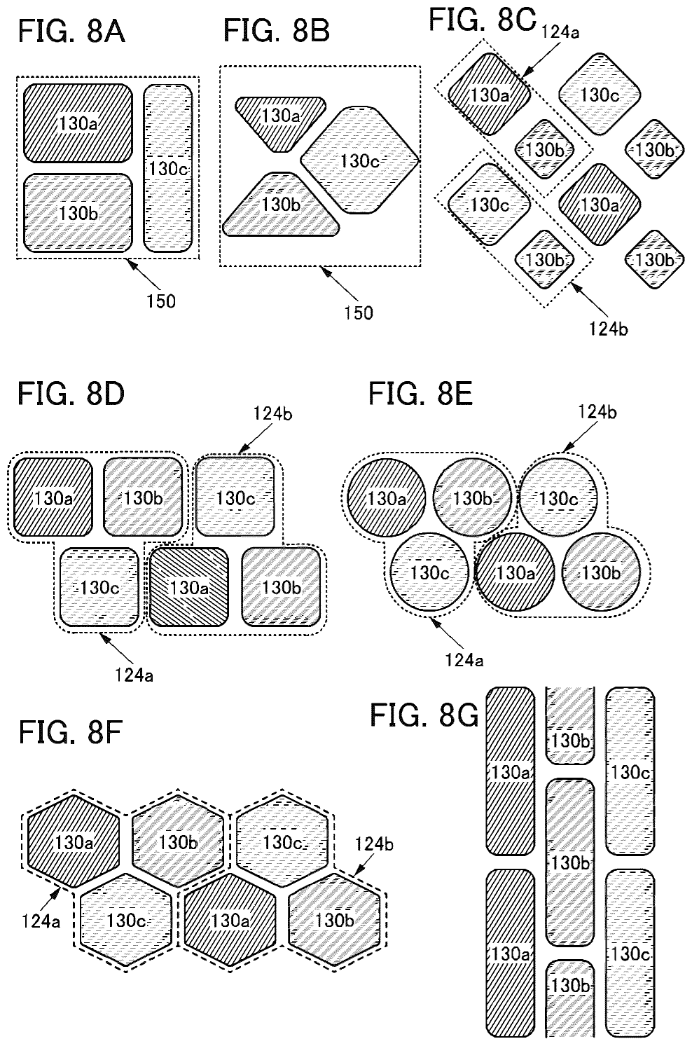

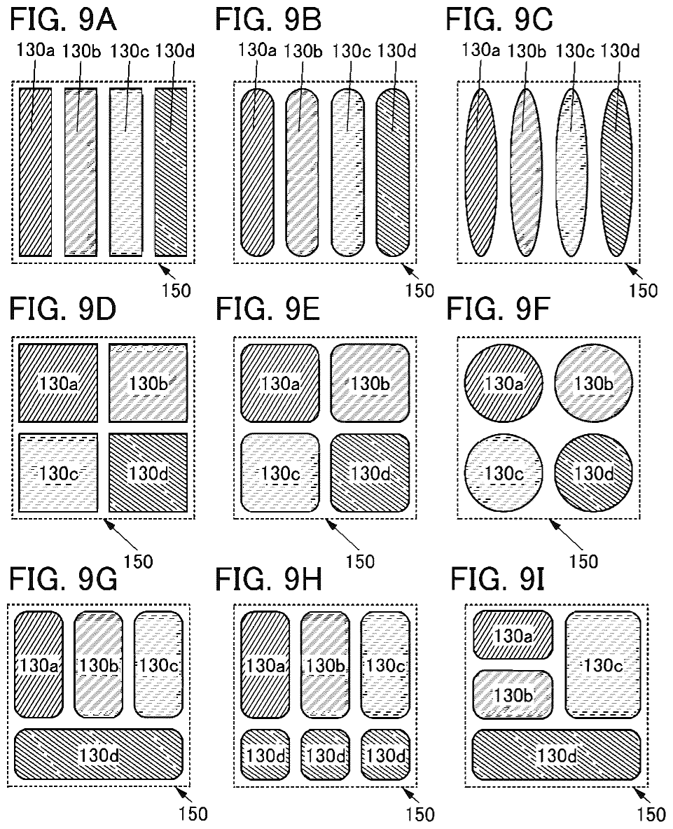

The top surface shapes of the subpixels illustrated in FIG. 8 and FIG. 9 each correspond to the top surface shape of a light-emitting region.

Examples of the top surface shape of the subpixel include polygons such as a triangle, a tetragon (including a rectangle and a square), and a pentagon; polygons with rounded corners; an ellipse; and a circle.

The range of the circuit layout for forming the subpixels is not limited to the range of the subpixels illustrated in diagrams and may be placed outside the range of the subpixels.

A pixel 150 illustrated in FIG. 8A employs S-stripe arrangement. The pixel 150 illustrated in FIG. 8A consists of three subpixels: a subpixel 130a, a subpixel 130b, and a subpixel 130c. The subpixel 130a can be a subpixel including the light-emitting element 110R, for example. The subpixel 130b can be a subpixel including the light-emitting element 110G, for example. The subpixel 130c can be a subpixel including the light-emitting element 110B, for example.

The pixel 150 illustrated in FIG. 8B includes the subpixel 130a whose top surface has a rough trapezoidal shape with rounded corners, the subpixel 130b whose top surface has a rough triangle shape with rounded corners, and the subpixel 130c whose top surface has a rough quadrangle or rough hexagonal shape with rounded corners. The subpixel 130a has a larger light-emitting area than the subpixel 130b. In this manner, the shapes and sizes of the subpixels can be determined independently. For example, the size of a subpixel including a light-emitting element with higher reliability can be smaller.

A pixel 124a and a pixel 124b illustrated in FIG. 8C employ pentile arrangement. FIG. 8C illustrates an example in which the pixels 124a including the subpixel 130a and the subpixel 130b and the pixels 124b including the subpixel 130b and the subpixel 130c are alternately arranged.

The pixels 124a and the pixels 124b illustrated in FIG. 8D to FIG. 8F employ delta arrangement. The pixel 124a includes two subpixels (the subpixel 130a and the subpixel 130b) in the upper row (first row) and one subpixel (the subpixel 130c) in the lower row (second row). The pixel 124b includes one subpixel (the subpixel 130c) in the upper row (first row) and two subpixels (the subpixel 130a and the subpixel 130b) in the lower row (second row).

FIG. 8D illustrates an example where the top surface of each subpixel has a rough tetragonal shape with rounded corners, FIG. 8E illustrates an example where the top surface of each subpixel is circular, and FIG. 8F illustrates an example where the top surface of each subpixel has a rough hexagonal shape with rounded corners.

In FIG. 8F, each subpixel is placed inside one of close-packed hexagonal regions. Focusing on one of the subpixels, the subpixel is placed so as to be surrounded by six subpixels. The subpixels are arranged such that subpixels exhibiting light of the same color are not adjacent to each other. For example, focusing on the subpixel 130a, the subpixel 130a is surrounded by three subpixels 130b and three subpixels 130c that are alternately arranged.

FIG. 8G illustrates an example in which subpixels of different colors are arranged in a zigzag manner. Specifically, the positions of the top sides of two subpixels arranged in the column direction (e.g., the subpixel 130a and the subpixel 130b or the subpixel 130b and the subpixel 130c) are not aligned in the top view.

In each pixel in FIG. 8A to FIG. 8G, preferably, the subpixel 130a is a subpixel that emits red light, the subpixel 130b is a subpixel that emits green light, and a subpixel 130c is the subpixel that emits blue light, for example. Note that the structure of the subpixels is not limited to this, and the colors and arrangement order of the subpixels can be determined as appropriate. For example, the subpixel 130b may be a subpixel that emits red light and the subpixel 130a may be a subpixel that emits green light.

In a photolithography method, as a pattern to be processed becomes finer, the influence of light diffraction becomes more difficult to ignore; therefore, the fidelity in transferring a photomask pattern by light exposure is degraded, and it becomes difficult to process a resist mask into a desired shape. Thus, a pattern with rounded corners is likely to be formed even with a rectangular photomask pattern. Consequently, the top surface shape of a subpixel may be a polygon with rounded corners, an ellipse, a circle, or the like.

Furthermore, in the method for manufacturing the display apparatus of one embodiment of the present invention, the EL layer is processed into an island shape with the use of a resist mask. A resist film formed over the EL layer needs to be cured at a temperature lower than the upper temperature limit of the EL layer. Therefore, the resist film is insufficiently cured in some cases depending on the upper temperature limit of the material of the EL layer and the curing temperature of the resist material. An insufficiently cured resist film may have a shape different from a desired shape by processing. As a result, a top surface of the EL layer has a polygonal shape with rounded corners, an elliptical shape, a circular shape, or the like in some cases. For example, when a resist mask with a square top surface is intended to be formed, a resist mask with a circular top surface may be formed, and the top surface of the EL layer may be circular.

To obtain a desired top surface shape of the EL layer, a technique of correcting a mask pattern in advance so that a transferred pattern agrees with a design pattern (an OPC (Optical Proximity Correction) technique) may be used. Specifically, with the OPC technique, a pattern for correction is added to a corner portion or the like of a figure on a mask pattern.

As illustrated in FIG. 9A to FIG. 9I, the pixel can include four types of subpixels. The pixel consists of four subpixels: the subpixel 130a, the subpixel 130b, the subpixel 130c, and a subpixel 130d, for example. The subpixel 130a can be a subpixel including the light-emitting element 110R, for example. The subpixel 130b can be a subpixel including the light-emitting element 110G, for example. The subpixel 130c can be a subpixel including the light-emitting element 110B, for example. In addition, the subpixel 130d can be a subpixel including the light-receiving element 110S, for example.

The pixels 150 illustrated in FIG. 9A to FIG. 9C each employ stripe arrangement.

FIG. 9A illustrates an example in which each subpixel has a rectangular top surface shape, FIG. 9B illustrates an example in which each subpixel has a top surface shape formed by combining two half circles and a rectangle, and FIG. 9C illustrates an example in which each subpixel has an elliptical top surface shape.

The pixels 150 illustrated in FIG. 9D to FIG. 9F each employ matrix arrangement.

FIG. 9D illustrates an example in which each subpixel has a square top surface shape, FIG. 9E illustrates an example in which each subpixel has a substantially square top surface shape with rounded corners, and FIG. 9F illustrates an example in which each subpixel has a circular top surface shape.

FIG. 9G and FIG. 9H each illustrate an example in which one pixel 150 is composed of two rows and three columns.

The pixel 150 illustrated in FIG. 9G includes three subpixels (the subpixel 130a, the subpixel 130b, and the subpixel 130c) in the upper row (first row) and one subpixel (the subpixel 130d) in the lower row (second row). In other words, the pixel 150 includes the subpixel 130a in the left column (first column), the subpixel 130b in the center column (second column), the subpixel 130c in the right column (third column), and the subpixel 130d across these three columns.

The pixel 150 illustrated in FIG. 9H includes three subpixels (the subpixel 130a, the subpixel 130b, and the subpixel 130c) in the upper row (first row) and three subpixels 130d in the lower row (second row). In other words, the pixel 150 includes the subpixel 130a and the subpixel 130d in the left column (first column), the subpixel 130b and the subpixel 130d in the center column (second column), and the subpixel 130c and the subpixel 130d in the right column (third column). Aligning the positions of the subpixels in the upper row and the lower row as illustrated in FIG. 9H enables dust and the like that would be produced in the manufacturing process to be removed efficiently. Thus, a display apparatus with high display quality can be provided.

FIG. 9I illustrates an example in which one pixel 150 is composed of three rows and two columns.

The pixel 150 illustrated in FIG. 9I includes the subpixel 130a in the upper row (first row), the subpixel 130b in the center row (second row), the subpixel 130c across the first and second rows, and one subpixel (the subpixel 130d) in the lower row (third row). In other words, the pixel 150 includes the subpixel 130a and the subpixel 130b in the left column (first column), the subpixel 130c in the right column (second column), and the subpixel 130d across these two columns.

The pixels 150 illustrated in FIG. 9A to FIG. 9I are each composed of four subpixels: the subpixel 130a, the subpixel 130b, the subpixel 130c, and the subpixel 130d.

The subpixel 130a, the subpixel 130b, and the subpixel 130c can include light-emitting elements emitting light of different colors, and the subpixel 130d can include a light-receiving element.

In each of the pixels 150 illustrated in FIG. 9A to FIG. 9I, for example, it is preferable that the subpixel 130a be a subpixel that emits red light, the subpixel 130b be a subpixel that emits green light, the subpixel 130c be a subpixel that emits blue light, and the subpixel 130d be a subpixel having a function of detecting one or both of visible light and infrared light. In the case of such a structure, stripe arrangement is employed as the subpixel layout of R, G, and B in the pixels 150 illustrated in FIG. 9G and FIG. 9H, leading to higher display quality. In addition, what is called S-stripe arrangement is employed as the subpixel layout of R, G, and B in the pixel 150 illustrated in FIG. 9I, leading to higher display quality.

Alternatively, the subpixel 130a, the subpixel 130b, the subpixel 130c, and the subpixel 130d may include light-emitting elements that emit light of different colors. For example, in the case where the subpixel 130a, the subpixel 130b, the subpixel 130c, and the subpixel 130d are light-emitting elements that emit light of different colors, subpixels of four colors of R, G, B, and white (W), subpixels of four colors of R, G, B, and Y, subpixels of R, G, B, and infrared light (IR), and the like can be given.

In the pixels 150 illustrated in FIG. 9A to FIG. 9I, it is preferable that the subpixel 130a be a subpixel that emits red light, the subpixel 130b be a subpixel that emits green light, the subpixel 130c be a subpixel that emits blue light, and the subpixel 130d be any of a subpixel that emits white light, a subpixel that emits yellow light, and a subpixel that emits near-infrared light, for example. In the case of such a structure, stripe arrangement is employed as the subpixel layout of R, G, and B in the pixels 150 illustrated in FIG. 9G and FIG. 9H, leading to higher display quality. In addition, what is called S-stripe arrangement is employed as the subpixel layout of R, G, and B in the pixel 150 illustrated in FIG. 9I, leading to higher display quality.

As described above, the pixel composed of the subpixels each including the light-emitting element can employ any of a variety of layouts in the display apparatus of one embodiment of the present invention.

This embodiment can be combined with the other embodiments as appropriate.

### Embodiment 2

In this embodiment, another structural example of the display apparatus (display panel) described in the above embodiment will be described. Display apparatuses (display panels) described below as examples can be used as the display apparatus 100A and the like in Embodiment 1. The display apparatuses (display panels) described below as examples includes transistors.

The display apparatus of this embodiment can be a high-resolution display apparatus. For example, the display apparatus of one embodiment of the invention can be used for display portions of information terminals (wearable devices) such as watch-type and bracelet-type information terminals and display portions of wearable devices capable of being worn on a head, such as a VR device like a head-mounted display and a glasses-type AR device.

### [Display Module]

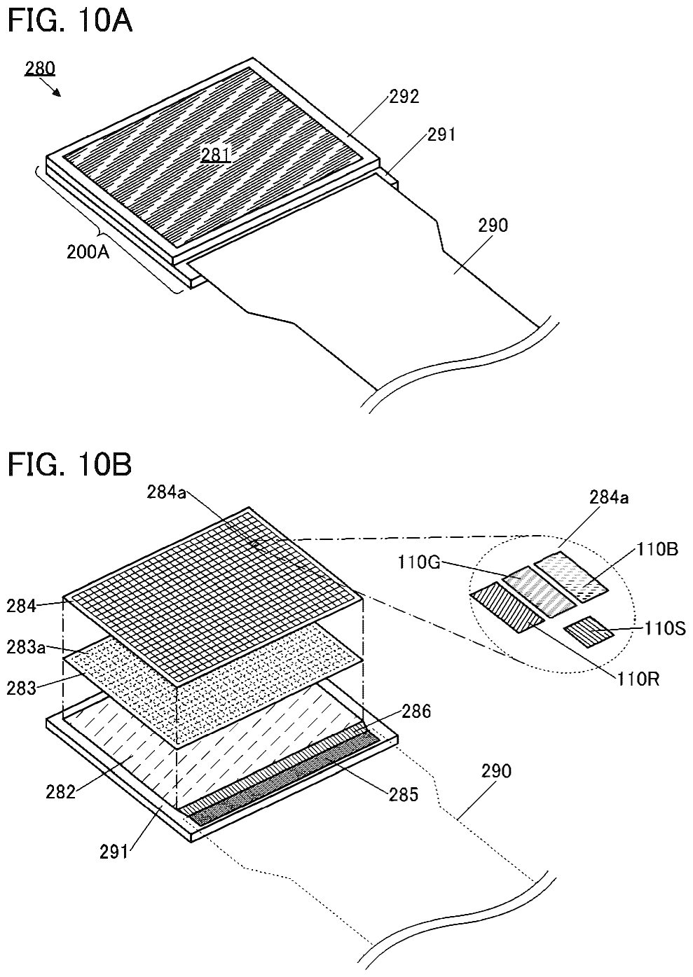

FIG. 10A is a perspective view of a display module 280. The display module 280 includes a display apparatus 200A and an FPC 290. Note that a display panel included in the display module 280 is not limited to the display apparatus 200A and may be any of a display apparatus 200B to a display apparatus 200F described later.

The display module 280 includes a substrate 291 and a substrate 292. The display module 280 includes a display portion 281. The display portion 281 is a region where an image is displayed.

FIG. 10B shows a perspective view schematically illustrating a structure on the substrate 291 side. A circuit portion 282, a pixel circuit portion 283 over the circuit portion 282, and a pixel portion 284 over the pixel circuit portion 283 are stacked over the substrate 291. A terminal portion 285 to be connected to the FPC 290 is provided in a portion over the substrate 291 that does not overlap with the pixel portion 284. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side of FIG. 10B. The pixel 284a includes the light-emitting element 110R that emits red light, the light-emitting element 110G that emits green light, the light-emitting element 110B that emits blue light, and the light-receiving element 110S.

The pixel circuit portion 283 includes a plurality of pixel circuits 283a arranged periodically. One pixel circuit 283a is a circuit that controls light emission of the light-emitting elements and the light-receiving element that are included in one pixel 284a. One pixel circuit 283a may be provided with four circuits each of which controls light emission of one light-emitting element (light-receiving element). For example, the pixel circuit 283a can include at least one selection transistor, one current control transistor (driving transistor), and a capacitor for one light-emitting element. In this case, a gate signal is input to a gate of the selection transistor, and a source signal is input to a source of the selection transistor. With such a structure, an active-matrix display panel is achieved.

The circuit portion 282 includes a circuit for driving the pixel circuits 283a in the pixel circuit portion 283. For example, one or both of a gate line driver circuit and a source line driver circuit are preferably included. In addition, at least one of an arithmetic circuit, a memory circuit, a power supply circuit, and the like may be included. In addition, a transistor provided in the circuit portion 282 may constitute part of the pixel circuit 283a. That is, the pixel circuit 283a may be constituted by a transistor included in the pixel circuit portion 283 and a transistor included in the circuit portion 282.

The FPC 290 functions as a wiring for supplying a video signal, a power supply potential, and the like to the circuit portion 282 from the outside. An IC may be mounted on the FPC 290.

The display module 280 can have a structure in which one or both of the pixel circuit portion 283 and the circuit portion 282 are stacked below the pixel portion 284; thus, the aperture ratio (the effective display area ratio) of the display portion 281 can be significantly high. For example, the aperture ratio of the display portion 281 can be greater than or equal to 40% and less than 100%, preferably greater than or equal to 50% and less than or equal to 95%, further preferably greater than or equal to 60% and less than or equal to 95%. Furthermore, the pixels 284a can be arranged extremely densely and thus the display portion 281 can have extremely high resolution. For example, the pixels 284a are preferably arranged in the display portion 281 with a resolution higher than or equal to 2000 ppi, preferably higher than or equal to 3000 ppi, further preferably higher than or equal to 5000 ppi, still further preferably higher than or equal to 6000 ppi, and lower than or equal to 20000 ppi or lower than or equal to 30000 ppi.

Such a display module 280 has an extremely high resolution, and thus can be suitably used for a VR device such as a head-mounted display or a glasses-type AR device. For example, even with a structure where the display portion of the display module 280 is seen through a lens, pixels of the extremely-high-resolution display portion 281 included in the display module 280 are prevented from being perceived when the display portion is enlarged by the lens, so that display providing a high sense of immersion can be performed. Without being limited thereto, the display module 280 can be suitably used for electronic devices including a relatively small display portion. For example, the display module 280 can be favorably used for a display portion of a wearable electronic device, such as a wrist watch.

### [Display Apparatus 200A]

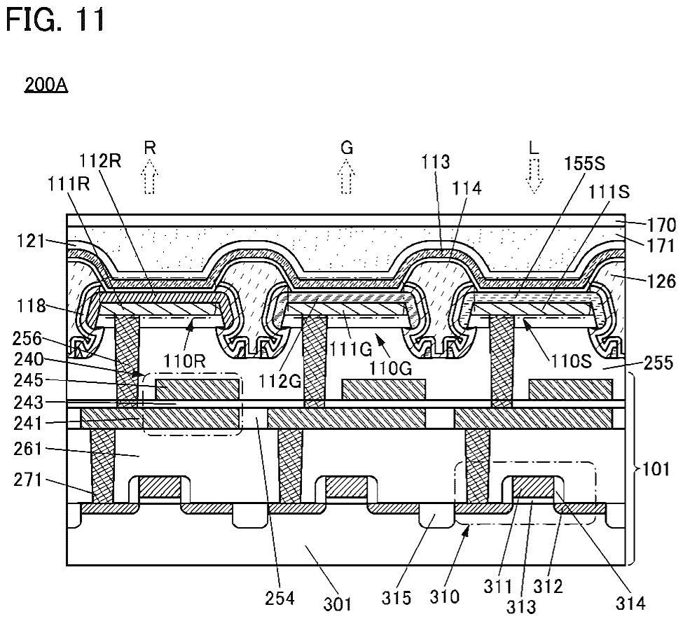

The display apparatus 200A illustrated in FIG. 11 includes a substrate 301, the light-emitting element 110R, the light-emitting element 110G, the light-emitting element 110B (not illustrated), the light-receiving element 110S, a capacitor 240, and a transistor 310.

The substrate 301 corresponds to the substrate 291 in FIG. 10A and FIG. 10B.

The transistor 310 is a transistor including a channel formation region in the substrate 301. As the substrate 301, a semiconductor substrate such as a single crystal silicon substrate can be used, for example. The transistor 310 includes part of the substrate 301, a conductive layer 311, low-resistance regions 312, an insulating layer 313, and insulating layers 314. The conductive layer 311 functions as a gate electrode. The insulating layer 313 is positioned between the substrate 301 and the conductive layer 311 and functions as a gate insulating layer. The low-resistance region 312 is a region where the substrate 301 is doped with an impurity, and functions as one of a source and a drain. The insulating layers 314 are provided to cover the side surface of the conductive layer 311.

An element isolation layer 315 is provided between two adjacent transistors 310 to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 positioned between these conductive layers. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

An insulating layer 255 is provided to cover the capacitor 240.

An inorganic insulating film can be suitably used as the insulating layer 255. A silicon oxide film, a silicon oxynitride film, or the like can be used for the insulating layer 255, for example. This embodiment shows an example in which part of the insulating layer 255 is etched to form a depressed portion.

Note that the insulating layer 255 may have a three-layer stacked structure of a first insulating layer, a second insulating layer over the first insulating layer, and a third insulating layer over the second insulating layer. An inorganic insulating film can be suitably used as each of the first insulating layer, the second insulating layer, and the third insulating layer. For example, it is preferable that silicon oxide films be used as the first insulating layer and the third insulating layer and a silicon nitride film be used as the second insulating layer. This enables the second insulating layer to function as an etching protective film.

The insulating layer 255 corresponds to the insulating layer 105 in FIG. 2A and the like. In the case where the insulating layer 255 has a stacked-layer structure, part of a plurality of layers included in the insulating layer 255 corresponds to the insulating layer 105 in FIG. 2A and the like.

The light-emitting element 110R, the light-emitting element 110G, and the light-receiving element 110S are provided over the insulating layer 255. Embodiment 1 can be referred to for the structures of the light-emitting element 110R, the light-emitting element 110G, and the light-receiving element 110S. The light-emitting element 110R is a light-emitting element that emits red light R, for example. The light-emitting element 110G is a light-emitting element that emits green light G, for example. The light-receiving element 110S is a light-emitting element having a function of detecting light L, for example.

In the display apparatus 200A, since the light-emitting elements of different emission colors are separately formed, the difference between the chromaticity at low luminance emission and that at high luminance emission is small. Furthermore, since the organic layer 112R, the organic layer 112G, and the organic layer 112B are separated from each other, crosstalk generated between adjacent subpixels can be inhibited while the display panel has high definition. Accordingly, the display panel can have high resolution and high display quality.

In a region between adjacent light-emitting elements, the insulating layer 118 and the resin layer 126 are provided.

The pixel electrode 111R, the pixel electrode 111G, and the pixel electrode 111S of the light-emitting elements are each electrically connected to one of the source and the drain of the transistor 310 through a plug 256 that is embedded in the insulating layer 255, the conductive layer 241 that is embedded in the insulating layer 254, and the plug 271 that is embedded in the insulating layer 261. The top surface of the insulating layer 255 and the top surface of the plug 256 are level or substantially level with each other. A variety of conductive materials can be used for the plugs.

The protective layer 121 is provided over the light-emitting element 110R, the light-emitting element 110G, and the light-receiving element 110S. A substrate 170 is bonded onto the protective layer 121 with an adhesive layer 171. A resin layer can be used as the adhesive layer 171, for example. Examples of the resin layer that can be used as the adhesive layer 171 and the like include a variety of curable adhesives, e.g., photocurable adhesive such as an ultraviolet curable adhesive, a reactive curable adhesive, a thermosetting curable adhesive, and an anaerobic adhesive. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferable. Alternatively, a two-liquid-mixture-type resin may be used. An adhesive sheet or the like may be used.

An insulating layer covering an end portion of the top surface of the pixel electrode 111 is not provided between two adjacent pixel electrodes 111. Thus, the distance between adjacent light-emitting elements can be extremely narrowed. Accordingly, the display apparatus can have high resolution or high definition.

### [Display Apparatus 200B]

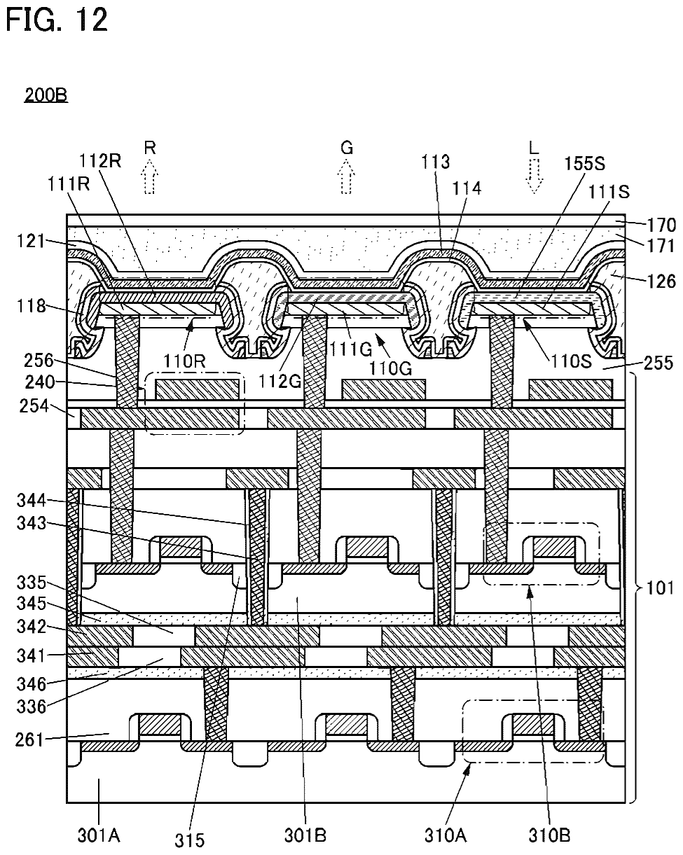

The display apparatus 200B illustrated in FIG. 12 has a structure where transistors 310A and transistors 310B in each of which a channel is formed in a semiconductor substrate are stacked. Note that in the following description of the display panel, the description of portions similar to those of the above display panel is omitted in some cases.

In the display apparatus 200B, a substrate 301B provided with the transistors 310B, the capacitors 240, and the light-emitting elements is bonded to a substrate 301A provided with the transistors 310A.

Here, an insulating layer 345 is provided on the bottom surface of the substrate 301B, and an insulating layer 346 is provided over the insulating layer 261 provided over the substrate 301A. The insulating layer 345 and the insulating layer 346 are insulating layers functioning as protective layers and can inhibit diffusion of impurities into the substrate 301B and the substrate 301A. As the insulating layer 345 and the insulating layer 346, an inorganic insulating film that can be used as the protective layer 121 or an insulating layer 332 can be used.

The substrate 301B is provided with a plug 343 that penetrates the substrate 301B and the insulating layer 345. Here, insulating layers 344 each functioning as a protective layer are preferably provided to cover side surfaces of the plugs 343.

In addition, a conductive layer 342 is provided under the insulating layer 345 on the substrate 301B. The conductive layer 342 is embedded in an insulating layer 335, and bottom surfaces of the conductive layer 342 and the insulating layer 335 are planarized. Furthermore, the conductive layer 342 is electrically connected to the plug 343.

Meanwhile, a conductive layer 341 is provided over the insulating layer 346 over the substrate 301A. The conductive layer 341 is embedded in an insulating layer 336, and top surfaces of the conductive layer 341 and the insulating layer 336 are planarized.

The conductive layer 341 and the conductive layer 342 are preferably formed using the same conductive material. For example, it is possible to use a metal film containing an element selected from Al, Cr, Cu, Ta, Ti, Mo, and W, or a metal nitride film containing any of the above elements as a component (a titanium nitride film, a molybdenum nitride film, or a tungsten nitride film). Copper is particularly preferably used for the conductive layer 341 and the conductive layer 342. In that case, it is possible to employ Cu—Cu (copper-to-copper) direct bonding (a technique for achieving electrical continuity by connecting Cu (copper) pads).

### [Display Apparatus 200C]

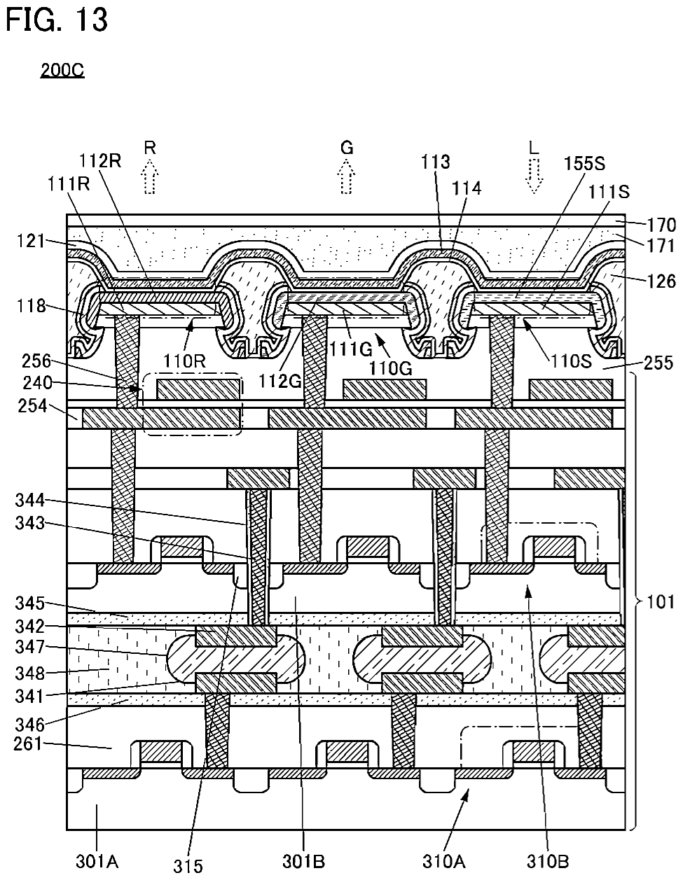

The display apparatus 200C illustrated in FIG. 13 has a structure where the conductive layer 341 and the conductive layer 342 are bonded to each other through a bump 347.

As illustrated in FIG. 13, providing the bump 347 between the conductive layer 341 and the conductive layer 342 enables the conductive layer 341 and the conductive layer 342 to be electrically connected to each other. The bump 347 can be formed using a conductive material containing gold (Au), nickel (Ni), indium (In), tin (Sn), or the like, for example. For another example, solder may be used for the bump 347. An adhesive layer 348 may be provided between the insulating layer 345 and the insulating layer 346. In the case where the bump 347 is provided, the insulating layer 345 and the insulating layer 346 may be omitted.

### [Display Apparatus 200D]

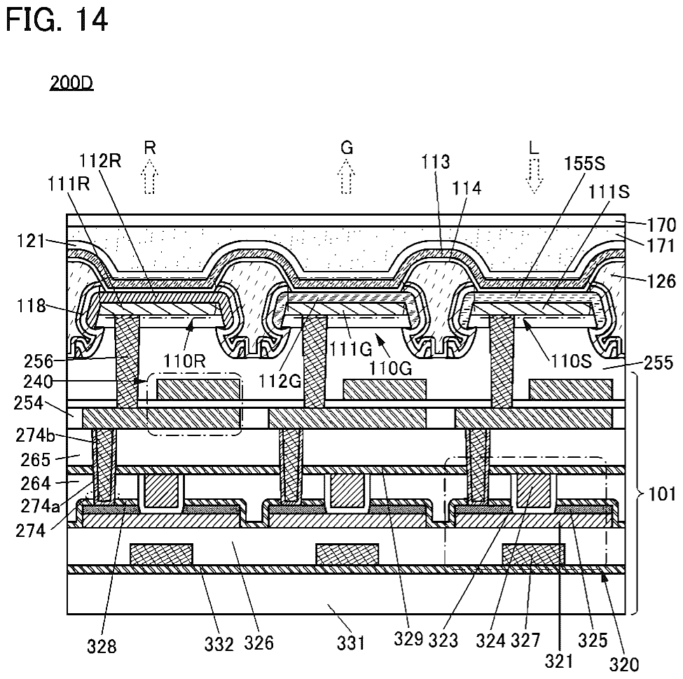

The display apparatus 200D illustrated in FIG. 14 is different from the display apparatus 200A mainly in a transistor structure.

A transistor 320 is a transistor that contains a metal oxide (also referred to as an oxide semiconductor) in a semiconductor layer where a channel is formed (i.e., an OS transistor).

The transistor 320 includes a semiconductor layer 321, an insulating layer 323, a conductive layer 324, a pair of conductive layers 325, an insulating layer 326, and a conductive layer 327.

A substrate 331 corresponds to the substrate 291 in FIG. 10A and FIG. 10B.

The insulating layer 332 is provided over the substrate 331. The insulating layer 332 functions as a barrier layer that prevents diffusion of impurities such as water and hydrogen from the substrate 331 into the transistor 320 and release of oxygen from the semiconductor layer 321 to the insulating layer 332 side. As the insulating layer 332, for example, a film in which hydrogen or oxygen is less likely to diffuse than in a silicon oxide film, such as an aluminum oxide film, a hafnium oxide film, or a silicon nitride film, can be used.

The conductive layer 327 is provided over the insulating layer 332, and the insulating layer 326 is provided to cover the conductive layer 327. The conductive layer 327 functions as a first gate electrode of the transistor 320, and part of the insulating layer 326 functions as a first gate insulating layer. An oxide insulating film such as a silicon oxide film is preferably used as at least part of the insulating layer 326 that is in contact with the semiconductor layer 321. The top surface of the insulating layer 326 is preferably planarized.

The semiconductor layer 321 is provided over the insulating layer 326. The semiconductor layer 321 preferably includes a metal oxide (also referred to as an oxide semiconductor) film exhibiting semiconductor characteristics. The pair of conductive layers 325 is provided over and in contact with the semiconductor layer 321 and functions as a source electrode and a drain electrode.

An insulating layer 328 is provided to cover the top surfaces and side surfaces of the pair of conductive layers 325, the side surface of the semiconductor layer 321, and the like, and an insulating layer 264 is provided over the insulating layer 328. The insulating layer 328 functions as a barrier layer that prevents diffusion of impurities such as water and hydrogen from the insulating layer 264 and the like into the semiconductor layer 321 and release of oxygen from the semiconductor layer 321. As the insulating layer 328, an insulating film similar to the insulating layer 332 can be used.

An opening reaching the semiconductor layer 321 is provided in the insulating layer 328 and the insulating layer 264. The conductive layer 324 and the insulating layer 323 that is in contact with the top surface of the semiconductor layer 321 are embedded in the opening. The conductive layer 324 functions as a second gate electrode, and the insulating layer 323 functions as a second gate insulating layer.

The top surface of the conductive layer 324, the top surface of the insulating layer 323, and the top surface of the insulating layer 264 are subjected to planarization treatment to be level or substantially level with each other, and an insulating layer 329 and an insulating layer 265 are provided to cover these layers.

The insulating layer 264 and the insulating layer 265 function as interlayer insulating layers. The insulating layer 329 functions as a barrier layer that prevents diffusion of impurities such as water and hydrogen from the insulating layer 265 and the like into the transistor 320. For the insulating layer 329, an insulating film similar to the insulating layer 328 and the insulating layer 332 can be used.

A plug 274 electrically connected to one of the pair of conductive layers 325 is provided to be embedded in the insulating layer 265, the insulating layer 329, and the insulating layer 264. Here, the plug 274 preferably includes a conductive layer 274a covering the side surface of the opening formed in the insulating layer 265, the insulating layer 329, the insulating layer 264, and the insulating layer 328 and part of the top surface of the conductive layer 325, and a conductive layer 274b in contact with the top surface of the conductive layer 274a. For the conductive layer 274a, a conductive material that does not easily allow diffusion of hydrogen and oxygen is preferably used.

### [Display Apparatus 200E]

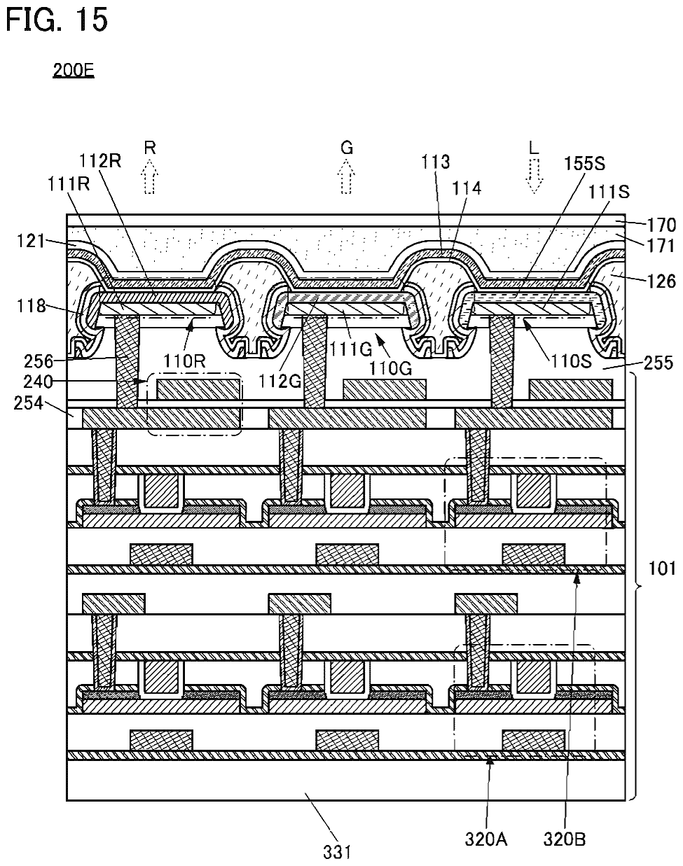

The display apparatus 200E illustrated in FIG. 15 has a structure in which a transistor 320A and a transistor 320B each including an oxide semiconductor in a semiconductor where a channel is formed are stacked.

The description of the display apparatus 200D can be referred to for the transistor 320A, the transistor 320B, and the components around them.

Although the structure in which two transistors including an oxide semiconductor are stacked is described, the present invention is not limited thereto. For example, three or more transistors may be stacked.

### [Display Apparatus 200F]

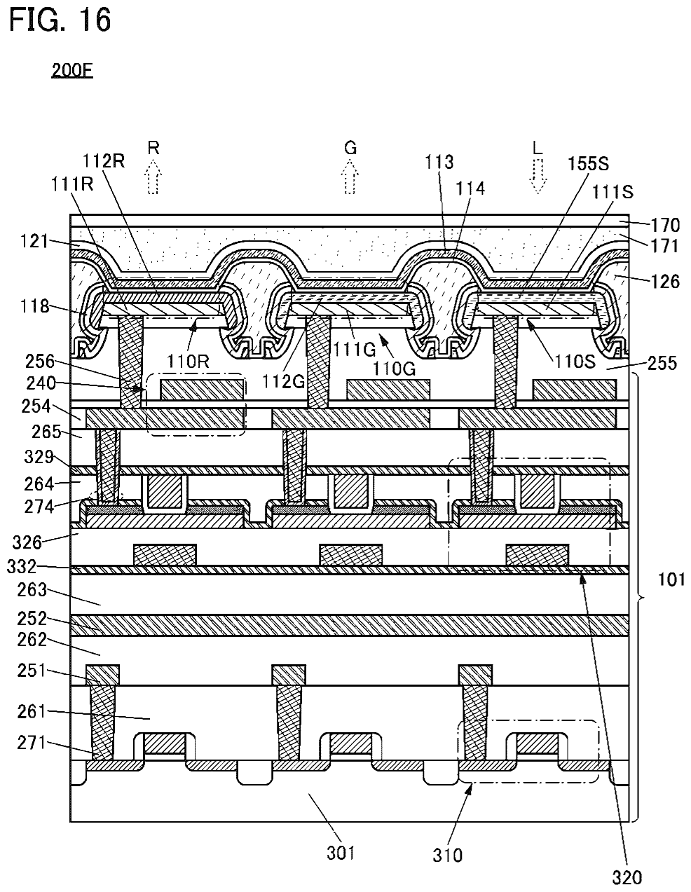

The display apparatus 200F illustrated in FIG. 16 has a structure in which the transistor 310 whose channel is formed in the substrate 301 and the transistor 320 including a metal oxide in the semiconductor layer where the channel is formed are stacked.

The insulating layer 261 is provided to cover the transistor 310, and a conductive layer 251 is provided over the insulating layer 261. An insulating layer 262 is provided to cover the conductive layer 251, and a conductive layer 252 is provided over the insulating layer 262. The conductive layer 251 and the conductive layer 252 each function as a wiring. An insulating layer 263 and the insulating layer 332 are provided to cover the conductive layer 252, and the transistor 320 is provided over the insulating layer 332. The insulating layer 265 is provided to cover the transistor 320, and the capacitor 240 is provided over the insulating layer 265. The capacitor 240 and the transistor 320 are electrically connected to each other through the plug 274.

The transistor 320 can be used as a transistor included in the pixel circuit. The transistor 310 can be used as a transistor included in the pixel circuit or a transistor included in a driver circuit (a gate line driver circuit or a source line driver circuit) for driving the pixel circuit. The transistor 310 and the transistor 320 can also be used as transistors included in a variety of circuits such as an arithmetic circuit and a memory circuit.

With such a structure, not only the pixel circuit but also the driver circuit and the like can be formed directly under the light-emitting elements; thus, the display panel can be downsized as compared with the case where a driver circuit is provided around a display region.

### [Display Apparatus 200G]

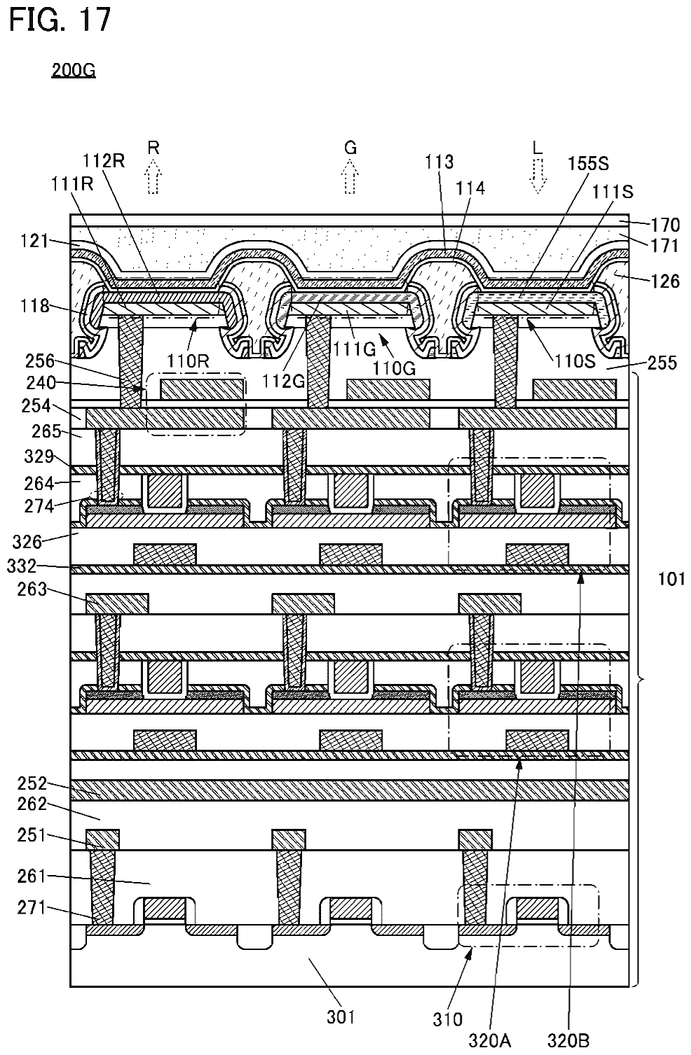

A display apparatus 200G illustrated in FIG. 17 has a structure in which the transistor 310 whose channel is formed in the substrate 301, the transistor 320A including a metal oxide in the semiconductor layer where the channel is formed, and the transistor 320B are stacked.

The transistor 320A can be used as a transistor included in the pixel circuit. The transistor 310 can be used as a transistor included in the pixel circuit or a transistor included in a driver circuit (a gate line driver circuit or a source line driver circuit) for driving the pixel circuit. The transistor 320B may be used as a transistor included in the pixel circuit or a transistor included in the driver circuit. The transistor 310, the transistor 320A, and the transistor 320B can also be used as transistors included in a variety of circuits such as an arithmetic circuit and a storage circuit.

Components such as a transistor that can be employed in the display apparatus will be described below.

### [Transistor]

The transistors each include a conductive layer functioning as a gate electrode, a semiconductor layer, a conductive layer functioning as a source electrode, a conductive layer functioning as a drain electrode, and an insulating layer functioning as a gate insulating layer.

Note that there is no particular limitation on the structure of the transistor included in the display apparatus of one embodiment of the present invention. For example, a planar transistor, a staggered transistor, or an inverted staggered transistor may be used. A top-gate or a bottom-gate transistor structure may be employed. Gate electrodes may be provided above and below a channel.

There is no particular limitation on the crystallinity of a semiconductor material used for the transistors, and any of an amorphous semiconductor, and a semiconductor having crystallinity (a microcrystalline semiconductor, a polycrystalline semiconductor, a single crystal semiconductor, or a semiconductor partly including crystal regions) may be used. A semiconductor having crystallinity is preferably used because deterioration of the transistor characteristics can be inhibited.

In particular, a transistor in which a metal oxide film is used for a semiconductor layer where a channel is formed will be described below.

As a semiconductor material used for the transistor, a metal oxide whose energy gap is greater than or equal to 2 eV, preferably greater than or equal to 2.5 eV, further preferably greater than or equal to 3 eV can be used. A typical example is a metal oxide containing indium, and a CAC-OS described later can be used, for example.

A transistor using a metal oxide having a wider band gap and a lower carrier density than silicon has a low off-state current; thus, charges accumulated in a capacitor that is connected in series with the transistor can be held for a long time.

The semiconductor layer can be, for example, a film represented by an In-M-Zn-based oxide that contains indium, zinc, and M (M is a metal such as aluminum, titanium, gallium, germanium, yttrium, zirconium, lanthanum, cerium, tin, neodymium, or hafnium).

In the case where the metal oxide contained in the semiconductor layer is an In-M-Zn oxide, the atomic ratio of the metal elements of a sputtering target used for forming a film of the In-M-Zn oxide preferably satisfies In≥M and Zn≥M. The atomic ratio of metal elements of such a sputtering target is preferably In:M:Zn=1:1:1, In:M:Zn=1:1:1.2, In:M:Zn=1:1:2, In:M:Zn=3:1:2, In:M:Zn=4:2:3, In:M:Zn=4:2:4.1, In:M:Zn=5:1:6, In:M:Zn=5:1:7, In:M:Zn=5:1:8, or the like. Note that the atomic ratio in the deposited semiconductor layer varies from the atomic ratio of metal elements contained in the sputtering target in a range of +40%.

A metal oxide film with a low carrier concentration is used as the semiconductor layer. For example, for the semiconductor layer, a metal oxide whose carrier concentration is lower than or equal to 1×10¹⁷ cm⁻³, preferably lower than or equal to 1×10¹⁵ cm⁻³, further preferably lower than or equal to 1×10¹³ cm⁻³, still further preferably lower than or equal to 1×10¹¹ cm⁻³, even further preferably lower than 1×10¹⁰ cm⁻³, and higher than or equal to 1×10⁻⁹ cm⁻³ can be used. Such a metal oxide is referred to as a highly purified intrinsic or substantially highly purified intrinsic metal oxide. The oxide semiconductor has a low density of defect states and can be regarded as a metal oxide having stable characteristics.

Note that the composition is not limited to those, and an oxide semiconductor having an appropriate composition may be used depending on required semiconductor characteristics and electrical characteristics (field-effect mobility, threshold voltage, and the like) of the transistor. In addition, to obtain the required semiconductor characteristics of the transistor, it is preferable that the carrier concentration, impurity concentration, defect density, atomic ratio between a metal element and oxygen, interatomic distance, density, and the like of the semiconductor layer be set to be appropriate.

When silicon or carbon, which is one of Group 14 elements, is contained in the metal oxide that constitutes the semiconductor layer, oxygen vacancies are increased in the semiconductor layer, and the semiconductor layer becomes n-type. Thus, the concentration (concentration obtained by secondary ion mass spectrometry) of silicon or carbon in the semiconductor layer is set lower than or equal to 2×10¹⁸ atoms/cm³, preferably lower than or equal to 2×10¹⁷ atoms/cm³.

Alkali metal and alkaline earth metal might generate carriers when bonded to a metal oxide, in which case the off-state current of the transistor might be increased. Thus, the concentration of alkali metal or alkaline earth metal in the semiconductor layer that is obtained by secondary ion mass spectrometry is set to lower than or equal to 1×10¹⁸ atoms/cm³, preferably lower than or equal to 2×10¹⁶ atoms/cm³.

Furthermore, when nitrogen is contained in the metal oxide that constitutes the semiconductor layer, electrons serving as carriers are generated and the carrier concentration is increased, so that the semiconductor layer easily becomes n-type. As a result, a transistor using a metal oxide that contains nitrogen easily have normally-on characteristics. Accordingly, the nitrogen concentration in the semiconductor layer that is obtained by secondary ion mass spectrometry is preferably set to lower than or equal to 5×10¹⁸ atoms/cm³.

Oxide semiconductors are classified into a single crystal oxide semiconductor and a non-single-crystal oxide semiconductor. Examples of the non-single-crystal oxide semiconductor include a CAAC-OS (c-axis-aligned crystalline oxide semiconductor), a polycrystalline oxide semiconductor, an nc-OS (nanocrystalline oxide semiconductor), an amorphous-like oxide semiconductor (a-like OS), and an amorphous oxide semiconductor.

In addition, a CAC-OS (cloud-aligned composite oxide semiconductor) may be used for a semiconductor layer of a transistor disclosed in one embodiment of the present invention.

Note that the above-mentioned non-single-crystal oxide semiconductor can be suitably used for a semiconductor layer of a transistor disclosed in one embodiment of the present invention. In addition, as the non-single-crystal oxide semiconductor, an nc-OS, a CAAC-OS, or a CAC-OS can be suitably used.

The semiconductor layer may be a mixed film including two or more kinds of a region of a CAAC-OS, a region of a polycrystalline oxide semiconductor, a region of an nc-OS, a region of a CAC-OS, a region of an amorphous-like oxide semiconductor, and a region of an amorphous oxide semiconductor. The mixed film has, for example, a single-layer structure or a stacked-layer structure including two or more kinds of regions selected from the above regions in some cases.

Furthermore, unlike a transistor including low-temperature polysilicon, the transistor including a metal oxide film in the semiconductor layer does not need a laser crystallization step. Thus, the manufacturing cost of a display apparatus can be reduced even when the display apparatus is formed using a large area substrate. In addition, the transistor including a CAC-OS in the semiconductor layer is preferably used for a driver circuit and a display portion in a large display apparatus having high resolution such as ultra-high definition (“4K definition”, “4K2K”, and “4K”) or super high definition (“8K definition”, “8K4K”, and “8K”), in which case writing can be performed in a short time and display defects can be reduced.

Alternatively, silicon may be used for a semiconductor in which a channel of a transistor is formed. As the silicon, amorphous silicon may be used but silicon having crystallinity is particularly preferably used. For example, microcrystalline silicon, polycrystalline silicon, or single crystal silicon is preferably used. In particular, polycrystalline silicon can be formed at a temperature lower than that for single crystal silicon and has higher field-effect mobility and higher reliability than amorphous silicon.

### [Conductive Layer]

Examples of materials that can be used for conductive layers of a variety of wirings and electrodes and the like included in the display apparatus in addition to a gate, a source, and a drain of a transistor include metals such as aluminum, titanium, chromium, nickel, copper, yttrium, zirconium, molybdenum, silver, tantalum, and tungsten and an alloy containing such a metal as its main component. Alternatively, a single layer or a stacked-layer structure including a film containing these materials can be used. For example, a single-layer structure of an aluminum film containing silicon, a two-layer structure in which an aluminum film is stacked over a titanium film, a two-layer structure in which an aluminum film is stacked over a tungsten film, a two-layer structure in which a copper film is stacked over a copper-magnesium-aluminum alloy film, a two-layer structure in which a copper film is stacked over a titanium film, a two-layer structure in which a copper film is stacked over a tungsten film, a three-layer structure in which an aluminum film or a copper film is stacked over a titanium film or a titanium nitride film and a titanium film or a titanium nitride film is formed thereover, and a three-layer structure in which an aluminum film or a copper film is stacked over a molybdenum film or a molybdenum nitride film and a molybdenum film or a molybdenum nitride film is formed thereover can be given. Note that an oxide such as indium oxide, tin oxide, or zinc oxide may be used. Copper containing manganese is preferably used because it increases controllability of a shape by etching.

### [Insulating Layer]

Examples of an insulating material that can be used for each insulating layer include, in addition to a resin such as acrylic resin or an epoxy resin and a resin having a siloxane bond, such as silicone, an inorganic insulating material such as silicon oxide, silicon oxynitride, silicon nitride oxide, silicon nitride, or aluminum oxide.

Note that in this specification, an oxynitride refers to a material that contains more oxygen than nitrogen in its composition, and a nitride oxide refers to a material that contains more nitrogen than oxygen in its composition. For example, in the case where silicon oxynitride is described, it refers to a material that contains more oxygen than nitrogen in its composition. In the case where silicon nitride oxide is described, it refers to a material that contains more nitrogen than oxygen in its composition.

The light-emitting element is preferably provided between a pair of insulating films with low water permeability. In that case, impurities such as water can be inhibited from entering the light-emitting element, and a decrease in the reliability of the device can be inhibited.

Examples of the insulating film with low water permeability include a film containing nitrogen and silicon, such as a silicon nitride film and a silicon nitride oxide film, and a film containing nitrogen and aluminum, such as an aluminum nitride film. Alternatively, a silicon oxide film, a silicon oxynitride film, an aluminum oxide film, or the like may be used.

For example, the moisture vapor transmission rate of the insulating film with low water permeability is lower than or equal to 1×10⁻⁵ [g/(m²·day)], preferably lower than or equal to 1×10⁻⁶ [g/(m²·day)], further preferably lower than or equal to 1×10⁻⁷ [g/(m²·day)], still further preferably lower than or equal to 1×10⁻⁸ [g/(m²·day)].

At least part of this embodiment can be implemented in combination with the other embodiments described in this specification as appropriate.

### [Display Apparatus 200H]

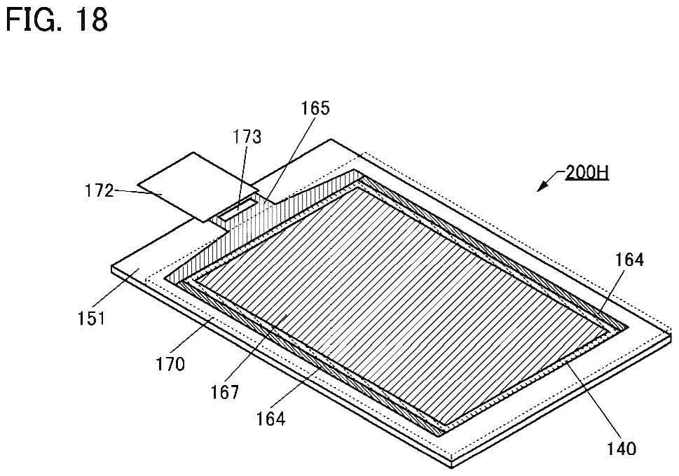

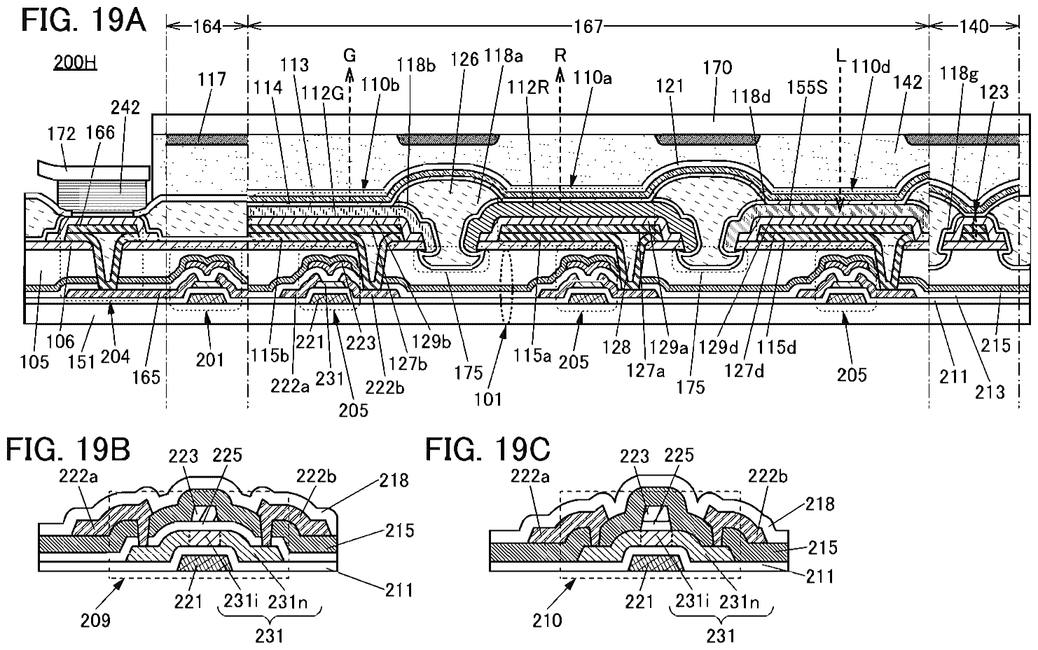

FIG. 18 is a perspective view of a display apparatus 200H, and FIG. 19A is a cross-sectional view of the display apparatus 200H.

The display apparatus 200H has a structure in which the substrate 170 and a substrate 151 are bonded to each other. In FIG. 18, the substrate 170 is denoted by the dashed line.

The display apparatus 200H includes a display portion 167, a connection portion 140, a circuit 164, a wiring 165, and the like. FIG. 18 illustrates an example in which an IC 173 and an FPC 172 are mounted on the display apparatus 200H. Thus, the structure illustrated in FIG. 18 can also be regarded as a display module including the display apparatus 200H, the IC (integrated circuit), and the FPC.

The connection portion 140 is provided outside the display portion 167. The connection portion 140 can be provided along one or more sides of the display portion 167. The number of the connection portions 140 can be one or more. In the example illustrated in FIG. 18, the connection portion 140 is provided to surround the four sides of the display portion. A common electrode of a light-emitting element is electrically connected to a conductive layer in the connection portion 140, and a potential can be supplied to the common electrode.

As the circuit 164, a scan line driver circuit can be used, for example. Although the depressed portion 175 is not provided in the insulating layer 105 in a region where the circuit 164 is provided in the example illustrated in FIG. 19A, the depressed portion 175 may be provided in the insulating layer 105 in the region where the circuit 164 is provided. For example, a transistor included in the circuit 164 may overlap with the depressed portion 175. In such a structure, for example, the insulating layer 105 is located over the transistor included in the circuit 164, and the surface of the insulating layer 105 is covered with an insulating layer that is formed using the same film as the insulating layer 118a, the insulating layer 118b, the insulating layer 118d, and the like.

The wiring 165 has a function of supplying a signal and power to the display portion 167 and the circuit 164. The signal and power are input to the wiring 165 from the outside through the FPC 172 or input to the wiring 165 from the IC 173.

In the example illustrated in FIG. 18, the IC 173 is provided over the substrate 151 by a COG (Chip On Glass) method, a COF (Chip On Film) method, or the like. An IC including a scan line driver circuit, a signal line driver circuit, or the like can be used as the IC 173, for example. Note that the display apparatus 200H and the display module are not necessarily provided with an IC. The IC may be mounted on the FPC by a COF method or the like.

FIG. 19A illustrates an example of cross sections of part of a region including the FPC 172, part of the circuit 164, part of the display portion 167, part of the connection portion 140, and part of a region including an end portion of the display apparatus 200H.

The display apparatus 200H illustrated in FIG. 19A includes a transistor 201, a transistor 205, the light-emitting element 110b, a light-emitting element 110a, a light-receiving element 110d, and the like between the substrate 151 and the substrate 170. The light-emitting element 110a is a light-emitting element that emits red light R, for example. The light-emitting element 110b is a light-emitting element that emits green light G, for example. The light-receiving element 110d is a light-emitting element having a function of detecting light L, for example.

The light-emitting element 110a and the light-emitting element 110b have the same structures as the light-emitting element 110R and the light-emitting element 110G illustrated in FIG. 2A and the like, respectively, except for the structure of the pixel electrode. Embodiment 1 can be referred to for the details of the light-emitting elements and the light-receiving element. The light-receiving element 110d has the same structure as the light-receiving element 110S illustrated in FIG. 2B and the like except for the structure of the pixel electrode. The light-emitting element 110a, the light-emitting element 110b, and the light-receiving element 110d are provided over the insulating layer 105. Although not illustrated, the display apparatus 200H includes a light-emitting element 110c (not illustrated) over the insulating layer 105 between the substrate 151 and the substrate 170, and the light-emitting element 110c has the same structure as the light-emitting element 110B illustrated in FIG. 2A and the like except for the structure of the pixel electrode.

Since the organic layer 112R, the organic layer 112G, and the PS layer 155S are separated from each other in the display apparatus 200H, generation of crosstalk between adjacent subpixels can be inhibited even when the display apparatus 200H has high resolution. Accordingly, the display apparatus can have high resolution and high display quality.

The light-emitting element 110a includes a conductive layer 115a, a conductive layer 127a over the conductive layer 115a, and a conductive layer 129a over the conductive layer 127a. All of the conductive layer 115a, the conductive layer 127a, and the conductive layer 129a can be referred to as pixel electrodes, or one or two of them can be referred to as pixel electrodes.

The light-emitting element 110b includes a conductive layer 115b, a conductive layer 127b over the conductive layer 115b, and a conductive layer 129b over the conductive layer 127b. All of the conductive layer 115b, the conductive layer 127b, and the conductive layer 129b can be referred to as pixel electrodes, or one or two of them can be referred to as pixel electrodes.

The light-receiving element 110d includes a conductive layer 115d, a conductive layer 127d over the conductive layer 115d, and a conductive layer 129d over the conductive layer 127d. All of the conductive layer 115d, the conductive layer 127d, and the conductive layer 129d can be referred to as pixel electrodes, or one or two of them can be referred to as pixel electrodes.

The conductive layer 115a is connected to a conductive layer 222b included in the transistor 205 through an opening provided in the insulating layer 105 and the insulating layer 106. The end portion of the conductive layer 115a and the end portion of the conductive layer 127a are aligned with each other. The end portion of the conductive layer 129a is positioned outward from the end portion of the conductive layer 127a. A reflective conductive layer can be used as the conductive layer 127a, and a light-transmitting conductive layer can be used as the conductive layer 129a, for example.

The conductive layer 115b is connected to the conductive layer 222b included in the transistor 205 through an opening provided in the insulating layer 105 and the insulating layer 106. The end portion of the conductive layer 115b and the end portion of the conductive layer 127b are aligned with each other. The end portion of the conductive layer 129b is located outward from the end portion of the conductive layer 127b. A reflective conductive layer can be used as the conductive layer 127b, and a light-transmitting conductive layer can be used as the conductive layer 129b, for example.

The conductive layer 115d is connected to the conductive layer 222b included in the transistor 205 through an opening provided in the insulating layer 105 and the insulating layer 106. The end portion of the conductive layer 115d and the end portion of the conductive layer 127d are aligned with each other. The end portion of the conductive layer 129d is located outward from the end portion of the conductive layer 127d. A reflective conductive layer can be used as the conductive layer 127d, and a light-transmitting conductive layer can be used as the conductive layer 129d, for example.

Depressed portions are formed in the conductive layers 115a, 115b, and 115d to cover the openings provided in the insulating layer 105 and the insulating layer 106. A layer 128 is embedded in each of the depressed portions.

The layer 128 has a planarization function for the depressed portions of the conductive layer 115a, the conductive layer 115b, and the conductive layer 115d. The conductive layer 127a, the conductive layer 127b, and the conductive layer 127d electrically connected to the conductive layers 115a, 115b, and 115d, respectively, are provided over the conductive layer 115a, the conductive layer 115b, the conductive layer 115d, and the layer 128. Thus, regions overlapping with the depressed portions of the conductive layer 115a, the conductive layer 115b, and the conductive layer 115d can also be used as light-emitting regions, increasing the aperture ratio of the pixels.

The layer 128 may be an insulating layer or a conductive layer. Any of a variety of inorganic insulating materials, organic insulating materials, and conductive materials can be used for the layer 128 as appropriate. In particular, the layer 128 is preferably formed using an insulating material.

An insulating layer containing an organic material can be suitably used for the layer 128. For example, an acrylic resin, a polyimide resin, an epoxy resin, a polyamide resin, a polyimide-amide resin, a siloxane resin, a benzocyclobutene-based resin, a phenol resin, a precursor of any of these resins, or the like can be used for the layer 128. A photosensitive resin can also be used for the layer 128. As the photosensitive resin, a positive photosensitive material or a negative photosensitive material can be used.

When a photosensitive resin is used, the layer 128 can be formed through only light-exposure and development processes, reducing the influence of dry etching, wet etching, or the like on the surfaces of the conductive layer 115a, the conductive layer 115b, and the conductive layer 115d. When the layer 128 is formed using a negative photosensitive resin, the layer 128 can sometimes be formed using the same photomask (light-exposure mask) as the photomask used for forming the opening in the insulating layer 105 and the insulating layer 106.

The top surface and the side surface of the conductive layer 129a are covered with the organic layer 112R. Similarly, the top surface and the side surface of the conductive layer 129b are covered with the organic layer 112G. The top surface and the side surface of the conductive layer 129d are covered with the PS layer 155S. Accordingly, regions where the conductive layer 127a, the conductive layer 127b, and the conductive layer 127d are provided can be entirely used as the light-emitting regions or the light-receiving region of the light-emitting element 110a, the light-emitting element 110b, and the light-receiving element 110d, thereby increasing the aperture ratio of the pixels.

The protective layer 121 is provided over each of the light-emitting element 110a, the light-emitting element 110b, and the light-receiving element 110d. Providing the protective layer 121 covering the light-emitting element inhibits an impurity such as water from entering the light-emitting element, thereby increasing the reliability of the light-emitting element.

The protective layer 121 and the substrate 170 are bonded to each other with an adhesive layer 142. A solid sealing structure, a hollow sealing structure, or the like can be employed to seal the light-emitting elements. In FIG. 19A, a solid sealing structure is employed in which a space between the substrate 170 and the substrate 151 is filled with the adhesive layer 142. Alternatively, a hollow sealing structure in which the space is filled with an inert gas (e.g., nitrogen or argon) may be employed. Here, the adhesive layer 142 may be provided not to overlap with the light-emitting elements. The space may be filled with a resin different from that of the frame-like adhesive layer 142. For the adhesive layer 142, the description of the adhesive layer 171 can be referred to.

A conductive layer 123 is provided over the insulating layer 105 and the insulating layer 106 in the connection portion 140. In the illustrate example, the conductive layer 123 has a stacked-layer structure of a conductive film obtained by processing the same conductive film as the conductive layer 115a, the conductive layer 115b, and the conductive layer 115d; a conductive film obtained by processing the same conductive film as the conductive layer 127a, the conductive layer 127b, and the conductive layer 127d; and a conductive film obtained by processing the same conductive film as the conductive layer 129a, the conductive layer 129b, and the conductive layer 129d. The end portion of the conductive layer 123 is covered with the insulating layer 118a, the insulating layer 125, and the resin layer 126. The common layer 114 is provided over the conductive layer 123, and the common electrode 113 is provided over the common layer 114. The conductive layer 123 and the common electrode 113 are electrically connected to each other through the common layer 114. Note that the common layer 114 is not necessarily formed in the connection portion 140. In that case, the conductive layer 123 and the common electrode 113 are in direct contact with each other to be electrically connected to each other. The depressed portion 175 including a region overlapping with the conductive layer 123 is provided in the insulating layer 105. An insulating layer 118g is provided to cover the side surface and the top surface of the conductive layer 123. The insulating layer 118g can be formed by processing the same insulating film as the insulating layer 118a, the insulating layer 118b, the insulating layer 118c (not illustrated), the insulating layer 118d, and the like. When the insulating layer 118g is provided to cover the side surface and the top surface of the conductive layer 123 in the connection portion 140, the adhesion of the conductive layer 123 with the insulating layer 106 is improved in some cases.

The display apparatus 200H has a top-emission structure. Light emitted by the light-emitting element is emitted toward the substrate 170 side. For the substrate 170, a material having a high visible-light-transmitting property is preferably used. The pixel electrode contains a material that reflects visible light, and a counter electrode (the common electrode 113) contains a material that transmits visible light.

A stacked-layer structure from the substrate 151 to an insulating layer 215 corresponds to the substrate 101 including transistors in Embodiment 1.

The transistor 201 and the transistor 205 are formed over the substrate 151. These transistors can be formed using the same material in the same process.

An insulating layer 211, an insulating layer 213, the insulating layer 215, the insulating layer 105, and the insulating layer 106 are provided in this order over the substrate 151.

For the insulating layer 105 and the insulating layer 106, the description in Embodiment 1 can be referred to.

Part of the insulating layer 211 functions as a gate insulating layer of each transistor. Part of the insulating layer 213 functions as a gate insulating layer of each transistor. The insulating layer 215 is provided to cover the transistors. The insulating layer 105 is provided to cover the transistors and has a function of a planarization layer. Note that the number of gate insulating layers and the number of insulating layers covering the transistors are not limited and may each be one or two or more.

A material that does not easily allow diffusion of impurities such as water and hydrogen is preferably used for at least one of the insulating layers that cover the transistors. This allows the insulating layer to function as a barrier layer. Such a structure can effectively inhibit diffusion of impurities into the transistors from the outside and increase the reliability of a display apparatus.

An inorganic insulating film is preferably used as each of the insulating layer 211, the insulating layer 213, and the insulating layer 215. As the inorganic insulating film, a silicon nitride film, a silicon oxynitride film, a silicon oxide film, a silicon nitride oxide film, an aluminum oxide film, an aluminum nitride film, or the like can be used, for example. A hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may be used. A stack including two or more of the above insulating films may also be used.

Each of the transistor 201 and the transistor 205 includes a conductive layer 221 functioning as a gate, the insulating layer 211 functioning as a gate insulating layer, a conductive layer 222a and the conductive layer 222b functioning as a source and a drain, a semiconductor layer 231, the insulating layer 213 functioning as a gate insulating layer, and a conductive layer 223 functioning as a gate. Here, a plurality of layers obtained by processing the same conductive film are shown with the same hatching pattern. The insulating layer 211 is positioned between the conductive layer 221 and the semiconductor layer 231. The insulating layer 213 is positioned between the conductive layer 223 and the semiconductor layer 231.

There is no particular limitation on the structure of the transistors included in the display apparatus of this embodiment. For example, a planar transistor, a staggered transistor, an inverted staggered transistor, or the like can be used. A top-gate or a bottom-gate transistor structure may be employed. Alternatively, gates may be provided above and below the semiconductor layer where a channel is formed.

The structure in which the semiconductor layer where a channel is formed is provided between two gates is used for the transistor 201 and the transistor 205. The two gates may be connected to each other and supplied with the same signal to drive the transistor. Alternatively, a potential for controlling the threshold voltage may be supplied to one of the two gates and a potential for driving may be supplied to the other to control the threshold voltage of the transistor.

There is no particular limitation on the crystallinity of a semiconductor material used for the transistors, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. It is preferable to use a single crystal semiconductor or a semiconductor having crystallinity because degradation of transistor characteristics can be inhibited.

The semiconductor layer of the transistor preferably includes a metal oxide (also referred to as an oxide semiconductor). That is, a transistor including a metal oxide in its channel formation region (hereinafter, referred to as an OS transistor) is preferably used for the display apparatus of this embodiment.

As the oxide semiconductor having crystallinity, a CAAC (c-axis aligned crystalline)-OS, an nc (nanocrystalline)-OS, and the like can be given.

Alternatively, a transistor using silicon in its channel formation region (a Si transistor) may be used. Examples of silicon include single crystal silicon, polycrystalline silicon, and amorphous silicon. In particular, a transistor containing low-temperature polysilicon (LTPS) in its semiconductor layer (hereinafter also referred to as an LTPS transistor) can be used. The LTPS transistor has high field-effect mobility and excellent frequency characteristics.

With the use of Si transistors such as LTPS transistors, a circuit required to be driven at a high frequency (e.g., a source driver circuit) can be formed on the same substrate as the display portion. Thus, external circuits mounted on the display apparatus can be simplified, whereby component cost and mounting cost can be reduced.

An OS transistor has much higher field-effect mobility than a transistor using amorphous silicon. In addition, the OS transistor has extremely low leakage current between a source and a drain in an off state (hereinafter, also referred to as off-state current), and charge accumulated in a capacitor that is connected in series to the transistor can be retained for a long period. Furthermore, the power consumption of the display apparatus can be reduced with the OS transistor.

The off-state current value per micrometer of channel width of the OS transistor at room temperature can be lower than or equal to 1 aA (1×10⁻¹⁸ A), lower than or equal to 1 zA (1×10⁻²¹ A), or lower than or equal to 1 yA (1×10⁻²⁴ A). Note that the off-state current value per micrometer of channel width of a Si transistor at room temperature is higher than or equal to 1 fA (1×10⁻¹⁵ A) and lower than or equal to 1 pA (1×10⁻¹² A). In other words, the off-state current of an OS transistor is lower than that of a Si transistor by approximately ten orders of magnitude.

To increase the emission luminance of the light-emitting element included in the pixel circuit, the amount of current fed through the light-emitting element needs to be increased. For that purpose, the source-drain voltage of the driving transistor included in the pixel circuit needs to be increased. Since an OS transistor has a higher withstand voltage between the source and the drain than a Si transistor, a high voltage can be applied between the source and the drain of the OS transistor. Accordingly, when an OS transistor is used as the driving transistor included in the pixel circuit, the amount of current flowing through the light-emitting element can be increased, so that the emission luminance of the light-emitting element can be increased.

When a transistor operates in a saturation region, a change in source-drain current relative to a change in gate-source voltage can be smaller in an OS transistor than in a Si transistor. Accordingly, when an OS transistor is used as the driving transistor included in the pixel circuit, the amount of current flowing between the source and the drain can be set minutely by a change in gate-source voltage; hence, the amount of current flowing through the light-emitting element can be controlled. Accordingly, the number of gray levels in the pixel circuit can be increased. Regarding saturation characteristics of current flowing when a transistor operates in a saturation region, even in the case where the source-drain voltage of an OS transistor increases gradually, more stable current (saturation current) can be fed through the OS transistor than through a Si transistor. Thus, by using an OS transistor as the driving transistor, stable constant current can be fed through a light-emitting element even when the current-voltage characteristics of an EL device vary, for example. In other words, when the OS transistor operates in the saturation region, the source-drain current hardly changes with an increase in the source-drain voltage; hence, the emission luminance of the light-emitting element can be stable.

As described above, the use of the OS transistor as the driving transistor included in the pixel circuit enables “inhibition of black floating”, “an increase in emission luminance”, “an increase in gray levels”, “inhibition of variation in light-emitting elements”, and the like.

The semiconductor layer preferably contains indium, M (M is one or more selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. Specifically, M is preferably one or more selected from aluminum, gallium, yttrium, and tin.

It is particularly preferable that an oxide containing indium (In), gallium (Ga), and zinc (Zn) (also referred to as IGZO) be used for the semiconductor layer. Alternatively, it is preferable to use an oxide containing indium, tin, and zinc. Alternatively, it is preferable to use an oxide containing indium, gallium, tin, and zinc. Alternatively, it is preferable to use an oxide containing indium (In), aluminum (Al), and zinc (Zn) (also referred to as IAZO). Alternatively, it is preferable to use an oxide containing indium (In), aluminum (Al), gallium (Ga), and zinc (Zn) (also referred to as IAGZO).

In the case where the semiconductor layer is an In-M-Zn oxide, the atomic proportion of In is preferably greater than or equal to the atomic proportion of M in the In-M-Zn oxide. Examples of the atomic ratio of the metal elements in such an In-M-Zn oxide include In:M:Zn=1:1:1 or a composition in the neighborhood thereof, In:M:Zn=1:1:1.2 or a composition in the neighborhood thereof, In:M:Zn=1:3:2 or a composition in the neighborhood thereof, In:M:Zn=1:3:4 or a composition in the neighborhood thereof, In:M:Zn=2:1:3 or a composition in the neighborhood thereof, In:M:Zn=3:1:2 or a composition in the neighborhood thereof, In:M:Zn=4:2:3 or a composition in the neighborhood thereof, In:M:Zn=4:2:4.1 or a composition in the neighborhood thereof, In:M:Zn=5:1:3 or a composition in the neighborhood thereof, In:M:Zn=5:1:6 or a composition in the neighborhood thereof, In:M:Zn=5:1:7 or a composition in the neighborhood thereof, In:M:Zn=5:1:8 or a composition in the neighborhood thereof, In:M:Zn=6:1:6 or a composition in the neighborhood thereof, and In:M:Zn=5:2:5 or a composition in the neighborhood thereof. Note that a composition in the neighborhood includes the range of +30% of an intended atomic ratio.

For example, when the atomic ratio is described as In:Ga:Zn=4:2:3 or a composition in the neighborhood thereof, the case is included where Ga is greater than or equal to 1 and less than or equal to 3 and Zn is greater than or equal to 2 and less than or equal to 4 with In being 4. When the atomic ratio is described as In:Ga:Zn=5:1:6 or a composition in the neighborhood thereof, the case is included where Ga is greater than 0.1 and less than or equal to 2 and Zn is greater than or equal to 5 and less than or equal to 7 with In being 5. When the atomic ratio is described as In:Ga:Zn=1:1:1 or a composition in the neighborhood thereof, the case is included where Ga is greater than 0.1 and less than or equal to 2 and Zn is greater than 0.1 and less than or equal to 2 with In being 1.

The transistor included in the circuit 164 and the transistor included in the display portion 167 may have the same structure or different structures. A plurality of transistors included in the circuit 164 may have the same structure or two or more kinds of structures. Similarly, a plurality of transistors included in the display portion 167 may have the same structure or two or more kinds of structures

All of the transistors included in the display portion 167 may be OS transistors or all of the transistors included in the display portion 167 may be Si transistors; alternatively, some of the transistors included in the display portion 167 may be OS transistors and the others may be Si transistors.

For example, when both an LTPS transistor and an OS transistor are used in the display portion 167, the display apparatus can have low power consumption and high drive capability. Note that a structure where an LTPS transistor and an OS transistor are combined is referred to as LTPO in some cases. As a favorable example, it is preferable that the OS transistor be used as a transistor functioning as a switch for controlling conduction or non-conduction between wirings and the LTPS transistor be used as a transistor for controlling current.

For example, one of the transistors included in the display portion 167 functions as a transistor for controlling a current flowing through the light-emitting element and can also be referred to as a driving transistor. One of a source and a drain of the driving transistor is electrically connected to the pixel electrode of the light-emitting element. An LTPS transistor is preferably used as the driving transistor. In that case, the amount of current flowing through the light-emitting element can be increased in the pixel circuit.

In contrast, another transistor included in the display portion 167 functions as a switch for controlling selection or non-selection of a pixel and can also be referred to as a selection transistor. A gate of the selection transistor is electrically connected to a gate line, and one of a source and a drain thereof is electrically connected to a source line (signal line). An OS transistor is preferably used as the selection transistor. Accordingly, the gray level of the pixel can be maintained even with an extremely low frame frequency (e.g., lower than or equal to 1 fps); thus, power consumption can be reduced by stopping the driver in displaying a still image.

As described above, the display apparatus of one embodiment of the present invention can have all of a high aperture ratio, high resolution, high display quality, and low power consumption.

Note that the display apparatus of one embodiment of the present invention has a structure including the OS transistor and the light-emitting element having an MML (metal maskless) structure. With this structure, leakage current that might flow through the transistor and leakage current that might flow between adjacent light-emitting elements (also referred to as lateral leakage current, side leakage current, or the like) can become extremely low. With the structure, a viewer can notice any one or more of the image crispness, the image sharpness, a high chroma, and a high contrast ratio in an image displayed on the display apparatus. Note that with the structure where the leakage current that might flow through the transistor and the lateral leakage current that might flow between light-emitting elements are extremely low, display with little leakage of light at the time of black display can be achieved.

FIG. 19B and FIG. 19C show other structure examples of transistors.

A transistor 209 and a transistor 210 each include the conductive layer 221 functioning as a gate, the insulating layer 211 functioning as a gate insulating layer, the semiconductor layer 231 including a channel formation region 231i and a pair of low-resistance regions 231n, the conductive layer 222a connected to one of the pair of low-resistance regions 231n, the conductive layer 222b connected to the other of the pair of the low-resistance regions 231n, an insulating layer 225 functioning as a gate insulating layer, the conductive layer 223 functioning as a gate, and the insulating layer 215 covering the conductive layer 223. The insulating layer 211 is positioned between the conductive layer 221 and the channel formation region 231i. The insulating layer 225 is positioned between at least the conductive layer 223 and the channel formation region 231i. Furthermore, an insulating layer 218 covering the transistor may be provided.

FIG. 19B shows an example of the transistor 209 in which the insulating layer 225 covers the top surface and the side surface of the semiconductor layer 231. The conductive layer 222a and the conductive layer 222b are connected to the low-resistance regions 231n through openings provided in the insulating layer 225 and the insulating layer 215. One of the conductive layer 222a and the conductive layer 222b functions as a source, and the other functions as a drain.

Meanwhile, in the transistor 210 shown in FIG. 19C, the insulating layer 225 overlaps with the channel formation region 231i of the semiconductor layer 231 and does not overlap with the low-resistance regions 231n. The structure shown in FIG. 19C can be formed by processing the insulating layer 225 using the conductive layer 223 as a mask, for example. In FIG. 19C, the insulating layer 215 is provided to cover the insulating layer 225 and the conductive layer 223, and the conductive layer 222a and the conductive layer 222b are connected to the low-resistance regions 231n through the openings in the insulating layer 215.

A connection portion 204 is provided in a region of the substrate 151 not overlapping with the substrate 170. In the connection portion 204, the wiring 165 is electrically connected to the FPC 172 through a conductive layer 166 and a connection layer 242. In the illustrated example, the conductive layer 166 has a stacked-layer structure of a conductive film obtained by processing the same conductive film as the conductive layer 115a, the conductive layer 115b, and the conductive layer 115d, a conductive film obtained by processing the same conductive film as the conductive layer 127a, the conductive layer 127b, and the conductive layer 127d, and a conductive film obtained by processing the same conductive film as the conductive layer 129a, the conductive layer 129b, and the conductive layer 129d. On the top surface of the connection portion 204, the conductive layer 166 is exposed. Thus, the connection portion 204 and the FPC 172 can be electrically connected to each other through the connection layer 242. Although the depressed portion 175 is not provided around the region where the connection layer 242 is provided in the example illustrated in FIG. 19A, the depressed portion 175 may be provided around the region where the connection layer 242 is provided. In such a structure, the depressed portion 175 is provided so as to surround the connection layer 242 in a top view, for example.

A light-blocking layer 117 is preferably provided on the surface of the substrate 170 on the substrate 151 side. The light-blocking layer 117 can be provided between adjacent light-emitting elements, in the connection portion 140, and in the circuit 164, for example. Any of a variety of optical members can be arranged on the outer surface of the substrate 170.

As each of the substrate 151 and the substrate 170, a glass substrate, a quartz substrate, a sapphire substrate, a ceramic substrate, a metal, an alloy, a semiconductor, or the like can be given. Alternatively, a single crystal semiconductor substrate or a polycrystalline semiconductor substrate using silicon or silicon carbide as a material, a compound semiconductor substrate of silicon germanium or the like, or a semiconductor substrate such as an SOI substrate can be used. When a flexible material is used for the substrate, the flexibility of the display apparatus can be increased. Furthermore, a polarizing plate may be used as the substrate.

For the substrate, it is possible to use polyester resins such as polyethylene terephthalate (PET) and polyethylene naphthalate (PEN), a polyacrylonitrile resin, an acrylic resin, a polyimide resin, a polymethyl methacrylate resin, a polycarbonate (PC) resin, a polyethersulfone (PES) resin, polyamide resins (e.g., nylon and aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, cellulose nanofiber, and the like. Glass that is thin enough to have flexibility may be used as the substrate.

In the case where a circularly polarizing plate overlaps with the display apparatus, a highly optically isotropic substrate is preferably used as the substrate included in the display apparatus. A highly optically isotropic substrate has a low birefringence (in other words, a small amount of birefringence).

The absolute value of a retardation (phase difference) of a highly optically isotropic substrate is preferably less than or equal to 30 nm, further preferably less than or equal to 20 nm, still further preferably less than or equal to 10 nm.

Examples of the films having high optical isotropy include a triacetyl cellulose (TAC, also referred to as cellulose triacetate) film, a cycloolefin polymer (COP) film, a cycloolefin copolymer (COC) film, and an acrylic film.

In the case where a film is used as the substrate and the film absorbs water, the shape of the display apparatus might be changed, e.g., creases might be caused. Thus, as the substrate, a film with a low water absorption rate is preferably used. For example, a film with a water absorption rate lower than or equal to 1% is preferably used, a film with a water absorption rate lower than or equal to 0.1% is further preferably used, and a film with a water absorption rate lower than or equal to 0.01% is still further preferably used.

As the connection layer 242, an anisotropic conductive film (ACF), an anisotropic conductive paste (ACP), or the like can be used.

### [Structure Example of Display Apparatus]

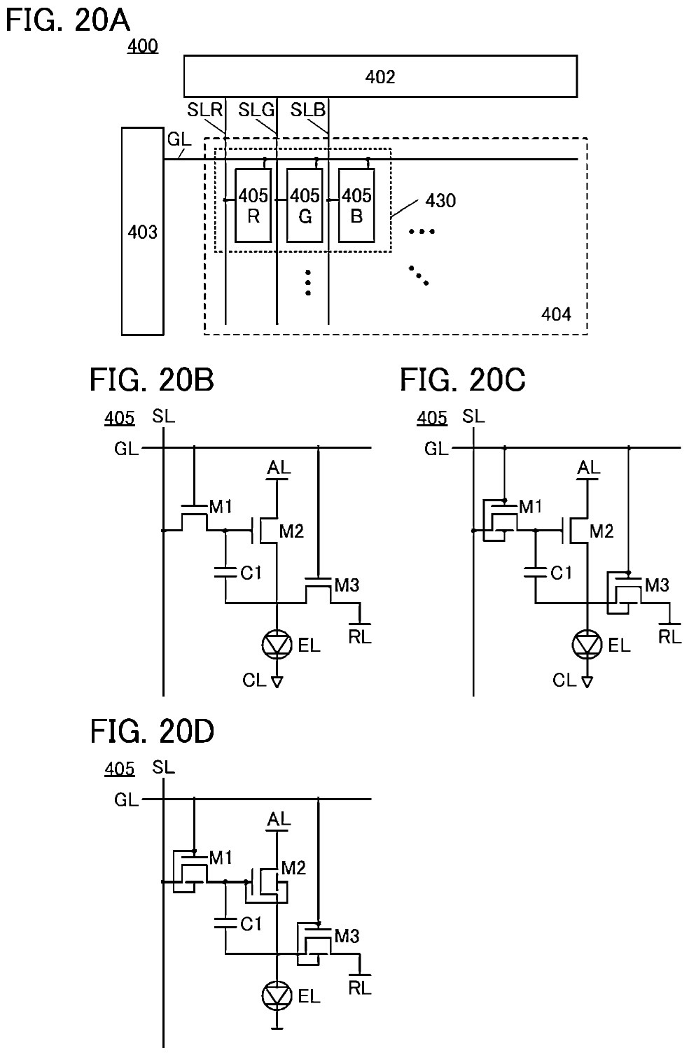

FIG. 20A illustrates a block diagram of a display apparatus 400. The display apparatus 400 includes a display portion 404, a driver circuit portion 402, a driver circuit portion 403, and the like.

The display portion 404 includes a plurality of pixels 430 arranged in a matrix. The pixels 430 each include a subpixel 405R, a subpixel 405G, and a subpixel 405B. The subpixel 405R, the subpixel 405G, and the subpixel 405B each include a light-emitting element functioning as a display device.

The pixel 430 is electrically connected to a wiring GL, a wiring SLR, a wiring SLG, and a wiring SLB. The wiring SLR, the wiring SLG, and the wiring SLB are each electrically connected to the driver circuit portion 402. The wiring GL is electrically connected to the driver circuit portion 403. The driver circuit portion 402 functions as a source line driver circuit (also referred to as a source driver), and the driver circuit portion 403 functions as a gate line driver circuit (also referred to as a gate driver). The wiring GL functions as a gate line, and the wiring SLR, the wiring SLG, and the wiring SLB each function as a source line.

The subpixel 405R includes a light-emitting element that emits red light. The subpixel 405G includes a light-emitting element that emits green light. The subpixel 405B includes a light-emitting element that emits blue light. Thus, the display apparatus 400 can perform full-color display. Note that the pixel 430 may include a subpixel including a light-emitting element that emits light of another color. For example, the pixel 430 may include, in addition to the above three subpixels, a subpixel including a light-emitting element that emits white light, a subpixel including a light-emitting element that emits yellow light, or the like.

The wiring GL is electrically connected to the subpixel 405R, the subpixel 405G, and the subpixel 405B arranged in a row direction (an extending direction of the wiring GL). The wiring SLR, the wiring SLG, and the wiring SLB are electrically connected to the subpixels 405R, the subpixels 405G, and the subpixels 405B (not illustrated) arranged in a column direction (an extending direction of the wiring SLR and the like), respectively.

### [Structure Example of Pixel Circuit]

FIG. 20B illustrates an example of a circuit diagram of a pixel 405 that can be used as the subpixel 405R, the subpixel 405G, and the subpixel 405B. The pixel 405 includes a transistor M1, a transistor M2, a transistor M3, a capacitor C1, and a light-emitting element EL. The wiring GL and a wiring SL are electrically connected to the pixel 405. The wiring SL corresponds to any of the wiring SLR, the wiring SLG, and the wiring SLB illustrated in FIG. 20A.

A gate of the transistor M1 is electrically connected to the wiring GL, one of a source and a drain of the transistor M1 is electrically connected to the wiring SL, and the other thereof is electrically connected to one electrode of the capacitor C1 and a gate of the transistor M2. One of a source and a drain of the transistor M2 is electrically connected to a wiring AL, and the other of the source and the drain of the transistor M2 is electrically connected to one electrode of the light-emitting element EL, the other electrode of the capacitor C1, and one of a source and a drain of the transistor M3. A gate of the transistor M3 is electrically connected to the wiring GL, and the other of the source and the drain of the transistor M3 is electrically connected to a wiring RL. The other electrode of the light-emitting element EL is electrically connected to a wiring CL.

A data potential is supplied to the wiring SL. A selection signal is supplied to the wiring GL. The selection signal includes a potential for bringing a transistor into a conducting state and a potential for bringing a transistor into a non-conducting state.

A reset potential is supplied to the wiring RL. An anode potential is supplied to a wiring AL. A cathode potential is supplied to the wiring CL. In the pixel 405, the anode potential is a potential higher than the cathode potential. The reset potential supplied to the wiring RL can be set such that a potential difference between the reset potential and the cathode potential is lower than the threshold voltage of the light-emitting element EL. The reset potential can be a potential higher than the cathode potential, a potential equal to the cathode potential, or a potential lower than the cathode potential.

The transistor M1 and the transistor M3 each function as a switch. The transistor M2 functions as a transistor that controls current flowing through the light-emitting element EL. For example, it can be said that the transistor M1 functions as a selection transistor and the transistor M2 functions as a driving transistor.

Here, it is preferable to use LTPS transistors as all of the transistor M1 to the transistor M3. Alternatively, it is preferable to use OS transistors as the transistor M1 and the transistor M3 and to use an LTPS transistor as the transistor M2.

Alternatively, OS transistors may be used as all of the transistor M1 to the transistor M3. In this case, an LTPS transistor can be used as at least one of a plurality of transistors included in the driver circuit portion 402 and a plurality of transistors included in the driver circuit portion 403, and OS transistors can be used as the other transistors. For example, OS transistors can be used as the transistors provided in the display portion 404, and LTPS transistors can be used as the transistors provided in the driver circuit portion 402 and the driver circuit portion 403.

As the OS transistor, a transistor including an oxide semiconductor in its semiconductor layer where a channel is formed can be used. The semiconductor layer preferably contains indium, M (M is one or more selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. Specifically, M is preferably one or more selected from aluminum, gallium, yttrium, and tin. It is particularly preferable to use an oxide containing indium, gallium, and zinc (also referred to as IGZO) for the semiconductor layer of the OS transistor. Alternatively, it is preferable to use an oxide containing indium, tin, and zinc. Alternatively, it is preferable to use an oxide containing indium, gallium, tin, and zinc.

A transistor using an oxide semiconductor having a wider band gap and smaller carrier density than silicon can achieve extremely low off-state current. Therefore, owing to the low off-state current, charge accumulated in a capacitor that is connected in series to the transistor can be retained for a long time. Therefore, it is particularly preferable to use a transistor including an oxide semiconductor as each of the transistor M1 and the transistor M3 each of which is connected to the capacitor C1 in series. The use of the transistor including an oxide semiconductor as each of the transistor M1 and the transistor M3 can prevent leakage of charge retained in the capacitor C1 through the transistor M1 or the transistor M3. Furthermore, since charge retained in the capacitor C1 can be retained for a long time, a still image can be displayed for a long time without rewriting data in the pixel 405.

Note that although the transistor is illustrated as an n-channel transistor in FIG. 20B, a p-channel transistor can also be used.

The transistors included in the pixel 405 are preferably formed to be arranged over the same substrate.

Transistors each including a pair of gates overlapping with each other with a semiconductor layer therebetween can be used as the transistors included in the pixel 405.

In the transistor including a pair of gates, the same potential is supplied to the pair of gates electrically connected to each other, which brings advantage that the transistor can have a higher on-state current and improved saturation characteristics. A potential for controlling the threshold voltage of the transistor may be supplied to one of the pair of gates. Furthermore, when a constant potential is supplied to one of the pair of gates, the stability of the electrical characteristics of the transistor can be improved. For example, one of the gates of the transistor may be electrically connected to a wiring to which a constant potential is supplied or may be electrically connected to a source or a drain of the transistor.

The pixel 405 illustrated in FIG. 20C is an example of the case where a transistor including a pair of gates is used as each of the transistor M1 and the transistor M3. In each of the transistor M1 and the transistor M3, the pair of gates are electrically connected to each other. Such a structure can shorten the period in which data is written to the pixel 405.

The pixel 405 illustrated in FIG. 20D is an example where a transistor including a pair of gates is used as the transistor M2 in addition to the transistor M1 and the transistor M3. A pair of gates of the transistor M2 are electrically connected to each other. When such a transistor is used as the transistor M2, the saturation characteristics are improved, whereby emission luminance of the light-emitting element EL can be controlled easily and the display quality can be increased.

### Embodiment 3

In this embodiment, a light-emitting element that can be used in the display apparatus of one embodiment of the present invention will be described.

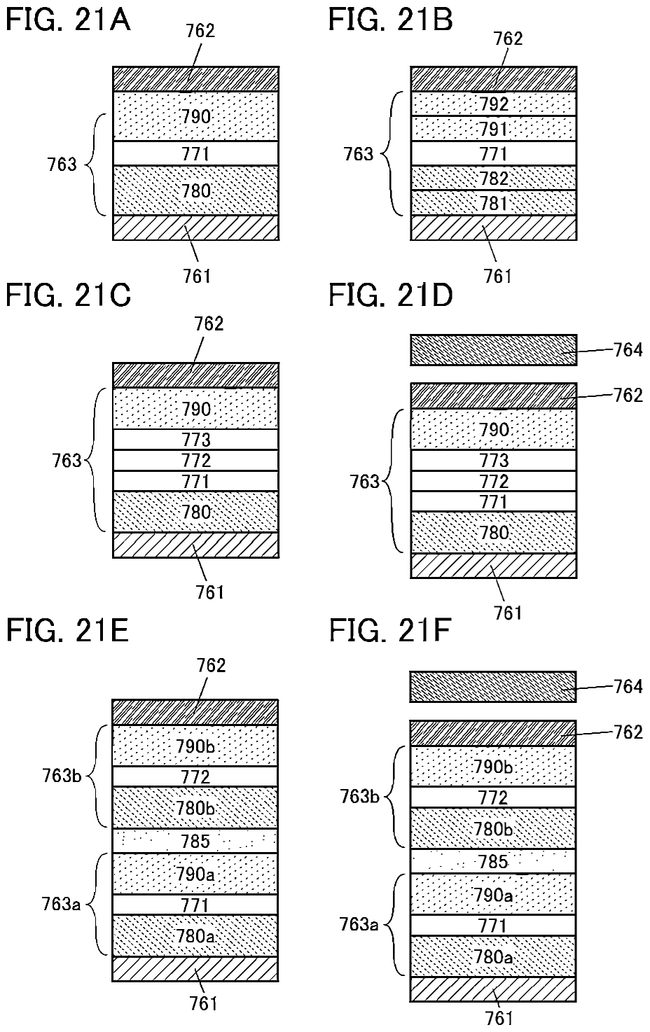

As illustrated in FIG. 21A, the light-emitting element includes an EL layer 763 between a pair of electrodes (a lower electrode 761 and an upper electrode 762). The EL layer 763 can be formed of a plurality of layers such as a layer 780, a light-emitting layer 771, and a layer 790. The light-emitting layer 771 contains at least a light-emitting substance (also referred to as a light-emitting material).

In the case where the lower electrode 761 is an anode and the upper electrode 762 is a cathode, the layer 780 includes one or more of a layer containing a substance having a high hole-injection property (hole-injection layer), a layer containing a substance having a high hole-transport property (hole-transport layer), and a layer containing a substance having a high electron-blocking property (electron-blocking layer). Furthermore, the layer 790 includes one or more of a layer containing a substance having a high electron-injection property (electron-injection layer), a layer containing a substance having a high electron-transport property (electron-transport layer), and a layer containing a substance having a high hole-blocking property (hole-blocking layer). In the case where the lower electrode 761 is a cathode and the upper electrode 762 is an anode, the structures of the layer 780 and the layer 790 are replaced with each other.

The structure including the layer 780, the light-emitting layer 771, and the layer 790, which is provided between the pair of electrodes, can function as a single light-emitting unit, and the structure in FIG. 21A is referred to as a single structure in this specification.

FIG. 21B is a variation example of the EL layer 763 included in the light-emitting element illustrated in FIG. 21A. Specifically, the light-emitting element illustrated in FIG. 21B includes a layer 781 over the lower electrode 761, a layer 782 over the layer 781, the light-emitting layer 771 over the layer 782, a layer 791 over the light-emitting layer 771, a layer 792 over the layer 791, and the upper electrode 762 over the layer 792.

In the case where the lower electrode 761 is an anode and the upper electrode 762 is a cathode, the layer 781 can be a hole-injection layer, the layer 782 can be a hole-transport layer, the layer 791 can be an electron-transport layer, and the layer 792 can be an electron-injection layer, for example. In the case where the lower electrode 761 is a cathode and the upper electrode 762 is an anode, the layer 781 can be an electron-injection layer, the layer 782 can be an electron-transport layer, the layer 791 can be a hole-transport layer, and the layer 792 can be a hole-injection layer. With such a layered structure, carriers can be efficiently injected to the light-emitting layer 771, and the efficiency of the recombination of carriers in the light-emitting layer 771 can be enhanced.

Note that structures in which a plurality of light-emitting layers (a light-emitting layer 771, a light-emitting layer 772, and a light-emitting layer 773) are provided between the layer 780 and the layer 790 as illustrated in FIG. 21C and FIG. 21D are variations of a single structure. Although FIG. 21C and FIG. 21D each illustrate an example in which three light-emitting layers are included, the number of light-emitting layers in the light-emitting element having a single structure may be two or four or more. The light-emitting element having a single structure may include a buffer layer between two light-emitting layers.

A structure in which a plurality of light-emitting units (a light-emitting unit 763a and a light-emitting unit 763b) are connected in series through a charge-generation layer 785 (also referred to as an intermediate layer) as illustrated in FIG. 21E and FIG. 21F is referred to as a tandem structure in this specification. The tandem structure may be referred to as a stack structure. The tandem structure enables a light-emitting element to be capable of high-luminance light emission. Furthermore, the tandem structure allows the amount of current needed for obtaining the same luminance to be reduced as compared to the case of using a single structure, and thus can improve the reliability.

Note that FIG. 21D and FIG. 21F each illustrate an example in which the display apparatus includes a layer 764 overlapping with the light-emitting element. FIG. 21D is an example in which the layer 764 overlaps with the light-emitting element illustrated in FIG. 21C and FIG. 21F illustrates an example in which the layer 764 overlaps with the light-emitting element illustrated in FIG. 21E. In FIG. 21D and FIG. 21F, light is extracted from the upper electrode 762 side, so that a conductive film that transmits visible light is used as the upper electrode 762.

One or both of a color conversion layer and a color filter (a coloring layer) can be used as the layer 764.

In the case where the light-emitting element having a single structure includes three light-emitting layers, for example, a light-emitting layer containing a light-emitting substance emitting red (R) light, a light-emitting layer containing a light-emitting substance emitting green (G) light, and a light-emitting layer containing a light-emitting substance emitting blue (B) light are preferably included. The stacking order of the light-emitting layers can be RGB or RBG from an anode side, for example. In this case, a buffer layer may be provided between R and G or B.

For example, in the case where the light-emitting element with a single structure includes two light-emitting layers, the light-emitting device preferably includes a light-emitting layer containing a light-emitting substance emitting blue (B) light and a light-emitting layer containing a light-emitting substance emitting yellow (Y) light. This structure may be referred to as a device with a BY single structure.

In the light-emitting element that emits white light, two or more types of light-emitting substances are preferably contained. To obtain white light emission, two or more types of light-emitting substances are selected so as to emit light of complementary colors. For example, when emission colors of a first light-emitting layer and a second light-emitting layer are complementary colors, the light-emitting element can emit white light as a whole. The same applies to a light-emitting element including three or more light-emitting layers.

Note that also in FIG. 21C and FIG. 21D, the layer 780 and the layer 790 may each independently have a stacked-layer structure of two or more layers as shown in FIG. 21B.

In the case where light-emitting elements with the structure illustrated in FIG. 21E or FIG. 21F are used in subpixels emitting light of different colors, light-emitting substances may be different between the subpixels. Specifically, in the light-emitting element included in the subpixel emitting red light, a light-emitting substance that emits red light can be used for each of the light-emitting layer 771 and the light-emitting layer 772. In the light-emitting element included in the subpixel emitting green light, a light-emitting substance that emits green light can be used for each of the light-emitting layer 771 and the light-emitting layer 772. In the light-emitting element included in the subpixel emitting blue light, a light-emitting substance that emits blue light can be used for each of the light-emitting layer 771 and the light-emitting layer 772. A display apparatus with such a structure includes a light-emitting element with a tandem structure and can be regarded as an SBS structure. Thus, the display apparatus can have advantages of both of a tandem structure and an SBS structure. Accordingly, a highly reliable light-emitting element capable of high-luminance light emission can be provided.

Although FIG. 21E and FIG. 21F each illustrate an example in which the light-emitting unit 763a includes one light-emitting layer 771 and the light-emitting unit 763b includes one light-emitting layer 772, one embodiment of the present invention is not limited thereto. Each of the light-emitting unit 763a and the light-emitting unit 763b may include two or more light-emitting layers.

Although FIG. 21E and FIG. 21F each illustrate the light-emitting element including two light-emitting units, one embodiment of the present invention is not limited thereto. The light-emitting element may include three or more light-emitting units. Note that a structure including two light-emitting units and a structure including three light-emitting units may be referred to as a two-unit tandem structure and a three-unit tandem structure, respectively.

In FIG. 21E and FIG. 21F, the light-emitting unit 763a includes a layer 780a, the light-emitting layer 771, and a layer 790a, and the light-emitting unit 763b includes a layer 780b, the light-emitting layer 772, and a layer 790b.

In the case where the lower electrode 761 is an anode and the upper electrode 762 is a cathode, the layer 780a and the layer 780b each include one or more of a hole-injection layer, a hole-transport layer, and an electron-blocking layer. The layer 790a and the layer 790b each include one or more of an electron-injection layer, an electron-transport layer, and a hole-blocking layer. In the case where the lower electrode 761 is a cathode and the upper electrode 762 is an anode, the structures of the layer 780a and the layer 790a are replaced with each other, and the structures of the layer 780b and the layer 790b are also replaced with each other.

In the case where the lower electrode 761 is an anode and the upper electrode 762 is a cathode, for example, the layer 780a includes a hole-injection layer and a hole-transport layer over the hole-injection layer, and may further include an electron-blocking layer over the hole-transport layer. The layer 790a includes an electron-transport layer, and may further include a hole-blocking layer between the light-emitting layer 771 and the electron-transport layer. The layer 780b includes a hole-transport layer, and may further include an electron-blocking layer over the hole-transport layer. The layer 790b includes an electron-transport layer and an electron-injection layer over the electron-transport layer, and may further include a hole-blocking layer between the light-emitting layer 772 and the electron-transport layer. In the case where the lower electrode 761 is a cathode and the upper electrode 762 is an anode, for example, the layer 780a includes an electron-injection layer and an electron-transport layer over the electron-injection layer, and may further include a hole-blocking layer over the electron-transport layer. The layer 790a includes a hole-transport layer, and may further include an electron-blocking layer between the light-emitting layer 771 and the hole-transport layer. The layer 780b includes an electron-transport layer, and may further include a hole-blocking layer over the electron-transport layer. The layer 790b includes a hole-transport layer and a hole-injection layer over the hole-transport layer, and may further include an electron-blocking layer between the light-emitting layer 772 and the hole-transport layer.

In the case of forming a light-emitting element with the tandem structure, two light-emitting units are stacked with the charge-generation layer 785 therebetween. The charge-generation layer 785 includes at least a charge-generation region. The charge-generation layer 785 has a function of injecting electrons into one of the two light-emitting units and injecting holes into the other when voltage is applied between the pair of electrodes.

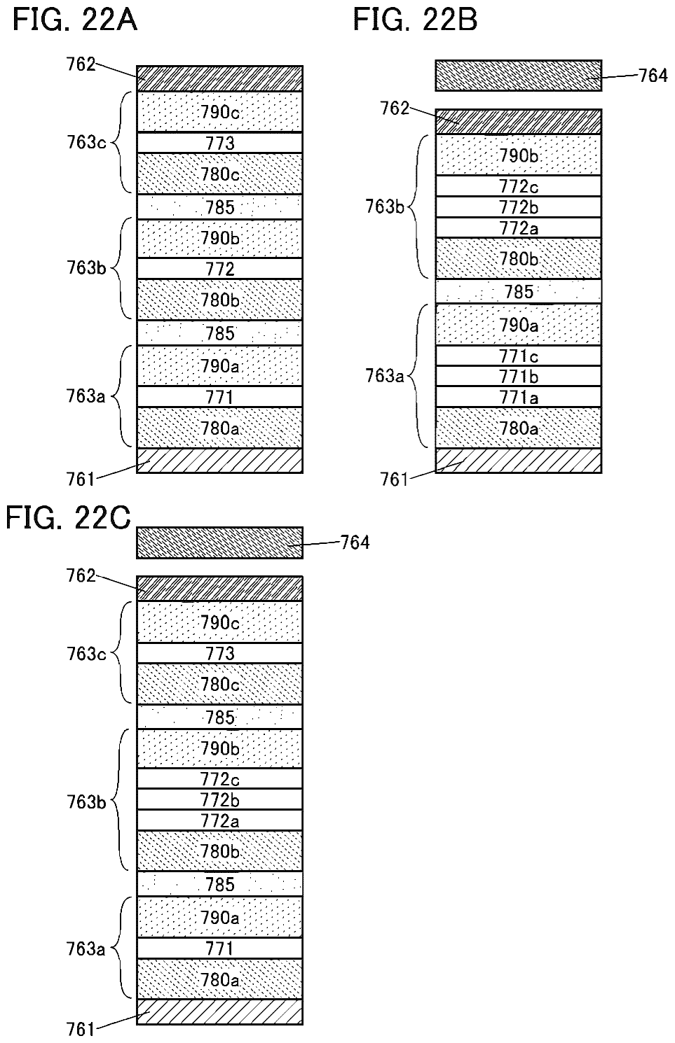

Structures illustrated in FIG. 22A to FIG. 22C are given as examples of a light-emitting element having a tandem structure.

FIG. 22A illustrates a structure including three light-emitting units. As illustrated in FIG. 22A, a plurality of light-emitting units (the light-emitting unit 763a, the light-emitting unit 763b, and a light-emitting unit 763c) are connected in series with the charge-generation layers 785 therebetween. The light-emitting unit 763a includes the layer 780a, the light-emitting layer 771, and the layer 790a. The light-emitting unit 763b includes the layer 780b, the light-emitting layer 772, and the layer 790b. The light-emitting unit 763c includes a layer 780c, the light-emitting layer 773, and a layer 790c. Note that the layer 780c can have a structure applicable to the layer 780a and the layer 780b, and the layer 790c can have a structure applicable to the layer 790a and the layer 790b.

In FIG. 22A, the light-emitting layer 771, the light-emitting layer 772, and the light-emitting layer 773 preferably contain light-emitting substances that emit light of the same color. Specifically, the light-emitting layer 771, the light-emitting layer 772, and the light-emitting layer 773 can each contain a light-emitting substance that emits red (R) light (what is called an R\R\R three-unit tandem structure); the light-emitting layer 771, the light-emitting layer 772, and the light-emitting layer 773 can each contain a light-emitting substance that emits green (G) light (what is called a G\G\G three-unit tandem structure); or the light-emitting layer 771, the light-emitting layer 772, and the light-emitting layer 773 can each contain a light-emitting substance that emits blue (B) light (what is called a B\B\B three-unit tandem structure). Note that “a\b” means that a light-emitting unit containing a light-emitting substance that emits light of b is provided over a light-emitting unit containing a light-emitting substance that emits light of a with a charge-generation layer therebetween, where a and b represent colors.

In FIG. 22A, light-emitting substances that emit light of different colors may be used for some or all of the light-emitting layer 771, the light-emitting layer 772, and the light-emitting layer 773. Examples of a combination of emission colors for the light-emitting layer 771, the light-emitting layer 772, and the light-emitting layer 773 include blue (B) for two of them and yellow (Y) for the other; and red (R) for one of them, green (G) for another, and blue (B) for the other.

Note that the structure containing the light-emitting substances that emit light of the same color is not limited to the above structure. For example, a light-emitting element with a tandem structure may be employed in which light-emitting units each including a plurality of light-emitting layers are stacked as illustrated in FIG. 22B. FIG. 22B illustrates a structure in which two light-emitting units (the light-emitting unit 763a and the light-emitting unit 763b) are connected in series with the charge-generation layer 785 therebetween. The light-emitting unit 763a includes the layer 780a, a light-emitting layer 771a, a light-emitting layer 771b, a light-emitting layer 771c, and the layer 790a. The light-emitting unit 763b includes the layer 780b, a light-emitting layer 772a, a light-emitting layer 772b, a light-emitting layer 772c, and the layer 790b.

In the structure illustrated in FIG. 22B, the light-emitting unit 763a is configured to emit white (W) light by selecting light-emitting substances so that the emission colors of the light-emitting layer 771a, the light-emitting layer 771b, and the light-emitting layer 771c are complementary colors. Furthermore, the light-emitting unit 763b is configured to emit white (W) light by selecting light-emitting substances for the light-emitting layer 772a, the light-emitting layer 772b, and the light-emitting layer 772c so that their emission colors are complementary colors. That is, the structure illustrated in FIG. 22B is a two-unit tandem structure of W\W. Note that there is no particular limitation on the stacking order of the light-emitting substances having complementary emission colors. The practitioner can select the optimal stacking order as appropriate. Although not illustrated, a three-unit tandem structure of W\W\W or a tandem structure with four or more units may be employed.

In the case of a light-emitting element with a tandem structure, examples of the structure include a two-unit tandem structure of B\Y or Y\B including a light-emitting unit that emits yellow (Y) light and a light-emitting unit that emits blue (B) light; a two-unit tandem structure of R·G\B or B\R·G including a light-emitting unit that emits red (R) and green (G) light and a light-emitting unit that emits blue (B) light; a three-unit tandem structure of B\Y\B including a light-emitting unit that emits blue (B) light, a light-emitting unit that emits yellow (Y) light, and a light-emitting unit that emits blue (B) light in this order; a three-unit tandem structure of B\YG\B including a light-emitting unit that emits blue (B) light, a light-emitting unit that emits yellow-green (YG) light, and a light-emitting unit that emits blue (B) light in this order; and a three-unit tandem structure of B\G\B including a light-emitting unit that emits blue (B) light, a light-emitting unit that emits green (G) light, and a light-emitting unit that emits blue (B) light in this order. Note that “a·b” means that one light-emitting unit contains a light-emitting substance that emits light of a and a light-emitting substance that emits light of b.

Alternatively, a light-emitting unit including one light-emitting layer and a light-emitting unit including a plurality of light-emitting layers may be used in combination as illustrated in FIG. 22C.

Specifically, in the structure illustrated in FIG. 22C, a plurality of light-emitting units (the light-emitting unit 763a, the light-emitting unit 763b, and the light-emitting unit 763c) are connected in series with the charge-generation layers 785 therebetween. The light-emitting unit 763a includes the layer 780a, the light-emitting layer 771, and the layer 790a. The light-emitting unit 763b includes the layer 780b, the light-emitting layer 772a, the light-emitting layer 772b, the light-emitting layer 772c, and the layer 790b. The light-emitting unit 763c includes the layer 780c, the light-emitting layer 773, and the layer 790c.

As the structure illustrated in FIG. 22C, for example, a three-unit tandem structure of B\R×G×YG\B in which the light-emitting unit 763a is a light-emitting unit that emits blue (B) light, the light-emitting unit 763b is a light-emitting unit that emits red (R), green (G), and yellow-green (YG) light, and the light-emitting unit 763c is a light-emitting unit that emits blue (B) light can be employed.

Examples of the number of stacked light-emitting units and the order of colors from the anode side include a two-unit structure of B and Y; a two-unit structure of B and a light-emitting unit X; a three-unit structure of B, Y, and B; and a three-unit structure of B, X, and B. Examples of the number of light-emitting layers stacked in the light-emitting unit X and the order of colors from the anode side include a two-layer structure of R and Y; a two-layer structure of R and G; a two-layer structure of G and R; a three-layer structure of G, R, and G; and a three-layer structure of R, G, and R. Another layer may be provided between two light-emitting layers.

Next, materials that can be used for the light-emitting element will be described.

A conductive film transmitting visible light is used as the electrode through which light is extracted, which is either the lower electrode 761 or the upper electrode 762. A conductive film reflecting visible light is preferably used as the electrode through which light is not extracted. In the case where a display apparatus includes a light-emitting element emitting infrared light, it is preferable that a conductive film transmitting visible light and infrared light be used as the electrode through which light is extracted and a conductive film reflecting visible light and infrared light be used as the electrode through which light is not extracted.

A conductive film transmitting visible light may be used as the electrode through which light is not extracted. In that case, the electrode is preferably placed between a reflective layer and the EL layer 763. In other words, light emitted from the EL layer 763 may be reflected by the reflective layer to be extracted from the display apparatus.

As a material that forms the pair of electrodes of the light-emitting element, a metal, an alloy, an electrically conductive compound, a mixture thereof, and the like can be used as appropriate. Specific examples of the material include metals such as aluminum, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing any of these metals in appropriate combination. Other examples of the material include indium tin oxide (also referred to as In—Sn oxide or ITO), In—Si—Sn oxide (also referred to as ITSO), indium zinc oxide (In—Zn oxide), and In—W—Zn oxide. Other examples of the material include an alloy containing aluminum (aluminum alloy) such as an alloy of aluminum, nickel, and lanthanum (Al—Ni-La) and an alloy of silver, palladium, and copper (also referred to as Ag—Pd—Cu or APC). Alternatively, as the material, an element belonging to Group 1 or Group 2 of the periodic table, which is not described above as an example (e.g., lithium, cesium, calcium, or strontium), a rare earth metal such as europium or ytterbium, an alloy containing an appropriate combination of any of these, graphene, or the like can be given.

In addition, the light-emitting element preferably also employs a microcavity structure. Thus, one of the pair of electrodes of the light-emitting element is preferably an electrode having properties of transmitting and reflecting visible light (a semi-transmissive and semi-reflective electrode), and the other is preferably an electrode having a property of reflecting visible light (a reflective electrode). When the light-emitting elements have a microcavity structure, light obtained from the light-emitting layers can be resonated between the electrodes, whereby light emitted from the light-emitting elements can be intensified.

Note that the transflective electrode can have a stacked-layer structure of a conductive layer that can be used as a reflective electrode and a conductive layer that can be used as an electrode having a property of transmitting visible light (also referred to as a transparent electrode).

The transparent electrode has a light transmittance higher than or equal to 40%. For example, an electrode having a visible light (light with wavelengths greater than or equal to 400 nm and less than 750 nm) transmittance higher than or equal to 40% is preferably used as the transparent electrode of the light-emitting element. The transflective electrode has a visible light reflectance higher than or equal to 10% and lower than or equal to 95%, preferably higher than or equal to 30% and lower than or equal to 80%. The reflective electrode has a visible light reflectance higher than or equal to 40% and lower than or equal to 100%, preferably higher than or equal to 70% and lower than or equal to 100%. These electrodes preferably have a resistivity less than or equal to 1×10⁻² Wcm.

The light-emitting element includes at least the light-emitting layer. The light-emitting element may further include, as a layer other than the light-emitting layer, a layer containing a substance with a high hole-injection property, a substance with a high hole-transport property, a hole-blocking material, a substance with a high electron-transport property, an electron-blocking material, a substance with a high electron-injection property, a substance with a bipolar property (a substance with a high electron-transport property and a high hole-transport property), or the like. For example, the light-emitting element can include one or more of a hole-injection layer, a hole-transport layer, a hole-blocking layer, a charge-generation layer, an electron-blocking layer, an electron-transport layer, and an electron-injection layer in addition to the light-emitting layer.

Either a low molecular compound or a high molecular compound can be used in the light-emitting element, and an inorganic compound may be included. Each of the layers included in the light-emitting element can be formed by an evaporation method (including a vacuum evaporation method), a transfer method, a printing method, an inkjet method, a coating method, or the like.

The light-emitting layer contains one or more kinds of light-emitting substances. As the light-emitting substance, a substance that exhibits an emission color of blue, violet, blue violet, green, yellow green, yellow, orange, red, or the like is appropriately used. Alternatively, as the light-emitting substance, a substance that emits near-infrared light can be used.

Examples of the light-emitting substance include a fluorescent material, a phosphorescent material, a TADF material, and a quantum dot material.

Examples of a fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of a phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton; an organometallic complex (particularly an iridium complex) having a phenylpyridine derivative including an electron-withdrawing group as a ligand; a platinum complex; and a rare earth metal complex.

The light-emitting layer may contain one or more kinds of organic compounds (e.g., a host material and an assist material) in addition to the light-emitting substance (a guest material). As one or more kinds of organic compounds, one or both of a substance with a high hole-transport property (a hole-transport material) and a substance with a high electron-transport property (an electron-transport material) can be used. As the hole-transport material, it is possible to use a material having a high hole-transport property which can be used for the hole-transport layer and will be described later. As the electron-transport material, it is possible to use a material having a high electron-transport property which can be used for the electron-transport layer and will be described later. Alternatively, as one or more kinds of organic compounds, a bipolar material or a TADF material may be used.

The light-emitting layer preferably contains a phosphorescent material and a combination of a hole-transport material and an electron-transport material that easily forms an exciplex, for example. Such a structure makes it possible to efficiently obtain light emission using ExTET (Exciplex-Triplet Energy Transfer), which is energy transfer from an exciplex to a light-emitting substance (a phosphorescent material). When a combination of materials is selected to form an exciplex that exhibits light emission whose wavelength overlaps with the wavelength of the lowest-energy-side absorption band of the light-emitting substance, energy can be transferred smoothly and light emission can be obtained efficiently. With this structure, high efficiency, low-voltage driving, and a long lifetime of the light-emitting element can be achieved at the same time. The hole-injection layer is a layer injecting holes from the anode to the hole-transport layer, and is a layer containing a material with a high hole-injection property. Examples of a material with a high hole-injection property include an aromatic amine compound and a composite material containing a hole-transport material and an acceptor material (electron-accepting material).

As the hole-transport material, it is possible to use a material having a high hole-transport property which can be used for the hole-transport layer and will be described later.

As the acceptor material, an oxide of a metal belonging to Group 4 to Group 8 of the periodic table can be used, for example. Specifically, molybdenum oxide, vanadium oxide, niobium oxide, tantalum oxide, chromium oxide, tungsten oxide, manganese oxide, and rhenium oxide are given. Among these, molybdenum oxide is particularly preferable since it is stable in the air, has a low hygroscopic property, and is easy to handle. An organic acceptor material containing fluorine can be used. Alternatively, an organic acceptor material such as a quinodimethane derivative, a chloranil derivative, or a hexaazatriphenylene derivative can be used.

As the material having a high hole-injection property, a material that contains a hole-transport material and the above-described oxide of a metal belonging to any of Group 4 to Group 8 of the periodic table (typically, molybdenum oxide) may be used, for example.

The hole-transport layer transports holes injected from the anode by the hole-injection layer, to the light-emitting layer. The hole-transport layer is a layer containing a hole-transport material. As the hole-transport material, a substance having a hole mobility higher than or equal to 1×10⁻⁶ cm²/Vs is preferable. Note that other substances can also be used as long as the substances have a hole-transport property higher than an electron-transport property. As the hole-transport material, a material with a high hole-transport property such as a π-electron rich heteroaromatic compound (e.g., a carbazole derivative, a thiophene derivative, or a furan derivative) or an aromatic amine (a compound having an aromatic amine skeleton) is preferable.

The electron-blocking layer is provided in contact with the light-emitting layer. The electron-blocking layer has a hole-transport property and contains a material capable of blocking electrons. Any of the materials having an electron-blocking property among the above hole-transport materials can be used for the electron-blocking layer.

The electron-blocking layer has a hole-transport property, and thus can also be referred to as a hole-transport layer. A layer having an electron-blocking property among the hole-transport layers can also be referred to as an electron-blocking layer.

The electron-transport layer is a layer transporting electrons injected from the cathode by the electron-injection layer, to the light-emitting layer. The electron-transport layer is a layer containing an electron-transport material. As the electron-transport material, a substance having an electron mobility higher than or equal to 1×10⁻⁶ cm²/Vs is preferable. Note that other substances can also be used as long as the substances have an electron-transport property higher than a hole-transport property. As the electron-transport material, it is possible to use a material with a high electron-transport property, such as a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, or a π-electron deficient heteroaromatic compound including a nitrogen-containing heteroaromatic compound.

The hole-blocking layer is provided in contact with the light-emitting layer. The hole-blocking layer is a layer having an electron-transport property and containing a material that can block holes. Any of the materials having a hole-blocking property among the above electron-transport materials can be used for the hole-blocking layer.

The hole-blocking layer has an electron-transport property, and thus can also be referred to as an electron-transport layer. A layer having a hole-blocking property among the electron-transport layers can also be referred to as a hole-blocking layer.

The electron-injection layer is a layer injecting electrons from the cathode to the electron-transport layer, and is a layer containing a material with a high electron-injection property. As the material with a high electron-injection property, an alkali metal, an alkaline earth metal, or a compound thereof can be used. As the material with a high electron-injection property, a composite material containing an electron-transport material and a donor material (electron-donating material) can also be used.

The difference between the lowest unoccupied molecular orbital (LUMO) level of the material with a high electron-injection property and the work function value of the material used for the cathode is preferably small (specifically, smaller than or equal to 0.5 eV).

The electron-injection layer can be formed using, for example, an alkali metal, an alkaline earth metal, or a compound thereof, such as lithium, cesium, ytterbium, lithium fluoride (LiF), cesium fluoride (CsF), calcium fluoride (CaFₓ, where X is a given number), 8-(quinolinolato) lithium (abbreviation: Liq), 2-(2-pyridyl) phenolatolithium (abbreviation: LiPP), 2-(2-pyridyl)-3-pyridinolatolithium (abbreviation: LiPPy), 4-phenyl-2-(2-pyridyl) phenolatolithium (abbreviation: LiPPP), lithium oxide (LiOₓ), or cesium carbonate. The electron-injection layer may have a stacked-layer structure of two or more layers. The stacked-layer structure can be, for example, a structure in which lithium fluoride is used for the first layer and ytterbium is used for the second layer.

The electron-injection layer may contain an electron-transport material. For example, a compound having an unshared electron pair and an electron deficient heteroaromatic ring can be used as the electron-transport material. Specifically, it is possible to use a compound having at least one of a pyridine ring, a diazine ring (a pyrimidine ring, a pyrazine ring, and a pyridazine ring), and a triazine ring.

Note that the LUMO level of the organic compound having an unshared electron pair is preferably higher than or equal to −3.6 eV and lower than or equal to −2.3 eV. In general, the highest occupied molecular orbital (HOMO) level and the LUMO level of an organic compound can be estimated by CV (cyclic voltammetry), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), 2,2-(1,3-phenylene)bis[9-phenyl-1,10-phenanthroline] (abbreviation: mPPhen2P), diquinoxalino[2,3-a:2′,3′-c]phenazine (abbreviation: HATNA), 2,4,6-tris[3′-(pyridin-3-yl) biphenyl-3-yl]-1,3,5-triazine (abbreviation: TmPPPyTz), or the like can be used as the organic compound having an unshared electron pair. Note that NBPhen has a higher glass transition temperature (Tg) than BPhen and thus has high heat resistance.

As described above, the charge-generation layer includes at least a charge-generation region. The charge-generation region preferably contains an acceptor material, and for example, preferably contains a hole-transport material and an acceptor material which can be used for the hole-injection layer.

The charge-generation layer preferably includes a layer containing a material having a high electron-injection property. The layer can also be referred to as an electron-injection buffer layer. The electron-injection buffer layer is preferably provided between the charge-generation region and the electron-transport layer. By provision of the electron-injection buffer layer, an injection barrier between the charge-generation region and the electron-transport layer can be lowered; thus, electrons generated in the charge-generation region can be easily injected into the electron-transport layer.

The electron-injection buffer layer preferably contains an alkali metal or an alkaline earth metal, and for example, can contain an alkali metal compound or an alkaline earth metal compound. Specifically, the electron-injection buffer layer preferably contains an inorganic compound containing an alkali metal and oxygen or an inorganic compound containing an alkaline earth metal and oxygen, further preferably contains an inorganic compound containing lithium and oxygen (lithium oxide (Li₂O) or the like). Alternatively, a material that can be used for the electron-injection layer can be suitably used for the electron-injection buffer layer.

The charge-generation layer preferably includes a layer containing a material having a high electron-transport property. The layer can also be referred to as an electron-relay layer. The electron-relay layer is preferably provided between the charge-generation region and the electron-injection buffer layer. In the case where the charge-generation layer does not include an electron-injection buffer layer, the electron-relay layer is preferably provided between the charge-generation region and the electron-transport layer. The electron-relay layer has a function of preventing interaction between the charge-generation region and the electron-injection buffer layer (or the electron-transport layer) and smoothly transferring electrons.

A phthalocyanine-based material such as copper (II) phthalocyanine (abbreviation: CuPc) or a metal complex having a metal-oxygen bond and an aromatic ligand is preferably used for the electron-relay layer.

Note that the charge-generation region, the electron-injection buffer layer, and the electron-relay layer cannot be clearly distinguished from each other in some cases on the basis of the cross-sectional shapes, the characteristics, or the like.

Note that the charge-generation layer may contain a donor material instead of an acceptor material. For example, the charge-generation layer may include a layer containing an electron-transport material and a donor material, which can be used for the electron-injection layer.

When the light-emitting units are stacked, provision of a charge-generation layer between two light-emitting units can inhibit an increase in driving voltage.

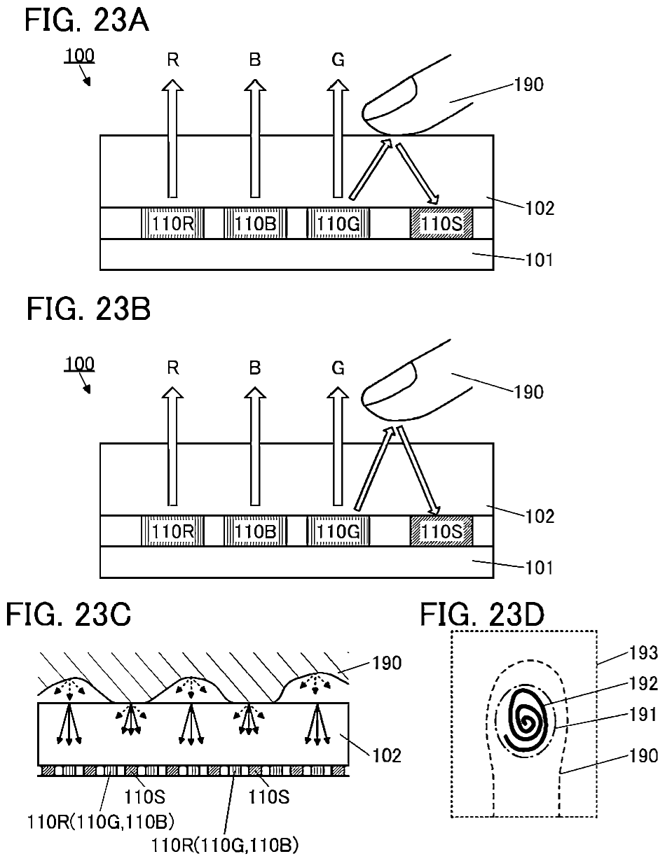

Next, functions of a display apparatus 100 including the light-emitting element 110R, the light-emitting element 110G, the light-emitting element 110B, and the light-receiving element 110S are described with reference to the schematic diagram illustrated in FIG. 23A. Here, light emission from the light-emitting element 110R is red (R), light emission from the light-emitting element 110G is green (G), and light emission from the light-emitting element 110B is blue (B). Each of the light-emitting element 110R, the light-emitting element 110G, and the light-emitting element 110B can correspond to any of the light-emitting element 110a, the light-emitting element 110b, and the light-emitting element 110c illustrated in FIG. 19A and the like.

FIG. 23A illustrates a finger 190 touching a surface of a substrate 102. For the substrate 102, the substrate 170 or the like described in Embodiment 2 can be referred to. Part of light emitted by the light-emitting element 110 (e.g., light emitted by the light-emitting element 110G) is reflected by the contact portion between the substrate 102 and the finger 190. Then, part of the reflected light is incident on the light-receiving element 110S, so that the contact of the finger 190 with the substrate 102 can be sensed. In this manner, the display apparatus 100 can detect a fingerprint of the finger 190 and perform personal authentication.

FIG. 23C schematically illustrates an enlarged view of the contact portion in a state where the finger 190 touches the substrate 102. FIG. 23C also illustrates the light-emitting elements 110 and the light-receiving elements 110S that are alternately arranged.

The fingerprint of the finger 190 is formed of depressed portions and projecting portions. Accordingly, as illustrated in FIG. 23C, the projecting portions of the fingerprint touch the substrate 102.

Reflection of light from a surface, an interface, or the like is categorized into regular reflection and diffuse reflection. Regularly reflected light is highly directional light with an angle of reflection equal to the angle of incidence. Diffusely reflected light has low directionality and low angular dependence of intensity. As for regular reflection and diffuse reflection, diffuse reflection components are dominant in the light reflected from the surface of the finger 190. Meanwhile, regular reflection components are dominant in the light reflected from the interface between the substrate 102 and the air.

The intensity of light that is reflected by contact surfaces or non-contact surfaces between the finger 190 and the substrate 102 and is incident on the light-receiving elements 110S positioned directly below the contact surfaces or the non-contact surfaces is the sum of intensities of regularly reflected light and diffusely reflected light. As described above, regularly reflected light (indicated by solid arrows) is dominant in the depressed portions of the finger 190, where the finger 190 is not in contact with the substrate 102; whereas diffusely reflected light (indicated by dashed arrows) from the finger 190 is dominant in the projecting portions of the finger 190, where the finger 190 is in contact with the substrate 102. Thus, the intensity of light received by the light-receiving element 110S positioned directly below the depressed portion is higher than the intensity of light received by the light-receiving element 110S positioned directly below the projecting portion. Accordingly, a fingerprint image of the finger 190 can be captured.

In the case where an arrangement interval between the light-receiving elements 110S is smaller than a distance between two projecting portions of a fingerprint, preferably a distance between a depressed portion and a projecting portion adjacent to each other, a clear fingerprint image can be obtained. The interval between a depressed portion and a projecting portion of a human's fingerprint is approximately 200 μm; thus, the arrangement interval between the light-receiving elements 110S is, for example, less than or equal to 400 μm, preferably less than or equal to 200 μm, further preferably less than or equal to 150 μm, still further preferably less than or equal to 100 μm, even still further preferably less than or equal to 50 μm and greater than or equal to 1 μm, preferably greater than or equal to 10 μm, further preferably greater than or equal to 20 μm.

FIG. 23D illustrates an example of a fingerprint image captured by the display apparatus 100. In an image capturing range 193 in FIG. 23D, the outline of the finger 190 is indicated by a dashed line and the outline of a contact portion 191 is indicated by a dashed-dotted line. In the contact portion 191, a high-contrast image of a fingerprint 192 can be captured owing to a difference in the amount of light incident on the light-receiving elements 110S.

Although FIG. 23A illustrates the example in which the finger 190 is in contact with the substrate 102, the finger 190 is not necessarily in contact with the substrate 102. For example, as illustrated in FIG. 23B, sensing can be performed while the finger 190 is at a distance from the substrate 102, in some cases. In a preferred mode, the distance between the finger 190 and the substrate 102 is relatively short, and the mode is referred to as near touch or hover touch in some cases.

In this specification and the like, near touch or hover touch means that a target (the finger 190) can be detected while the target (the finger 190) is not in contact with the display apparatus, for example. For example, the display apparatus is preferably capable of detecting the target (the finger 190) when the distance between the display apparatus and the target (the finger 190) is within the range greater than or equal to 0.1 mm and less than or equal to 300 mm, further preferably greater than or equal to 3 mm and less than or equal to 50 mm. This structure enables the display apparatus to be operated without direct contact of the target (the finger 190), that is, enables the display apparatus to be operated in a contactless (touchless) manner. This structure can reduce the risk of the display apparatus being dirty or damaged or enables the target (the finger 190) to operate the display apparatus without directly touching a dirt (e.g., dust or a virus) attached to the display apparatus.

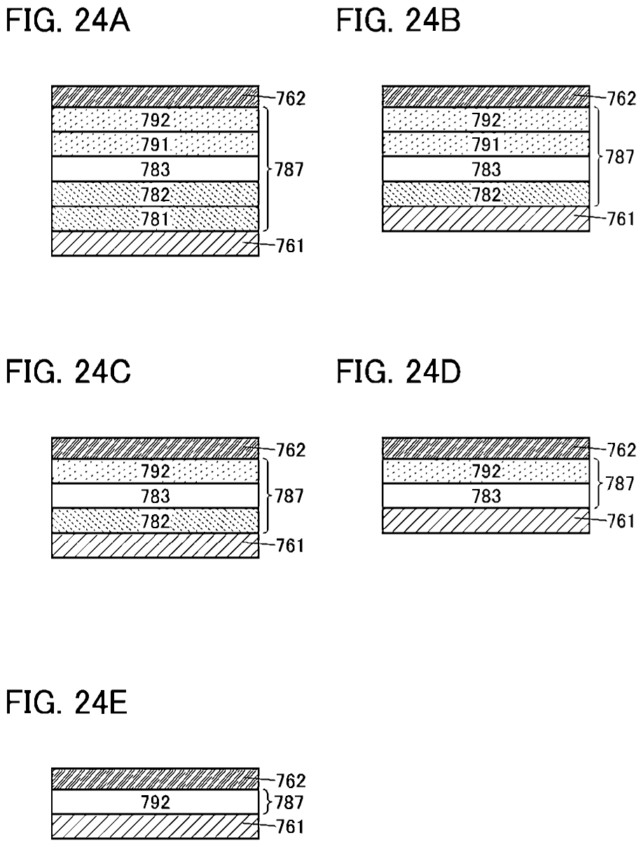

FIG. 24A to FIG. 24E illustrate structure examples of a light-receiving element that can be used in a display apparatus. In the components illustrated in FIG. 24A to FIG. 24E, components similar to the components in FIG. 21 are denoted by the same reference numerals.

The light-receiving element illustrated in FIG. 24A includes a PS layer 787 between a pair of electrodes (the lower electrode 761 and the upper electrode 762). The lower electrode 761 functions as a pixel electrode and is provided in each light-receiving element. The electrode 762 functions as a common electrode and is shared by a plurality of light-emitting elements and the light-receiving element.

The PS layer 787 illustrated in FIG. 24A can be formed as an island-shaped layer. In other words, the PS layer 787 illustrated in FIG. 24A corresponds to the PS layer 155S in FIG. 2B and the like. Note that the light-receiving element corresponds to the light-receiving element 110S. Furthermore, the lower electrode 761 corresponds to the pixel electrode 111S. The upper electrode 762 corresponds to the common electrode 113.

The PS layer 787 includes the layer 781, the layer 782, a photoelectric conversion layer 783, the layer 791, the layer 792, and the like. The layer 781, the layer 782, the layer 791, the layer 792 and the like are similar to those used for the light-emitting element. Here, the layer 792 and the upper electrode 762 can be provided in common for the light-emitting element and the light-receiving element.

The photoelectric conversion layer 783 includes a semiconductor. Examples of the semiconductor include an inorganic semiconductor such as silicon and an organic semiconductor including an organic compound. This embodiment shows an example in which an organic semiconductor is used as the semiconductor included in the photoconversion layer 783. The use of an organic semiconductor is preferable because the light-emitting layer and the photoconversion layer 783 can be formed by the same method (e.g., a vacuum evaporation method) and thus a manufacturing apparatus can be shared.

As the photoelectric conversion layer 783, a pn photodiode or a pin photodiode can be used, for example. An n-type semiconductor material and a p-type semiconductor material that can be used as the photoelectric conversion layer 783 are described below. The n-type semiconductor material and the p-type semiconductor material may be formed as layers to be stacked or may be mixed to form one layer.

Examples of an n-type semiconductor material included in the photoelectric conversion layer 783 include electron-accepting organic semiconductor materials such as fullerene (e.g., C₆₀ and C₇₀) and fullerene derivatives. Fullerene has a soccer ball-like shape, which is energetically stable. Both the HOMO level and the LUMO level of fullerene are deep (low). Having a deep LUMO level, fullerene has an extremely high electron-accepting property (acceptor property). When π-electron conjugation (resonance) spreads on a plane as in benzene, an electron-donating property (donor property) usually increases; however, fullerene has a spherical shape, and thus has a high electron-accepting property although π-electron conjugation widely spread therein. The high electron-accepting property efficiently causes rapid charge separation and thus is useful for light-receiving elements. Both C₆₀ and C₇₀ have a wide absorption band in the visible light region, and C₇₀ is especially preferable because of having a larger π-electron conjugation system and a wider absorption band in the long wavelength region than C₆₀. Other examples of fullerene derivatives include [6,6]-phenyl-C₇₁-butyric acid methyl ester (abbreviation: PC70BM), [6,6]-phenyl-C₆₁-butyric acid methyl ester (abbreviation: PC60BM), and 1′,1″,4′,4″-tetrahydro-di[1,4]methanonaphthaleno[1,2:2′,3′,56,60:2″,3″][5,6]fullerene-C₆₀ (abbreviation: ICBA).

Another example of an n-type semiconductor material is a perylenetetracarboxylic derivative such as N,N′-dimethyl-3,4,9,10-perylenetetracarboxylic diimide (abbreviation: Me-PTCDI).

Another example of an n-type semiconductor material is 2,2′-(5,5′-(thieno[3,2-b]thiophene-2,5-diyl)bis(thiophene-5,2-diyl))bis(methan-1-yl-1-ylidene)dimalononitrile (abbreviation: FT2TDMN).

Other examples of an n-type semiconductor material include a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative, a benzoquinoline derivative, a quinoxaline derivative, a dibenzoquinoxaline derivative, a pyridine derivative, a bipyridine derivative, a pyrimidine derivative, a naphthalene derivative, an anthracene derivative, a coumarin derivative, a rhodamine derivative, a triazine derivative, and a quinone derivative.

Examples of a p-type semiconductor material contained in the photoelectric conversion layer 783 include electron-donating organic semiconductor materials such as copper (II) phthalocyanine (CuPc), tetraphenyldibenzoperiflanthene (DBP), zinc phthalocyanine (ZnPc), tin phthalocyanine (SnPc), quinacridone, and rubrene.

Other examples of a p-type semiconductor material include a carbazole derivative, a thiophene derivative, a furan derivative, and a compound having an aromatic amine skeleton. Other examples of a p-type semiconductor material include a naphthalene derivative, an anthracene derivative, a pyrene derivative, a triphenylene derivative, a fluorene derivative, a pyrrole derivative, a benzofuran derivative, a benzothiophene derivative, an indole derivative, a dibenzofuran derivative, a dibenzothiophene derivative, an indolocarbazole derivative, a porphyrin derivative, a phthalocyanine derivative, a naphthalocyanine derivative, a quinacridone derivative, a rubrene derivative, a tetracene derivative, a polyphenylene vinylene derivative, a polyparaphenylene derivative, a polyfluorene derivative, a polyvinylcarbazole derivative, and a polythiophene derivative.

The HOMO level of the electron-donating organic semiconductor material is preferably shallower (higher) than the HOMO level of the electron-accepting organic semiconductor material. The LUMO level of the electron-donating organic semiconductor material is preferably shallower (higher) than the LUMO level of the electron-accepting organic semiconductor material.

Fullerene having a spherical shape is preferably used as the electron-accepting organic semiconductor material, and an organic semiconductor material having a substantially planar shape is preferably used as the electron-donating organic semiconductor material. Molecules of similar shapes tend to aggregate, and aggregated molecules of similar kinds, which have molecular orbital energy levels close to each other, can increase the carrier-transport property.

For example, the photoelectric conversion layer 783 is preferably formed by co-evaporation of an n-type semiconductor and a p-type semiconductor. Alternatively, the photoelectric conversion layer 783 may be formed by stacking an n-type semiconductor and a p-type semiconductor.

Either a low molecular compound or a high molecular compound can be used for the light-emitting element and the light-receiving element, and an inorganic compound may also be contained. Each of the layers included in the light-emitting element and the light-receiving element can be formed by an evaporation method (including a vacuum evaporation method), a transfer method, a printing method, an inkjet method, a coating method, or the like.

As the hole-transport material or the electron-blocking material, a high molecular compound such as poly(3,4-ethylenedioxythiophene)/poly(styrenesulfonic acid) (PEDOT/PSS), or an inorganic compound such as molybdenum oxide or copper iodide (CuI) can be used, for example. As the electron-transport material or the hole-blocking material, an inorganic compound such as zinc oxide (ZnO), or an organic compound such as polyethylenimine ethoxylate (PEIE) can be used. The light-receiving element may include a mixed film of PEIE and ZnO, for example.

For the photoelectric conversion layer 783, a high molecular compound such as poly[[4,8-bis[5-(2-ethylhexyl)-2-thienyl]benzo[1,2-b: 4,5-b′]dithiophene-2,6-diyl]-2,5-thiophenediyl[5,7-bis(2-ethylhexyl)-4,8-dioxo-4H,8H-benzo[1,2-c:4,5-c′]dithiophene-1,3-diyl]] polymer (abbreviation: PBDB-T) or a PBDB-T derivative, which functions as a donor, can be used. For example, a method in which an acceptor material is dispersed to PBDB-T or a PBDB-T derivative can be used.

The photoelectric conversion layer 783 may contain a mixture of three or more types of materials. For example, a third material may be mixed with an n-type semiconductor material and a p-type semiconductor material in order to extend the wavelength range. The third material may be a low molecular compound or a high molecular compound.

As illustrated in FIG. 24A, the layer 781 (hole-injection layer), the layer 782 (hole-transport layer), the photoelectric conversion layer 783, the layer 791 (electron-transport layer), and the layer 792 (electron-injection layer) can be stacked in this order in the PS layer 787. This stacking order is the same as the stacking order of the EL layer 763 illustrated in FIG. 21B. In this case, the lower electrode 761 can function as an anode and the upper electrode 762 can function as a cathode in any of the light-emitting elements and the light-receiving element. In other words, the light-receiving element is driven by application of reverse bias between the lower electrode 761 and the upper electrode 762, whereby light incident on the light-receiving element can be detected and electric charges can be generated and extracted as current.

However, the present invention is not limited thereto. For example, the layer 781 may include an electron-injection layer, the layer 782 may include an electron-transport layer, the layer 791 may include a hole-transport layer, and the layer 792 may include a hole-injection layer. In that case, in the light-receiving element, the lower electrode 761 functions as a cathode and the upper electrode 762 can function as an anode. As described in the above embodiment, the light-emitting element and the light-receiving element can be separately formed in the present invention. Therefore, even when the structure of the light-emitting element is greatly different from the structure of the light-receiving element, the light-emitting element and the light-receiving element can be formed relatively easily.

It is not always necessary to provide all of the layer 781, the layer 782, the layer 791, and the layer 792 illustrated in FIG. 24A. For example, the layer 782 including a hole-injection layer may be in contact with the lower electrode 761 as illustrated in FIG. 24B without providing the layer 781 including a hole-injection layer. Note that as illustrated in FIG. 24A and FIG. 24B, at least one of the layer 782 including a hole-transport layer and the layer 791 including an electron-transport layer is preferably provided in contact with the photoelectric conversion layer 783. Thus, in the light-receiving element, a reduction in the sensitivity of imaging due to generation of leakage current between the lower electrode 761 and the upper electrode 762 can be inhibited.

Furthermore, either one of the layers 782 and 791 may be omitted. For example, the photoelectric conversion layer 783 may be in contact with the layer 792 without providing the layer 791 including an electron-transport layer as illustrated in FIG. 24C.

Moreover, the PS layer 787 can include only the photoelectric conversion layer 783. For example, the photoelectric conversion layer 783 may be in contact with the lower electrode 761, without formation of the layer 782 including a hole-transport layer as illustrated in FIG. 24D.

In addition, in the case where the layer 792 is provided for each light-emitting element without being formed as a common layer, the layer 792 in the light-receiving element can be omitted. For example, the photoelectric conversion layer 783 may be in contact with the upper electrode 762, without formation of the layer 792 including an electron-injection layer as illustrated in FIG. 24E.

This embodiment can be combined with the other embodiments as appropriate.

### Embodiment 4

In this embodiment, electronic devices of one embodiment of the present invention will be described.

Electronic devices of this embodiment are each provided with the display apparatus of one embodiment of the present invention in a display portion. The display apparatus of one embodiment of the present invention can be easily increased in resolution and definition. Thus, the display apparatus of one embodiment of the present invention can be used for display portions of a variety of electronic devices.

Examples of electronic devices include a digital camera, a digital video camera, a digital photo frame, a mobile phone, a portable game console, a portable information terminal, and an audio reproducing device in addition to electronic devices with a relatively large screen, such as a television device, a desktop or laptop personal computer, a monitor of a computer or the like, digital signage, and a large game machine like a pachinko machine.

In particular, the display apparatus of one embodiment of the present invention can have a high resolution, and thus can be suitably used for an electronic device having a relatively small display portion. Examples of such an electronic device include watch-type and bracelet-type information terminal devices (wearable devices) and wearable devices worn on the head, such as a VR device like a head-mounted display, a glasses-type AR device, and an MR device.

The definition of the display apparatus of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, the definition is preferably 4K, 8K, or higher. In particular, the definition is preferably 4K, 8K, or higher. Furthermore, the pixel density (resolution) of the display apparatus of one embodiment of the present invention is preferably higher than or equal to 100 ppi, preferably higher than or equal to 300 ppi, further preferably higher than or equal to 500 ppi, still further preferably higher than or equal to 1000 ppi, still further preferably higher than or equal to 2000 ppi, still further preferably higher than or equal to 3000 ppi, still further preferably higher than or equal to 5000 ppi, yet further preferably higher than or equal to 7000 ppi. With the use of such a display apparatus having one or both of high definition and high resolution, the electronic device can provide higher realistic sensation, sense of depth, and the like in personal use such as portable use and home use. There is no particular limitation on the screen ratio (aspect ratio) of the display apparatus of one embodiment of the present invention. For example, the display apparatus is compatible with a variety of screen ratios such as 1:1 (a square), 4:3, 16:9, and 16:10.

The electronic device in this embodiment may include a sensor (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device in this embodiment can have a variety of functions. For example, the electronic device can have a function of displaying a variety of data (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

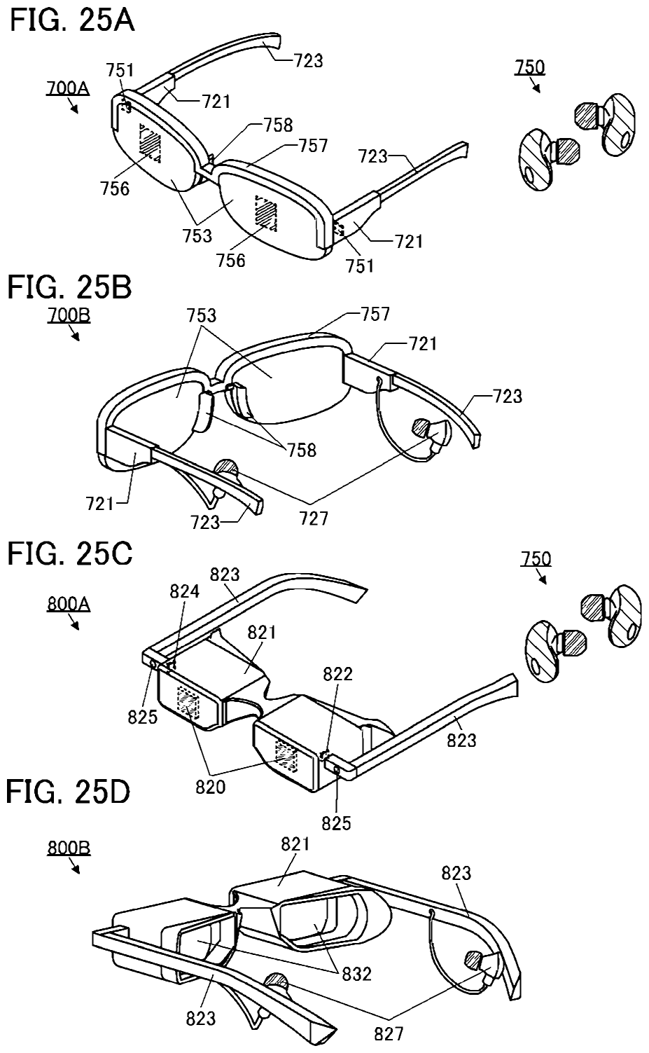

Examples of head-mounted wearable devices are described with reference to FIG. 25A to FIG. 25D. These wearable devices have at least one of a function of displaying AR contents, a function of displaying VR contents, a function of displaying SR contents, and a function of displaying MR contents. The electronic device having a function of displaying a content of at least one of AR, VR, SR, MR, and the like enables the user to reach a higher level of immersion. An electronic device 700A illustrated in FIG. 25A and an electronic device 700B illustrated in FIG. 25B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display apparatus of one embodiment of the present invention can be used for the display panel 751. Thus, the electronic device with extremely high resolution can be obtained.

The electronic device 700A and the electronic device 700B can each project an image displayed on the display panel 751 onto display regions 756 of the optical members 753. Since the optical members 753 have a light-transmitting property, a user can see images displayed on the display regions, which are superimposed on transmission images seen through the optical members 753. Accordingly, the electronic device 700A and the electronic device 700B are electronic devices capable of AR display.

In the electronic device 700A and the electronic device 700B, a camera capable of capturing images of the front side may be provided as the image capturing portion. Furthermore, when the electronic device 700A and the electronic device 700B are provided with an acceleration sensor such as a gyroscope sensor, the orientation of the user's head can be sensed and an image corresponding to the orientation can be displayed on the display region 756.

The communication portion includes a wireless communication device, and a picture signal, for example, can be supplied by the wireless communication device. Note that instead of the wireless communication device or in addition to the wireless communication device, a connector to which a cable for supplying a video signal and a power supply potential can be connected may be provided.

The electronic device 700A and the electronic device 700B are provided with a battery so that they can be charged wirelessly and/or by wire.

A touch sensor module may be provided in the housing 721. The touch sensor module has a function of detecting a touch on the outer surface of the housing 721. A tap operation or a slide operation, for example, by the user can be detected with the touch sensor module, whereby a variety of processing can be executed. For example, processing such as a pause or a restart of a moving image can be executed by a tap operation, and processing such as fast forward and fast rewind can be executed by a slide operation. The touch sensor module is provided in each of the two housings 721, whereby the range of the operation can be increased.

A variety of touch sensors can be applied to the touch sensor module. Any of touch sensors of various types such as a capacitive type, a resistive type, an infrared type, an electromagnetic induction type, a surface acoustic wave type, and an optical type can be employed. In particular, a capacitive sensor or an optical sensor is preferably used for the touch sensor module.

In the case of using an optical touch sensor, a photoelectric conversion element (also referred to as a photoelectric conversion device) can be used as a light-receiving element. One or both of an inorganic semiconductor and an organic semiconductor can be used for an active layer of the photoelectric conversion element.

An electronic device 800A illustrated in FIG. 25C and an electronic device 800B illustrated in FIG. 25D each include a pair of display portions 820, a housing 821, a communication portion 822, a pair of wearing portions 823, a control portion 824, a pair of image capturing portions 825, and a pair of lenses 832.

The display apparatus of one embodiment of the present invention can be used in the display portions 820. Thus, the electronic device with extremely high resolution can be obtained.

The display portions 820 are positioned inside the housing 821 so as to be seen through the lenses 832. When the pair of display portions 820 display different images, three-dimensional display using parallax can be performed.

The electronic device 800A and the electronic device 800B can be regarded as electronic devices for VR. The user who wears the electronic device 800A or the electronic device 800B can see images displayed on the display portions 820 through the lenses 832.

The electronic device 800A and the electronic device 800B preferably include a mechanism for adjusting the lateral positions of the lenses 832 and the display portions 820 so that the lenses 832 and the display portions 820 are positioned optimally in accordance with the positions of the user's eyes. Moreover, the electronic device 800A and the electronic device 800B preferably include a mechanism for adjusting focus by changing the distance between the lenses 832 and the display portions 820.

The electronic device 800A or the electronic device 800B can be mounted on the user's head with the wearing portions 823. FIG. 25C illustrate an example where the mounting portion 823 has a shape like a temple of glasses; however, one embodiment of the present invention is not limited thereto. The wearing portion 823 can have any shape with which the user can wear the electronic device, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to support a plurality of fields of view, such as a telescope field of view and a wide field of view.

Although an example of including the image capturing portion 825 is described here, a range sensor (also referred to as a sensing portion) that is capable of measuring a distance from an object may be provided. That is, the image capturing portion 825 is one embodiment of the sensing portion. As the sensing portion, an image sensor or a distance image sensor such as LIDAR (Light Detection and Ranging) can be used, for example. With the use of images obtained by the camera and images obtained by the distance image sensor, more pieces of information can be obtained and a gesture operation with higher accuracy is possible.

The electronic device 800A may include a vibration mechanism that functions as bone-conduction earphones. For example, a structure including the vibration mechanism can be applied to any one or more of the display portion 820, the housing 821, and the wearing portion 823. Thus, without additionally requiring an audio device such as headphones, earphones, or a speaker, the user can enjoy video and sound only by wearing the electronic device 800A.

The electronic device 800A and the electronic device 800B may each include an input terminal. To the input terminal, a cable for supplying a video signal from a video output device or the like, electric power for charging a battery provided in the electronic device, and the like can be connected.

The electronic device of one embodiment of the present invention may have a function of performing wireless communication with earphones 750. The earphones 750 include a communication portion (not illustrated) and have a wireless communication function. The earphones 750 can receive information (e.g., audio data) from the electronic device with the wireless communication function. For example, the electronic device 700A illustrated in FIG. 25A has a function of transmitting information to the earphones 750 with the wireless communication function. As another example, the electronic device 800A illustrated in FIG. 25C has a function of transmitting information to the earphones 750 with the wireless communication function.

The electronic device may include an earphone portion. The electronic device 700B illustrated in FIG. 25B includes earphone portions 727. For example, a structure in which the earphone portions 727 and the control portion are connected to each other by wire may be employed. Part of a wiring that connects the earphone portions 727 and the control portion may be positioned inside the housing 721 or the wearing portion 723.

Similarly, the electronic device 800B illustrated in FIG. 25D includes earphone portions 827. For example, a structure in which the earphone portions 827 and the control portion 824 are connected to each other by wire may be employed. Part of a wiring that connects the earphone portions 827 and the control portion 824 may be positioned inside the housing 821 or the wearing portion 823. The earphone portions 827 and the wearing portion 823 may include magnets. This is preferable because the earphone portions 827 can be fixed to the wearing portion 823 with magnetic force and thus can be easily housed.

Note that the electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of a headset by including the audio input mechanism.

As described above, both the glasses-type device (e.g., the electronic device 700A and the electronic device 700B) and the goggles-type device (e.g., the electronic device 800A and the electronic device 800B) are preferable as the electronic device of one embodiment of the present invention.

The electronic device of one embodiment of the present invention can transmit information to earphones by wire or wirelessly.

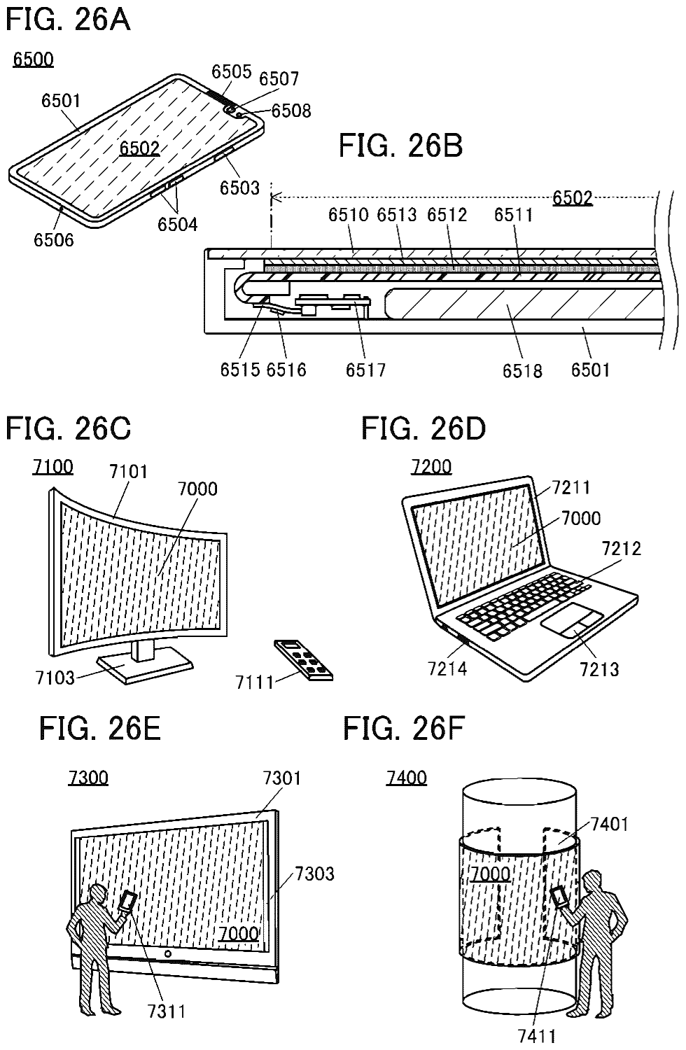

An electronic device 6500 illustrated in FIG. 26A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display apparatus of one embodiment of the present invention can be used in the display portion 6502. Thus, the electronic device with extremely high resolution can be obtained.

FIG. 26B is a schematic cross-sectional view including an end portion of the housing 6501 on the microphone 6506 side.

A protection member 6510 having a light-transmitting property is provided on a display surface side of the housing 6501, and a display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the region that is folded back. An IC 6516 is mounted on the FPC 6515. The FPC 6515 is connected to a terminal provided on the printed circuit board 6517.

A flexible display of one embodiment of the present invention can be used as the display panel 6511. Thus, an extremely lightweight electronic device can be achieved. Since the display panel 6511 is extremely thin, the battery 6518 with high capacity can be mounted while the thickness of the electronic device is reduced. Moreover, part of the display panel 6511 is folded back so that a connection portion with the FPC 6515 is provided on the back side of the pixel portion, whereby an electronic device with a narrow bezel can be achieved.

FIG. 26C illustrates an example of a television device. In a television device 7100, a display portion 7000 is incorporated in a housing 7101. Here, the housing 7101 is supported by a stand 7103.

The display apparatus of one embodiment of the present invention can be used in the display portion 7000. Thus, the electronic device with extremely high resolution can be obtained.

Operation of the television device 7100 illustrated in FIG. 26C can be performed with an operation switch provided in the housing 7101 and a separate remote controller 7111. Alternatively, the display portion 7000 may include a touch sensor, and the television device 7100 may be operated by touch on the display portion 7000 with a finger or the like. The remote controller 7111 may be provided with a display portion for displaying information output from the remote controller 7111. With operation keys or a touch panel provided in the remote controller 7111, channels and volume can be operated and videos displayed on the display portion 7000 can be operated.

Note that the television device 7100 has a structure in which a receiver, a modem, and the like are provided. A general television broadcast can be received with the receiver. When the television device is connected to a communication network with or without wires via the modem, one-way (from a transmitter to a receiver) or two-way (between a transmitter and a receiver or between receivers, for example) data communication can be performed.

FIG. 26D illustrates an example of a laptop personal computer. The laptop personal computer 7200 includes a housing 7211, a keyboard 7212, a pointing device 7213, an external connection port 7214, and the like. In the housing 7211, the display portion 7000 is incorporated.

The display apparatus of one embodiment of the present invention can be used in the display portion 7000. Thus, the electronic device with extremely high resolution can be obtained.

FIG. 26E and FIG. 26F illustrate examples of digital signage.

Digital signage 7300 illustrated in FIG. 26E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 26F is digital signage 7400 attached to a cylindrical pillar 7401. The digital signage 7400 includes the display portion 7000 provided along a curved surface of the pillar 7401.

The display apparatus of one embodiment of the present invention can be used in the display portion 7000 illustrated in each of FIG. 26E and FIG. 26F. Thus, the electronic device with extremely high resolution can be obtained.

A larger area of the display portion 7000 can increase the amount of information that can be provided at a time. The larger display portion 7000 attracts more attention, so that the effectiveness of the advertisement can be increased, for example.

The use of a touch panel in the display portion 7000 is preferable because in addition to display of a still image or a moving image on the display portion 7000, intuitive operation by a user is possible. Moreover, for an application for providing information such as route information or traffic information, usability can be enhanced by intuitive operation.

As illustrated in FIG. 26E and FIG. 26F, it is preferable that the digital signage 7300 or the digital signage 7400 can work with an information terminal 7311 or an information terminal 7411 such as a smartphone a user has through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

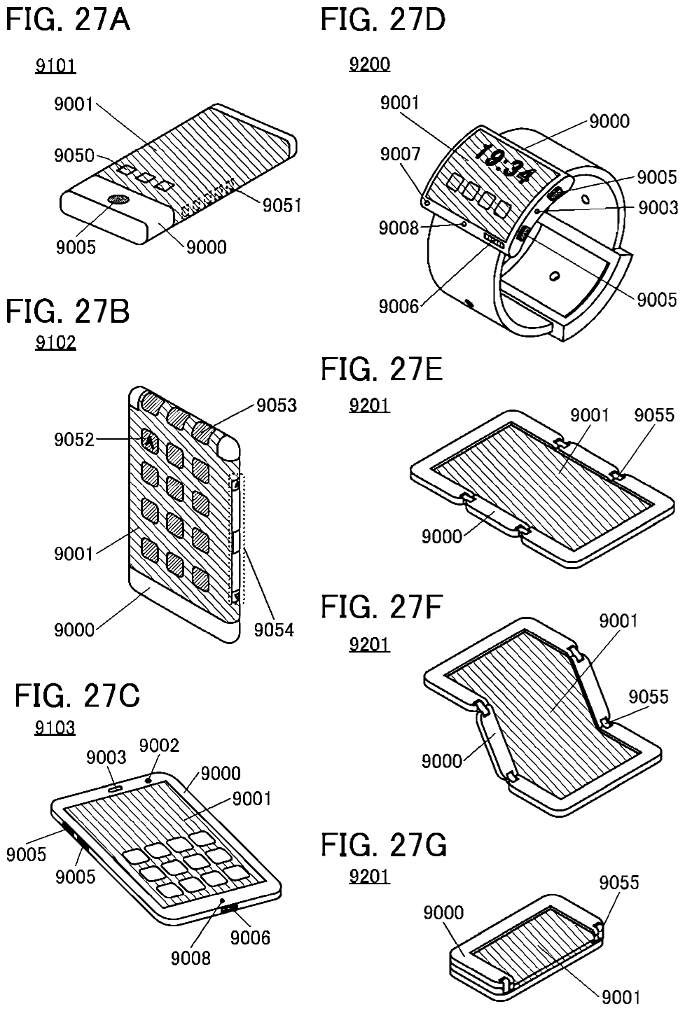

Electronic devices illustrated in FIG. 27A to FIG. 27G each include a housing 9000, a display portion 9001, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a microphone 9008, and the like.

The electronic devices illustrated in FIG. 27A to FIG. 27G have a variety of functions. For example, the electronic devices can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may each include a plurality of display portions. The electronic devices may each be provided with a camera or the like and have a function of taking a still image or a moving image, a function of storing the taken image in a storage medium (an external storage medium or a storage medium incorporated in the camera), a function of displaying the taken image on the display portion, or the like.

The details of the electronic devices illustrated in FIG. 27A to FIG. 27G are described below.

FIG. 27A is a perspective view illustrating a portable information terminal 9101. For example, the portable information terminal 9101 can be used as a smartphone. Note that the portable information terminal 9101 may include the speaker 9003, the connection terminal 9006, the sensor 9007, or the like. The portable information terminal 9101 can display characters and image information on its plurality of surfaces. FIG. 27A illustrates an example where three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, for example, the icon 9050 may be displayed at the position where the information 9051 is displayed.

FIG. 27B is a perspective view showing a portable information terminal 9102. The portable information terminal 9102 has a function of displaying information on three or more surfaces of the display portion 9001. Shown here is an example in which information 9052, information 9053, and information 9054 are displayed on different surfaces. For example, a user of the portable information terminal 9102 can check the information 9053 displayed such that it can be seen from above the portable information terminal 9102, with the portable information terminal 9102 put in a breast pocket of his/her clothes. The user can see the display without taking out the portable information terminal 9102 from the pocket and decide whether to answer the call, for example.

FIG. 27C is a perspective view of a tablet terminal 9103. The tablet terminal 9103 is capable of executing a variety of applications such as mobile phone calls, e-mailing, viewing and editing texts, music reproduction, Internet communication, and a computer game. The tablet terminal 9103 includes the display portion 9001, a camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 27D is a perspective view illustrating a watch-type portable information terminal 9200. For example, the portable information terminal 9200 can be used as a Smartwatch (registered trademark). The display surface of the display portion 9001 is curved, and an image can be displayed on the curved display surface. Furthermore, intercommunication between the portable information terminal 9200 and, for example, a headset capable of wireless communication enables hands-free calling. With the connection terminal 9006, the portable information terminal 9200 can perform mutual data transmission with another information terminal and charging. Note that the charging operation may be performed by wireless power feeding.

FIG. 27E to FIG. 27G are perspective views illustrating a foldable portable information terminal 9201. FIG. 27E is a perspective view of an opened state of the portable information terminal 9201, FIG. 27G is a perspective view of a folded state thereof, and FIG. 27F is a perspective view of a state in the middle of change from one of FIG. 27E and FIG. 27G to the other. The portable information terminal 9201 is highly portable when folded. When the portable information terminal 9201 is opened, a seamless large display region is highly browsable. The display portion 9001 of the portable information terminal 9201 is supported by three housings 9000 joined together by hinges 9055. The display portion 9001 can be folded with a radius of curvature of greater than or equal to 0.1 mm and less than or equal to 150 mm, for example.

This embodiment can be combined with the other embodiments as appropriate. In this specification, in the case where a plurality of structure examples are shown in one embodiment, the structure examples can be combined as appropriate.

### Example 1

In this example, an example of an insulating layer that can be used in the display apparatus of one embodiment of the present invention is described. Furthermore, results of a peel test on the insulating layer are described.

As a sample subjected to the peel test, a structure in which two kinds of films subjected to the peel test were formed sequentially over a glass substrate was prepared. The sample seen from the above had a size of 126 mm in length and 25 mm in width. A tape was attached to the top surface, tensile strength was applied to the tape, and strength at the time of peeling the upper film of the formed two films from the lower film was measured to obtain peel force. The sample was placed on a flat stage, and tensile strength was applied to the tape in a direction perpendicular to the stage.

As the peel force, a median value in the range of tape peel distance of 20 mm to 50 mm from a point where peeling began was used.

As Sample S1, a structure in which an In—Si—Sn oxide layer was formed over a glass substrate and a first organic layer was formed over the In—Si—Sn oxide layer was prepared.

As Sample S2, a structure in which a silicon oxynitride layer was formed over a glass substrate and a first organic layer was formed over the silicon oxynitride layer was prepared.

As Sample S3, a structure in which a second organic layer was formed over a glass substrate and an aluminum oxide layer was formed over the second organic layer was prepared.

As Sample S4, a structure in which an In—Si—Sn oxide layer was formed over a glass substrate and an aluminum oxide layer was formed over the In—Si—Sn oxide layer was prepared.

As Sample S5, a structure in which a silicon oxynitride layer was formed over a glass substrate and an aluminum oxide layer was formed over the silicon oxynitride layer was prepared.

As Sample S6, a structure in which an acrylic resin layer was formed over a glass substrate and an aluminum oxide layer was formed over the acrylic resin layer was prepared.

As the first organic layer of each of Sample S1 and Sample S2, N-(1,1′-biphenyl-4-yl)-N-[4-(9-phenyl-9H-carbazol-3-yl)phenyl]-9,9-dimethyl-9H-fluoren-2-amine (abbreviation: PCBBiF) was formed to a thickness of 60 nm by a vacuum evaporation method.

As the second organic layer of Sample S3, a stacked-layer structure of 2-[4′-(9-phenyl-9H-carbazol-3-yl)-3,1′-biphenyl-1-yl]dibenzo[f,h] quinoxaline (abbreviation: 2mpPCBPDBq) and 2,9-di(naphthalen-2-yl)-4,7-diphenyl-1,10-phenanthroline (abbreviation: NBPhen) was used. 2mpPCBPDBq was stacked to a thickness of 30 nm by a vacuum evaporation method, and NBPhen was stacked thereover to a thickness of 10 nm by a vacuum evaporation method.

The In—Si—Sn oxide layer used in each of Sample S1 and Sample S4 was formed by a sputtering method. An In—Si—Sn oxide was used as a target, and a mixed gas of argon and oxygen was used as a gas.

The aluminum oxide layer used in each of Sample S3 to Sample S6 was formed to a thickness of 30 nm under conditions at a substrate heating temperature of 80° C. by an ALD method.

The silicon oxynitride layer used in each of Sample S2 and Sample S4 was formed to a thickness of 100 nm by a PECVD method. Silane and nitrous oxide were used as gases, and the substrate heating temperature was set to 200° C.

An acrylic resin was applied, and then heat treatment was performed in a nitrogen gas atmosphere at 250° C. for one hour, whereby the acrylic resin layer used in Sample S6 was formed. Note that the acrylic resin layer was formed so as to have a thickness of 2 μm after the heat treatment.

Table 1 shows the structures of Sample S1 to Sample S6.

TABLE 1

| | Lower layer | Upper layer |
|---|---|---|
| S1 | In—Si—Sn oxide layer | First oragnic layer |
| S2 | Silicon oxynitride layer | First organic layer |
| S3 | Second organic layer | Aluminum oxide layer |
| S4 | In—Si—Sn oxide layer | Aluminum oxide layer |
| S5 | Silicon oxynitride layer | Aluminum oxide layer |
| S6 | Acrylic resin layer | Aluminum oxide layer |

Evaluation of Sample S1 enables an estimation of the adhesion between the pixel electrode 111 and the organic layer 112 in the display apparatus described in Embodiment 1 or the like, for example. Specifically, for example, it is possible to estimate the adhesion between the pixel electrode 111 and a hole-injection layer included in the organic layer 112. Alternatively, for example, it is possible to estimate the adhesion between the pixel electrode 111 and a hole-transport layer included in the organic layer 112.

Evaluation of Sample S2 enables an estimation of the adhesion between the insulating layer 106 and the organic layer 112 in the display apparatus described in Embodiment 1 or the like, for example. Specifically, for example, it is possible to estimate the adhesion between the insulating layer 106 and the hole-injection layer included in the organic layer 112. Alternatively, for example, it is possible to estimate the adhesion between the insulating layer 106 and the hole-transport layer included in the organic layer 112.

Evaluation of Sample S3 enables an estimation of the adhesion between the organic layer 112 and the insulating layer 118 in the display apparatus described in Embodiment 1 or the like, for example. Specifically, for example, it is possible to estimate the adhesion between an electron-transport layer of the organic layer 112 and the insulating layer 118.

Evaluation of Sample S4 enables an estimation of the adhesion between the pixel electrode 111 and the insulating layer 118 in the display apparatus described in Embodiment 1 or the like, for example.

Evaluation of Sample S5 enables an estimation of the adhesion between the insulating layer 106 and the insulating layer 118 in the display apparatus described in Embodiment 1 or the like, for example.

Evaluation of Sample S6 enables an estimation of the adhesion between the insulating layer 105 and the insulating layer 118 in the display apparatus described in Embodiment 1 or the like, for example.

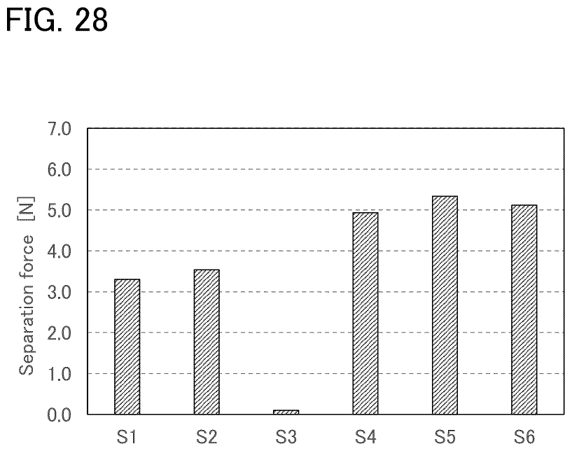

FIG. 28 shows peel force in Sample S1 to Sample S6. In Sample S3, the peel force was 0.1 [N], which was lower than those of the other samples. Note that in the other samples, high peel force of 3.0 [N] or higher was obtained. There is a possibility that the actual peel force of these samples exceeded the upper limit of a measurement system, and thus the actual peel force may be higher.

It is suggested from FIG. 28 that, as described in the above embodiment, sealing the pixel electrode 111 and the organic layer 112 (the PS layer 155S) with the combination of two films with high peel force, such as the insulating layer 106 and the insulating layer 118, has an effect of inhibiting the insulating layer 118 from being separated from the organic layer 112 (the PS layer 155S) in the display apparatus of one embodiment of the present invention.

### Example 2

In this example, a display panel of one embodiment of the present invention was fabricated.

The fabrication of the display panel was performed based on the manufacturing method described in Embodiment 1. Specifically, a substrate in which a pixel circuit including a transistor, a wiring, and the like was formed over a glass substrate was prepared. Then, the insulating layer 105, the insulating layer 106, and the pixel electrode 111 were formed in this order, and then the depressed portion 175 was formed in the insulating layer 105. Next, after the organic layer 112R including a red-light-emitting layer, the organic layer 112G including a green-light-emitting layer, the organic layer 112B including a blue-light-emitting layer, and the PS layer 155S including a photoelectric conversion layer were formed in this order, the resin layer 126 was provided, and opening portions were provided in the insulating layer 118 and the resin layer 126 over the organic layers 112 and the PS layer 155S. A layer including an organic photoelectric conversion layer was used as the PS layer 155S. Subsequently, an electron-injection layer, a common electrode, and a protective layer were formed in this order over each EL layer. Then, a glass substrate was bonded to the substrate with a sealing resin.

A stacked-layer structure of an aluminum oxide layer and an In—Ga—Zn oxide layer over the aluminum oxide layer was used as the insulating layer 118. The aluminum oxide layer was formed by an ALD method. The In—Ga—Zn oxide layer was formed by a sputtering method.

The diagonal size, the number of effective pixels, and the resolution of a display portion of the display panel are 5.72 inches, 1440×2560, and 513 ppi, respectively.

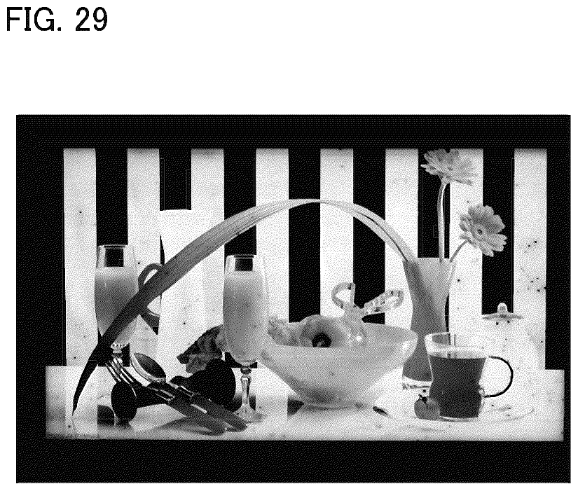

FIG. 29 shows the display panel in a display state. A separate coloring method made it possible to achieve displaying a full-color image with an extremely high resolution. Furthermore, light incident on the panel was able to be received using the display panel shown in FIG. 29 to perform image capturing.

### Example 3

In this example, a structure including a depressed portion of one embodiment of the present invention was formed and subjected to cross-sectional observation.

A substrate in which a pixel circuit including a transistor, a wiring, and the like was formed over a glass substrate was prepared.

Next, an acrylic resin layer was formed as the insulating layer 105. Specifically, an acrylic resin was applied, and then heat treatment was performed in a nitrogen atmosphere at 250° C. for one hour, whereby the acrylic resin layer was formed. Note that the acrylic resin layer was formed so as to have a thickness of 2 μm after the heat treatment.

Next, a stacked-layer structure of a silicon nitride layer and a silicon oxynitride layer was formed as the insulating layer 106 by a PECVD method. Specifically, first, the substrate heating temperature was set to 200° C., and a 10-nm-thick silicon nitride layer was formed using a mixed gas of silane and nitrogen as a gas. Subsequently, the substrate heating temperature was set to 200° C., and a 200-nm-thick silicon oxynitride layer was formed using silane and nitrous oxide as gases.

Next, a stacked-layer structure of an In—Si—Sn oxide layer, an APC layer, and an In—Si—Sn oxide layer was formed as the pixel electrode 111. Specifically, first, a 10-nm-thick In—Si—Sn oxide layer was formed as the first conductive layer of the pixel electrode 111 by a sputtering method. An In—Si—Sn oxide was used as a target, and a mixed gas of argon and oxygen was used as a gas.

Next, a 100-nm-thick APC layer was formed as the second conductive layer of the pixel electrode 111 by a sputtering method. An alloy containing silver (Ag), palladium (Pd), and copper (Cu) was used as a target, and argon was used as a gas. After that, the second conductive layer was processed by wet etching.

Next, a 100-nm-thick In—Si—Sn oxide layer was formed as the third conductive layer of the pixel electrode 111 by a sputtering method. The deposition conditions were the same as those for the first conductive layer. After that, the first conductive layer and the third conductive layer were processed by wet etching.

Next, the insulating layer 106 and the insulating layer 105 were processed by dry etching and ashing, whereby the depressed portion 175 part of which is located below the insulating layer 106 was formed in the insulating layer 105.

First, a resist mask was formed. Then, dry etching was performed. The insulating layer 106 and the insulating layer 105 were processed by the dry etching. As specific conditions of the dry etching, sulfur hexafluoride was used as an etching gas at a flow rate of 100 sccm, the pressure was set to 0.67 Pa, the ICP power was set to 6000 W, and the bias power was set to 500 W. The etching treatment time was set to 180 seconds.

Next, ashing was performed. The insulating layer 105 is mainly processed by the ashing. As specific conditions of the ashing, oxygen was used as a gas at a flow rate of 1800 sccm, the pressure was set to 40 Pa, and the bias power was set to 700 W. Three conditions of treatment time, that is, 30 seconds, 90 seconds, and 150 seconds, were employed. Then, resist separation was performed after the ashing.

Next, PCBBiF was formed as the organic layer 112Rf to a thickness of 100 nm by vacuum evaporation. Note that as for the organic layer 112Rf described here, the formation process was simplified and a single-layer structure of PCBBiF was used as the organic layer for shape confirmation. Therefore, although the organic layer 112Rf formed in this example did not actually include a layer having intensity in the red wavelength range, the thickness of the organic layer 112Rf was set to a thickness equivalent to that of the organic layer used in the display apparatus.

Next, a stacked-layer structure of two layers was formed as the insulating film 118A (hereinafter, the lower layer is referred to as an insulating film 118A(1) and the upper layer is referred to as an insulating film 118A(2)). An aluminum oxide film was formed as the insulating film 118A(1), and a stacked-layer structure of an In—Ga—Zn oxide film was formed as the insulating film 118A(2).

The aluminum oxide film was formed to a thickness of 30 nm by an ALD method. The substrate heating temperature was set to 80° C.

The In—Ga—Zn oxide film was formed to a thickness of 50 nm by a sputtering method using an In—Si—Sn oxide as a target and a mixed gas of argon and oxygen as a gas.

### <Cross-Sectional Observation>

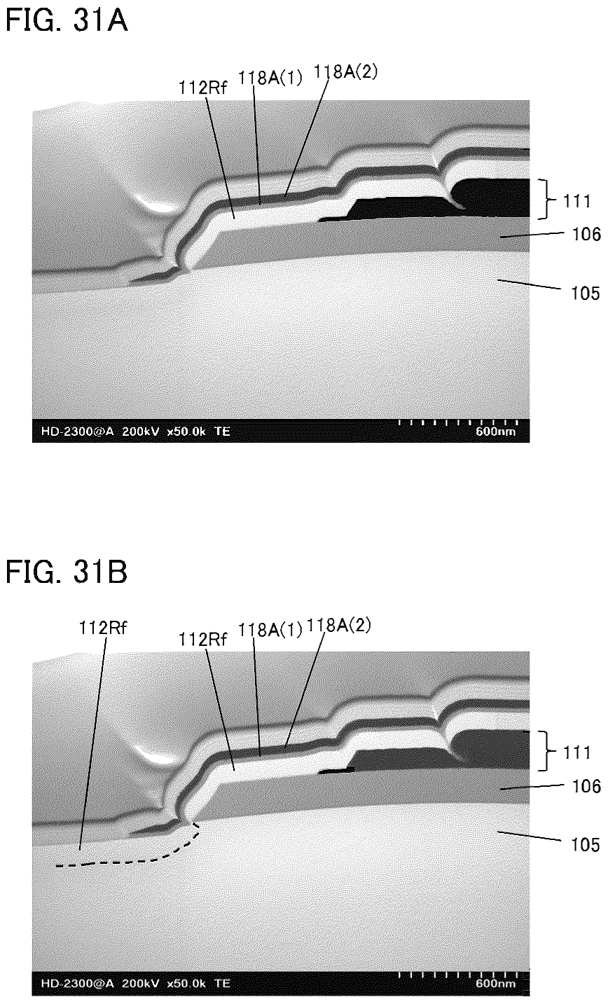

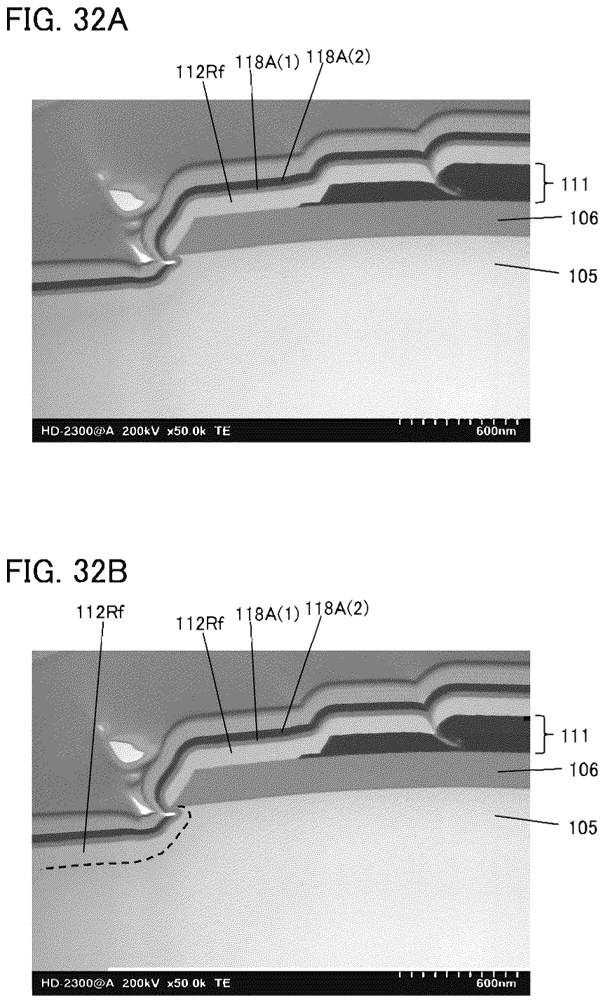

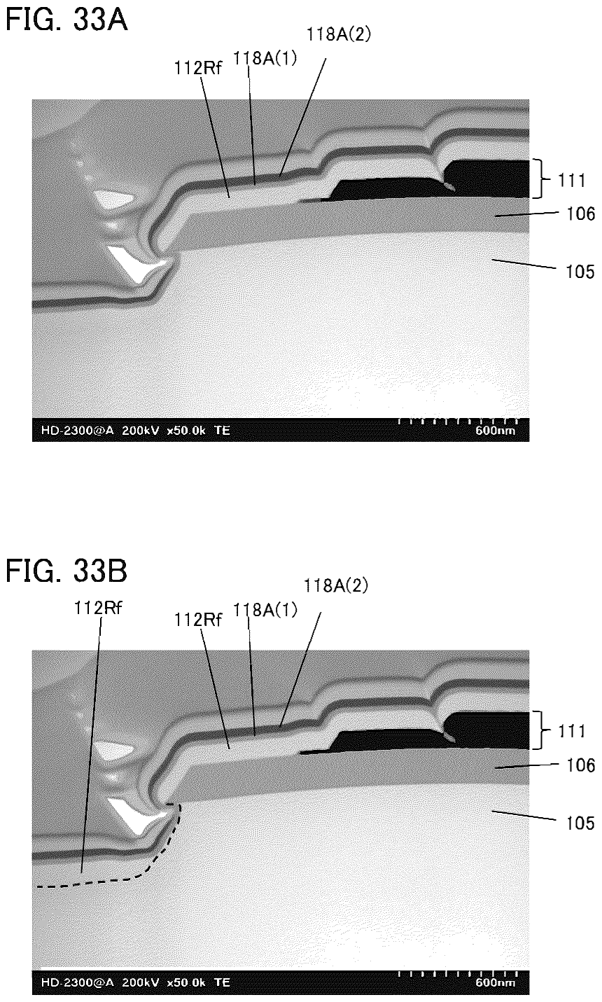

The fabricated samples were each processed by FIB to expose a cross section, and the cross section was observed with a STEM. As the STEM, HD-2300 manufactured by Hitachi High-Tech Corporation was used. FIG. 31A, FIG. 32A, and FIG. 33A show transmission images taken at an accelerating voltage of 200 kV. FIG. 31A, FIG. 32A, and FIG. 33A show observation results of the sample fabricated under conditions with an ashing treatment time of 30 seconds, the sample fabricated under conditions with 90 seconds, and the sample fabricated under conditions with 150 seconds, respectively.

FIG. 31B shows an example where the organic layer 112Rf and the like are clarified by adding an auxiliary line in FIG. 31A, FIG. 32B shows an example where the organic layer 112Rf and the like are clarified by adding an auxiliary line in FIG. 32A, and FIG. 33B shows an example where the organic layer 112Rf and the like are clarified by adding an auxiliary line in FIG. 33A.

In FIG. 32A and FIG. 33A, the organic layer 112Rf disconnected at a projecting portion of the insulating layer 106 was observed. Furthermore, it was also suggested that the insulating film 118A(1) was in contact with the bottom surface of the insulating layer 106 and the side surface of the insulating layer 105.

In FIG. 32A, the width W2 was estimated to be approximately 60 nm and the depth W5 was estimated to be approximately 280 nm in the depressed portion 175.

In FIG. 33A, the width W2 was estimated to be approximately 90 nm and the depth W5 was estimated to be approximately 400 nm in the depressed portion 175.

Note that in FIG. 31A, the width W2 was estimated to be approximately 10 nm and the depth W5 was estimated to be approximately 180 nm in the depressed portion 175. Furthermore, in FIG. 31A, disconnection of the organic layer 112Rf was not clearly observed.

With the use of the manufacturing method of one embodiment of the present invention, the depressed portion 175 was able to be formed in the insulating layer 105. In addition, the width W2 in the depressed portion 175 was able to be suitably adjusted by an ashing process using oxygen. It was suggested that a structure in which part of the insulating film 118A was in contact with the bottom surface of the insulating layer 106 and the side surface of the insulating layer 105 can obtained with the use of the manufacturing method of one embodiment of the present invention.

### <Peel Test>

Next, a peel test was performed using the fabricated samples.

The samples were each cut such that the sample seen from above had 126 mm in length and 25 mm in width. A tape was attached to the top surface, tensile strength was applied to the tape, and strength at the time of peeling the upper film of the formed two films from the lower film was measured to obtain peel force. The sample was placed on a flat stage, and tensile strength was applied to the tape in a direction perpendicular to the stage.

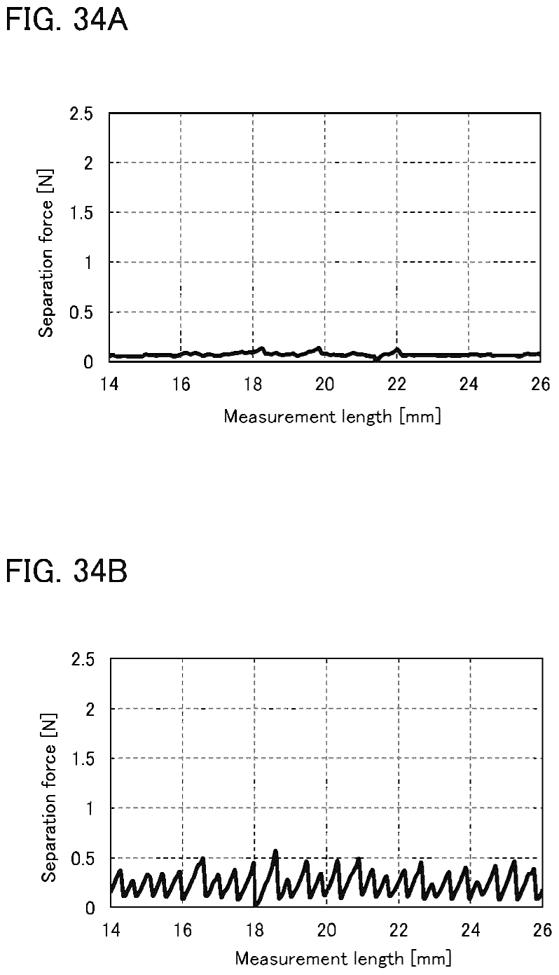

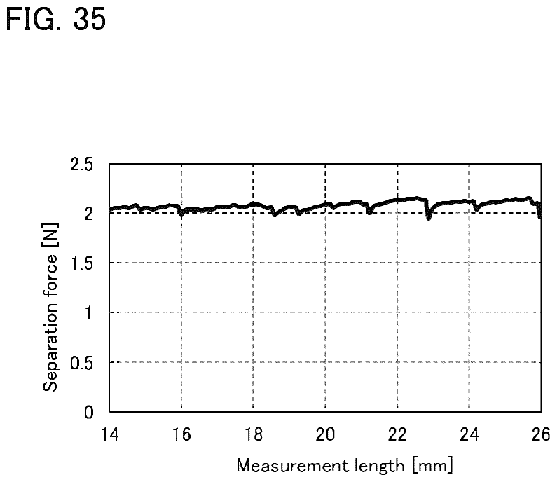

Peel force measured in the range of tape peel distance (expressed as measurement length on the horizontal axis of the graph) of 13 mm to 27 mm from a point where peeling began is shown in FIG. 34A, FIG. 34B, and FIG. 35. FIG. 34A, FIG. 34B, and FIG. 35 show measurement results of the sample fabricated under conditions with ashing for 30 seconds, the sample fabricated under conditions with ashing for 90 seconds, and the sample fabricated under conditions with ashing for 150 seconds, respectively. In FIG. 34A, the minimum value and the maximum value of the peel force were 0.04 N and 0.06N, respectively. In FIG. 34B, the minimum value and the maximum value of the peel force were 0.03 N and 0.57N, respectively. In FIG. 35, the minimum value and the maximum value of the peel force were 1.95 N and 2.15N, respectively. As the width W2 of the depressed portion 175 was increased, the peel force was found to become higher; and the conditions with W2 of 60 nm (the sample with ashing for 90 seconds) had many measurement points where the peel force exceeded 0.2 N, thereby exhibiting excellent peel force. In addition, under the conditions with W2 of 90 nm (the sample subjected to ashing for 150 seconds), higher and excellent peel force was achieved.

### REFERENCE NUMERALS

100A: display apparatus, 100: display apparatus, 101: substrate, 102: substrate, 105: insulating layer, 106: insulating layer, 110a: light-emitting element, 110B: light-emitting element, 110b: light-emitting element, 110c: light-emitting element, 110d: light-receiving element, 110G: light-emitting element, 110R: light-emitting element, 110S: light-receiving element, 110: light-emitting element, 111_1: conductive layer, 111_2: conductive layer, 111_3: conductive layer, 111B: pixel electrode, 111G: pixel electrode, 111R: pixel electrode, 111S: pixel electrode, 111: pixel electrode, 112B: organic layer, 112G: organic layer, 112Gf: organic layer, 112R: organic layer, 112Rf: organic layer, 112: organic layer, 113: common electrode, 114: common layer, 115a: conductive layer, 115b: conductive layer, 115d: conductive layer, 117: light-blocking layer, 118a: insulating layer, 118A: insulating film, 118b: insulating layer, 118B: insulating film, 118c: insulating layer, 118d: insulating layer, 118g: insulating layer, 118: insulating layer, 121: protective layer, 123: conductive layer, 124a: pixel, 124b: pixel, 125A: insulating film, 125: insulating layer, 126A: resin film, 126: resin layer, 127a: conductive layer, 127b: conductive layer, 127d: conductive layer, 128: layer, 129a: conductive layer, 129b: conductive layer, 129d: conductive layer, 130a: subpixel, 130b: subpixel, 130c: subpixel, 130d: subpixel, 140: connection portion, 142: adhesive layer, 150: pixel, 151: substrate, 152: substrate, 155S: PS layer, 164: circuit, 165: wiring, 166: conductive layer, 167: display portion, 170: substrate, 171: adhesive layer, 172: FPC, 173: IC, 175: depressed portion, 181: resist mask, 182: resist mask, 190: finger, 191: contact portion, 192: fingerprint, 193: image capturing range, 200A: display apparatus, 200B: display apparatus, 200C: display apparatus, 200D: display apparatus, 200E: display apparatus, 200F: display apparatus, 200G: display apparatus, 200H: display apparatus, 201: transistor, 204: connection portion, 205: transistor, 209: transistor, 210: transistor, 211: insulating layer, 213: insulating layer, 215: insulating layer, 218: insulating layer, 221: conductive layer, 222a: conductive layer, 222b: conductive layer, 223: conductive layer, 225: insulating layer, 231i: channel formation region, 231n: low-resistance region, 231: semiconductor layer, 240: capacitor, 241: conductive layer, 242: connection layer, 243: insulating layer, 245: conductive layer, 251: conductive layer, 252: conductive layer, 254: insulating layer, 255: insulating layer, 256: plug, 261: insulating layer, 262: insulating layer, 263: insulating layer, 264: insulating layer, 265: insulating layer, 271: plug, 274a: conductive layer, 274b: conductive layer, 274: plug, 280: display module, 281: display portion, 282: circuit portion, 283a: pixel circuit, 283: pixel circuit portion, 284a: pixel, 284: pixel portion, 285: terminal portion, 286: wiring portion, 290: FPC, 291: substrate, 292: substrate, 301A: substrate, 301B: substrate, 301: substrate, 310A: transistor, 310B: transistor, 310: transistor, 311: conductive layer, 312: low-resistance region, 313: insulating layer, 314: insulating layer, 315: element isolation layer, 320A: transistor, 320B: transistor, 320: transistor, 321: semiconductor layer, 323: insulating layer, 324: conductive layer, 325: conductive layer, 326: insulating layer, 327: conductive layer, 328: insulating layer, 329: insulating layer, 331: substrate, 332: insulating layer, 335: insulating layer, 336: insulating layer, 341: conductive layer, 342: conductive layer, 343: plug, 344: insulating layer, 345: insulating layer, 346: insulating layer, 347: bump, 348: adhesive layer, 400: display apparatus, 402: driver circuit portion, 403: driver circuit portion, 404: display portion, 405B: subpixel, 405G: subpixel, 405R: subpixel, 405: pixel, 430: pixel, 700A: electronic device, 700B: electronic device, 721: housing, 723: wearing portion, 727: earphone portion, 750: earphone, 751: display panel, 753: optical member, 756: display region, 757: frame, 758: nose pad, 761: lower electrode, 762: upper electrode, 763a: light-emitting unit, 763b: light-emitting unit, 763c: light-emitting unit, 763: EL layer, 764: layer, 771a: light-emitting layer, 771b: light-emitting layer, 771c: light-emitting layer, 771: light-emitting layer, 772a: light-emitting layer, 772b: light-emitting layer, 772c: light-emitting layer, 772: light-emitting layer, 773: light-emitting layer, 780a: layer, 780b: layer, 780c: layer, 780: layer, 781: layer, 782: layer, 783: photoelectric conversion layer, 785: charge-generation layer, 787: PS layer, 790a: layer, 790b: layer, 790c: layer, 790: layer, 791: layer, 792: layer, 800A: electronic device, 800B: electronic device, 820: display portion, 821: housing, 822: communication portion, 823: wearing portion, 824: control portion, 825: image capturing portion, 827: earphone portion, 832: lens, 6500: electronic device, 6501: housing, 6502: display portion, 6503: power button, 6504: button, 6505: speaker, 6506: microphone, 6507: camera, 6508: light source, 6510: protection member, 6511: display panel, 6512: optical member, 6513: touch sensor panel, 6515: FPC, 6516: IC, 6517: printed circuit board, 6518: battery, 7000: display portion, 7100: television device, 7101: housing, 7103: stand, 7111: remote controller, 7200: laptop personal computer, 7211: housing, 7212: keyboard, 7213: pointing device, 7214: external connection port, 7300: digital signage, 7301: housing, 7303: speaker, 7311: information terminal, 7400: digital signage, 7401: pillar, 7411: information terminal, 9000: housing, 9001: display portion, 9002: camera, 9003: speaker, 9005: operation key, 9006: connection terminal, 9007: sensor, 9008: microphone, 9050: icon, 9051: information, 9052: information, 9053: information, 9054: information, 9055: hinge, 9101: portable information terminal, 9102: portable information terminal, 9103: tablet terminal, 9200: portable information terminal, 9201: portable information terminal

1. A display apparatus comprising:
a first insulating layer;
a light-emitting element and a light-receiving element over the first insulating layer;
a second insulating layer;
a third insulating layer; and
a resin layer over the first insulating layer,
wherein the light-emitting element comprises a first pixel electrode, a first organic layer, and a common electrode,
wherein the light-receiving element comprises a second pixel electrode, a second organic layer, and the common electrode,
wherein the first organic layer comprises a light-emitting layer,
wherein the second organic layer comprises a photoelectric conversion layer,
wherein the first insulating layer comprises a depressed portion,
wherein the depressed portion comprises a region overlapping with the first pixel electrode, a region overlapping with the second pixel electrode, and a region overlapping with neither the first pixel electrode nor the second pixel electrode,
wherein the second insulating layer comprises a region in contact with a top surface of the first organic layer, a region in contact with a side surface of the first organic layer, and a region located below the first pixel electrode,
wherein the third insulating layer comprises a region in contact with a top surface of the second organic layer, a region in contact with a side surface of the second organic layer, and a region located below the second pixel electrode,
wherein the resin layer comprises a region located in the depressed portion, and
wherein the common electrode is provided to cover a top surface of the resin layer.

2. The display apparatus according to claim 1,
wherein the second insulating layer comprises a region in contact with the first insulating layer below the first pixel electrode, and
wherein the third insulating layer comprises a region in contact with the first insulating layer below the second pixel electrode.

3. The display apparatus according to claim 1,
wherein a shortest distance between an end portion of the first pixel electrode and an end portion of the second pixel electrode is larger than twice a thickness of the first organic layer.

4. The display apparatus according to claim 1,
wherein the depressed portion has a downward-convex arc shape in a cross-sectional view.

5. The display apparatus according to claim 1,
wherein each of the second insulating layer and the third insulating layer comprises aluminum and oxygen.

6. A display apparatus comprising:
a first insulating layer;
a second insulating layer and a third insulating layer over the first insulating layer;
a light-emitting element over the second insulating layer;
a light-receiving element over the third insulating layer;
a fourth insulating layer;
a fifth insulating layer; and
a resin layer over the first insulating layer,
wherein the first insulating layer is an organic insulating layer,
wherein the second insulating layer and the third insulating layer are inorganic insulating layers,
wherein the light-emitting element comprises a first pixel electrode, a first organic layer, and a common electrode,
wherein the light-receiving element comprises a second pixel electrode, a second organic layer, and the common electrode,
wherein the first organic layer comprises a light-emitting layer,
wherein the second organic layer comprises a photoelectric conversion layer,
wherein the first insulating layer comprises a depressed portion,
wherein the depressed portion comprises a region overlapping with the first pixel electrode, a region overlapping with the second pixel electrode, and a region overlapping with neither the first pixel electrode nor the second pixel electrode,
wherein the fourth insulating layer comprises a region in contact with a top surface of the first organic layer, a region in contact with a side surface of the first organic layer, and a region in contact with the second insulating layer below the first pixel electrode,
wherein the fifth insulating layer comprises a region in contact with a top surface of the second organic layer, a region in contact with a side surface of the second organic layer, and a region in contact with the third insulating layer below the second pixel electrode,
wherein the resin layer comprises a region located in the depressed portion, and
wherein the common electrode is provided to cover a top surface of the resin layer.

7. A method for manufacturing a display apparatus, comprising:
forming a first pixel electrode and a second pixel electrode over a first insulating layer;
etching part of the first insulating layer to form a depressed portion comprising a region overlapping with the first pixel electrode, a region overlapping with the second pixel electrode, and a region overlapping with neither the first pixel electrode nor the second pixel electrode;
forming a first organic film over the first pixel electrode, the second pixel electrode, and the first insulating layer to form a first organic layer over the first pixel electrode and form a second organic layer over the second pixel electrode;
forming a second insulating layer over the first organic layer;
removing the second organic layer;
forming a second organic film over the first organic layer, the second pixel electrode, and the first insulating layer to form a third organic layer over the second pixel electrode and form a fourth organic layer over the first organic layer;
forming a third insulating layer over the third organic layer;
removing the fourth organic layer;
forming a resin layer over the first insulating layer, the second insulating layer, and the third insulating layer;
removing part of the resin layer, part of the second insulating layer, and part of the third insulating layer to form a first opening portion reaching the first organic layer in the resin layer and the second insulating layer and form a second opening portion reaching the third organic layer in the resin layer and the third insulating layer; and
forming a common electrode that overlaps with the first organic layer through the first opening portion and overlaps with the third organic layer through the second opening portion.

8. The method for manufacturing a display apparatus, according to claim 7,
wherein the first organic film comprises a light-emitting compound emitting light having intensity in a red-wavelength range, a green-wavelength range, or a blue-wavelength range, and
wherein the second organic film comprises a light-emitting compound emitting light having intensity in a wavelength range that is any of the red-wavelength range, the green-wavelength range, and the blue-wavelength range and is different from the wavelength range of the color of the first organic film.

9. The method for manufacturing a display apparatus, according to claim 7,
wherein the first organic film comprises a light-emitting compound, and
wherein the second organic film comprises an organic semiconductor.

10. A display apparatus comprising:
a first insulating layer;
a first light-emitting element, a second light-emitting element, and a resin layer over the first insulating layer;
a second insulating layer; and
a third insulating layer,
wherein the first light-emitting element comprises a first pixel electrode, a first organic layer, and a common electrode,
wherein the second light-emitting element comprises a second pixel electrode, a second organic layer, and the common electrode,
wherein each of the first organic layer and the second organic layer comprises a light-emitting layer,
wherein the first insulating layer comprises a depressed portion,
wherein the depressed portion comprises a groove-like region provided along a side of the first pixel electrode in a plan view,
wherein the groove-like region comprises a first region overlapping with the first pixel electrode and a second region overlapping with the second pixel electrode,
wherein the first region has a width greater than or equal to 20 nm and less than or equal to 500 nm,
wherein the second region has a width greater than or equal to 20 nm and less than or equal to 500 nm,
wherein the second insulating layer comprises a region in contact with a top surface of the first organic layer, a region in contact with a side surface of the first organic layer, and a region located below the first pixel electrode,
wherein the third insulating layer comprises a region in contact with a top surface of the second organic layer, a region in contact with a side surface of the second organic layer, and a region located below the second pixel electrode,
wherein the resin layer comprises a region located in the depressed portion, and
wherein the common electrode comprises a region covering a top surface of the resin layer.

11. The display apparatus according to claim 10,
wherein the groove-like region has a depth greater than or equal to 50 nm and less than or equal to 3000 nm.

12. The display apparatus according to claim 10,
wherein the second insulating layer comprises a region in contact with the first insulating layer below the first pixel electrode, and
wherein the third insulating layer comprises a region in contact with the first insulating layer below the second pixel electrode.

13. The display apparatus according to claim 10,
wherein a shortest distance between an end portion of the first pixel electrode and an end portion of the second pixel electrode is larger than twice a thickness of the first organic layer.

14. The display apparatus according to claim 10,
wherein the depressed portion has a downward-convex arc shape in a cross-sectional view.

15. The display apparatus according to claim 10,
wherein each of the second insulating layer and the third insulating layer comprises aluminum and oxygen.

16. A display apparatus comprising:
a first insulating layer;
a second insulating layer, a third insulating layer, and a resin layer over the first insulating layer;
a first light-emitting element over the second insulating layer;
a second light-emitting element over the third insulating layer;
a fourth insulating layer; and
a fifth insulating layer,
wherein the first insulating layer is an organic insulating layer,
wherein the second insulating layer and the third insulating layer are inorganic insulating layers,
wherein the first light-emitting element comprises a first pixel electrode, a first organic layer, and a common electrode,
wherein the second light-emitting element comprises a second pixel electrode, a second organic layer, and the common electrode,
wherein each of the first organic layer and the second organic layer comprises a light-emitting layer,
wherein the first insulating layer comprises a depressed portion,
wherein the depressed portion comprises a groove-like region provided along a side of the first pixel electrode in a plan view,
wherein the groove-like region comprises a first region overlapping with the first pixel electrode and a second region overlapping with the second pixel electrode,
wherein the first region has a width greater than or equal to 20 nm and less than or equal to 500 nm,
wherein the second region has a width greater than or equal to 20 nm and less than or equal to 500 nm,
wherein the fourth insulating layer comprises a region in contact with a top surface of the first organic layer, a region in contact with a side surface of the first organic layer, and a region in contact with the second insulating layer below the first pixel electrode,
wherein the fifth insulating layer comprises a region in contact with a top surface of the second organic layer, a region in contact with a side surface of the second organic layer, and a region in contact with the third insulating layer below the second pixel electrode,
wherein the resin layer comprises a region located in the depressed portion, and
wherein the common electrode comprises a region covering a top surface of the resin layer.

17. The display apparatus according to claim 16,
wherein the groove-like region has a depth greater than or equal to 50 nm and less than or equal to 3000 nm.
